(19) United States
(12) Patent Application Publication
(10) Pub. No.: US 2026/0123144 A1
(43) Pub. Date: Apr. 30, 2026

(54) METHOD OF MANUFACTURING DISPLAY DEVICE, AND ELECTRONIC APPARATUS INCLUDING DISPLAY PANEL

(71) Applicant: Samsung Display Co., Ltd., Yongin-si (KR)

(72) Inventors: Seongwon Kim, Yongin-si (KR); Kyungho Kim, Yongin-si (KR); Junsu Park, Yongin-si (KR); Junhyeong Park, Yongin-si (KR)

(21) Appl. No.: 19/373,535

(22) Filed: Oct. 29, 2025

(30) Foreign Application Priority Data
Oct. 30, 2024 (KR) 10-2024-0151492

(51) Int. Cl. H10H 29/49; H01L 25/075; H10H 29/01

(52) U.S. Cl. CPC H10H 29/49; H10H 29/012; H10W 90/00

(57) ABSTRACT

Provided is a method of manufacturing a display panel including a pixel area and a connection area surrounding the pixel area, the method including forming a lower layer including a substrate, forming, on the lower layer, a pixel circuit layer including an inorganic insulating layer and a pixel circuit to overlap the pixel area, removing a portion of the inorganic insulating layer that overlaps the connection area, forming a light-emitting diode on the pixel circuit layer, forming connection wiring that overlaps the connection area by using a sacrificial layer, and removing the sacrificial layer.

### CROSS-REFERENCE TO RELATED APPLICATION

The present application claims priority to and the benefit of Korean Patent Application No. 10-2024-0151492, filed on Oct. 30, 2024, in the Korean Intellectual Property Office, the entire disclosure of which is incorporated herein by reference.

### BACKGROUND

### 1. Field

One or more aspects of embodiments of the present disclosure relate to a method of manufacturing a display panel, and an electronic apparatus including the display panel.

### 2. Description of the Related Art

Along with the development of display panels that visually display images based on the provided electrical signals, various display panels having characteristics such as a slim profile, a lightweight, and/or suitably low power consumption, and electronic apparatuses including the display panels have been introduced. For example, flexible display panels which may be folded and/or rolled, display panels of one or more suitable structures (such as, stretchable display panels), and electronic apparatuses including the display panels have been researched and developed.

### SUMMARY

One or more aspects of embodiments of the present disclosure are directed toward a method of manufacturing a display panel having improved stretchability and implementing excellent or suitable quality images even when being stretched, and an electronic apparatus including the display panel. However, aspects of embodiments are not limited thereto, and the above characteristics do not limit the scope of embodiments according to the disclosure.

Additional aspects will be set forth in portion in the description which follows and, in part, will be apparent from the description, or may be learned by practice of the presented embodiments of the disclosure.

According to one or more embodiments, a method of manufacturing a display panel including a pixel area and a connection area around (e.g., surrounding) the pixel area includes forming a lower layer including a substrate, forming, on the lower layer, a pixel circuit layer including an inorganic insulating layer and a pixel circuit to overlap the pixel area, removing a portion of the inorganic insulating layer that overlaps the connection area, forming a light-emitting diode on the pixel circuit layer, forming connection wiring that overlaps the connection area by using a sacrificial layer, and removing the sacrificial layer.

The sacrificial layer may include a hydrophobic material.

The removing of the sacrificial layer may include removing the sacrificial layer through a cleaning process utilizing water.

The forming of the pixel circuit layer may include forming a signal line electrically connected to the pixel circuit, and the signal line arranged in the pixel area may extend to the connection area and may be in direct contact with the connection wiring.

The signal line may be a gate line extending along a first direction or a data line extending along a second direction intersecting the first direction.

The forming of the connection wiring that overlaps the connection area by using the sacrificial layer may include forming the sacrificial layer, in which a first opening overlapping the connection area is defined, and forming connection wiring in an area overlapping the first opening.

The method may further include, between the forming of the light-emitting diode and the forming of the connection wiring, inverting the display panel so that an upper surface and a lower surface of the display panel are reversely arranged, and removing the lower layer.

The sacrificial layer may be formed on a lower surface of the pixel circuit layer.

The method may further include, between the forming of the light-emitting diode and the inverting of the display panel, forming an upper elastomer layer to cover the light-emitting diode, and the connection wiring may be provided on a lower surface of the upper elastomer layer.

The method may further include, after the removing of the sacrificial layer, forming a lower elastomer layer on a lower surface of the pixel circuit layer to cover the connection wiring.

The forming of the connection wiring that overlaps the connection area by using the sacrificial layer and the removing of the sacrificial layer may be performed between the forming of the pixel circuit layer and the forming of the light-emitting diode.

The sacrificial layer may be formed on an upper surface of the pixel circuit layer.

The forming of the lower layer may include forming a base layer on the substrate, and the connection wiring may be defined in the base layer and provided within a second opening that overlaps the first opening.

The second opening may expose an upper surface of the substrate.

The method may further include detaching the substrate, and forming a lower elastomer layer on a lower surface of the base layer and a lower surface of the connection wiring.

The forming of the lower layer may further include forming a lower elastomer layer between the substrate and the base layer, and the second opening may expose an upper surface of the lower elastomer layer.

The method may further include forming an upper elastomer layer to cover the light-emitting diode and the connection wiring.

The forming of the connection wiring that overlaps the connection area by using the sacrificial layer and the removing of the sacrificial layer may be performed between the forming of the lower layer and the forming of the pixel circuit layer.

The forming of the lower layer may include forming a lower elastomer layer on the substrate, and the sacrificial layer and the connection wiring may be formed on the lower elastomer layer.

The method may further include forming an upper elastomer layer to cover the light-emitting diode and the connection wiring.

The forming of the connection wiring that overlaps the connection area by using the sacrificial layer may include forming a sacrificial layer on the lower layer, forming, on the sacrificial layer, a sub-elastomer layer patterned to overlap the connection area, and forming the connection wiring on an upper surface of the sub-elastomer layer.

The method may further include forming an upper elastomer layer to cover the light-emitting diode and the connection wiring.

The method may further include, after the removing of the sacrificial layer, forming a lower elastomer layer on a lower surface of the pixel circuit layer and a lower surface of the sub-elastomer layer.

According to one or more embodiments, an electronic apparatus including a pixel area and a connection area around (e.g., surrounding) the pixel area includes a display panel, and a lower cover forming an outer appearance and having an opening exposing a portion of the display panel in a front surface of the lower cover. The display panel includes a lower elastomer layer, a pixel circuit layer provided on the lower elastomer layer, and including an inorganic insulating layer and a pixel circuit to overlap the pixel area, a light-emitting diode provided on the pixel circuit layer, and connection wiring provided on the lower elastomer layer and overlapping the connection area. The pixel circuit layer may include a signal line electrically connected to the pixel circuit, and the signal line arranged in the pixel area may extend to the connection area and come into direct contact with the connection wiring.

A side surface of the connection wiring and a lower surface of the connection wiring may be surrounded by the lower elastomer layer.

The electronic apparatus may further include a base layer between the lower elastomer layer and the pixel circuit layer, the base layer may be provided in the pixel area, and the connection wiring may cover an end of the base layer.

The signal line may cover an end of the connection wiring.

The electronic apparatus may further include a sub-elastomer layer between the lower elastomer layer and the connection wiring, and the sub-elastomer layer and the connection wiring may overlap each other in a plan view.

A planar area of the sub-elastomer layer may be equal to a planar area of the connection wiring.

The electronic apparatus may further include an upper elastomer layer configured to cover the light-emitting diode and the connection wiring.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a schematic perspective view of an electronic apparatus according to one or more embodiments;

FIG. 1B is a schematic block diagram of the electronic apparatus according to one or more embodiments;

FIG. 2 is a schematic perspective view of a display panel according to one or more embodiments;

FIGS. 3A and 3B are each a perspective view of the display panel of FIG. 2 in a state of being stretched in a first direction;

FIG. 3C is a perspective view of the display panel of FIG. 2 stretched in a second direction;

FIG. 3D is a perspective view of the display panel of FIG. 2 stretched in the first direction and the second direction;

FIG. 3E is a perspective view of the display panel of FIG. 2 stretched in a third direction;

FIG. 4 is a schematic plan view of a display panel according to one or more embodiments;

FIG. 5 is a plan view schematically illustrating an arrangement of pixels of a display panel according to one or more embodiments;

FIG. 6 is a schematic cross-sectional view of a portion of the display panel according to one or more embodiments;

FIGS. 7A-7C are each an equivalent circuit diagram of pixels of a display panel according to one or more embodiments;

FIGS. 8A-8D are each a schematic cross-sectional view of a light-emitting diode of a display panel according to one or more embodiments;

FIG. 9 is a schematic plan view of a portion of a display panel according to one or more embodiments;

FIG. 10 is a schematic cross-sectional view of a portion of a display panel according to one or more embodiments;

FIGS. 11A-11J are cross-sectional views sequentially illustrating operations of a method of manufacturing a display panel, according to one or more embodiments;

FIG. 12 is a schematic cross-sectional view of a portion of a display panel according to one or more other embodiments;

FIGS. 13A-13J are cross-sectional views sequentially illustrating operations of a method of manufacturing a display panel, according to one or more other embodiments;

FIGS. 14A-14I are cross-sectional views sequentially illustrating operations of a method of manufacturing a display panel, according to one or more other embodiments;

FIG. 15 is a schematic cross-sectional view of a portion of a display panel according to one or more other embodiments;

FIGS. 16A-16H are cross-sectional views sequentially illustrating operations of a method of manufacturing a display panel, according to one or more other embodiments;

FIG. 17 is a schematic cross-sectional view of a portion of a display panel according to one or more other embodiments;

FIGS. 18A-18H are cross-sectional views sequentially illustrating operations of a method of manufacturing a display panel, according to one or more other embodiments; and

FIGS. 19A-19G are each a schematic perspective view of one or more embodiments of an electronic apparatus including a display panel according to one or more embodiments.

### DETAILED DESCRIPTION

Reference will now be made in more detail to one or more embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described in more detail herein below, by referring to the drawings, to explain aspects of the present description. As used herein, the term “and/or” includes any and all combinations of one or more of the associated listed items. Throughout the disclosure, the expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As the disclosure allows for one or more suitable changes and numerous embodiments, particular embodiments will be illustrated in the drawings and described in more detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

One or more embodiments will be described below in more detail with reference to the accompanying drawings. Those components that are the same as or are in correspondence with each other are rendered the same reference numeral regardless of the drawing number, and redundant explanations are not provided.

It will be understood that although the terms “first,” “second,” and/or the like may be used herein to describe various components, these components should not be limited by these terms. These components are only used to distinguish one component from another. Thus, a first element could be termed a second element without departing from the teachings of the present invention. Similarly, a second element could be termed a first element.

As used herein, the singular forms “a,” “an,” and “the” are intended to include the plural forms as well, unless the context clearly indicates otherwise.

The terms “includes,” “including,” “comprises” and/or “comprising” used herein specify the presence of stated features or components, but do not preclude the presence or addition of one or more other features or components. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the terms “use,” “using,” and “used” may be considered synonymous with the terms “utilize,”“utilizing,”and “utilized,”respectively.

It will be understood that when a layer, region, or component is referred to as being “formed on” another layer, region, or component, it can be directly or indirectly formed on the other layer, region, or component. For example, for example, intervening layers, regions, or components may be present. In contrast, when an element is referred to as being “directly on,” “directly connected to,” or “directly coupled to” another element, there are no intervening elements present.

Sizes of elements in the drawings may be exaggerated or reduced for convenience of explanation. For example, because sizes and thicknesses of components in the drawings are arbitrarily illustrated for convenience of explanation, embodiments are not limited thereto.

When a certain embodiment may be implemented differently, a specific process order may be performed differently from the described order. For example, two consecutively described processes may be performed substantially at the same time or performed in an order opposite to the described order.

It will also be understood that when a layer, region, or component is referred to as being “connected” or “coupled” to another layer, region, or component, it can be directly connected or coupled to the other layer, region, or component or intervening layers, regions, or components may be present. For example, when a layer, region, or component is referred to as being “electrically connected” or “electrically coupled” to another layer, region, or component, it can be directly electrically connected or coupled to the other layer, region, or component or intervening layers, regions, or components may be present.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above”or “over”the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

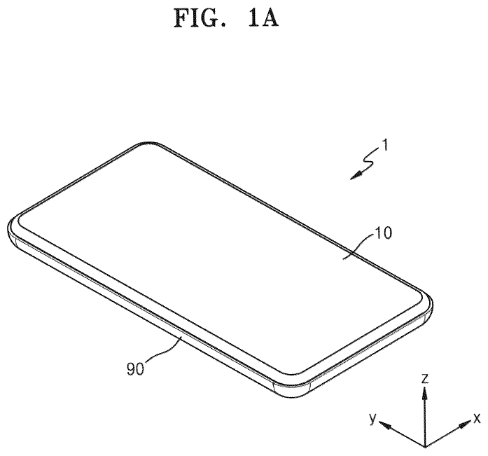

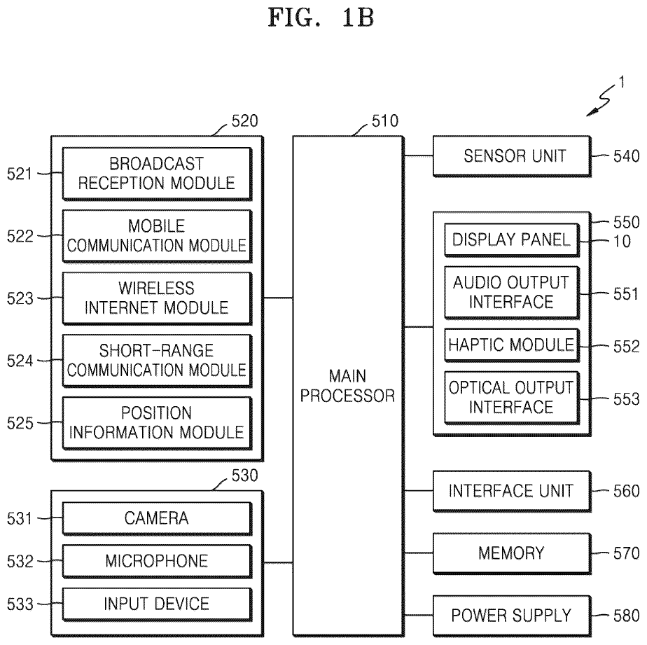

FIG. 1A is a schematic perspective view showing an electronic apparatus 1 according to one or more embodiments, and FIG. 1B is a schematic block diagram of the electronic apparatus 1 according to one or more embodiments.

Referring to FIGS. 1A and 1B, the display apparatus 1 including a display panel 10 according to one or more embodiments displays a moving picture and/or a still image, and thus may be used as the display screens of one or more suitable products including not only portable electronic apparatuses, such as mobile phones, smartphones, tablet personal computers (PCs), mobile communication terminals, electronic notebooks, electronic books, portable multimedia players (PMPs), navigation devices, and/or ultra mobile PCs (UMPCs), but also televisions, notebooks, monitors, advertisement panels, and/or Internet of Things (IoT) devices. The electronic apparatus 1 according to one or more embodiments may be used in wearable devices, such as smart watches, watch phones, glasses-type or kind displays, and/or head mounted displays (HMDs). The electronic apparatus 1 according to one or more embodiments may be used as dashboards of automobiles, center information displays (CIDs) of the center fasciae and/or dashboards of automobiles, room mirror displays that replace the side mirrors of automobiles, and displays arranged on the rear sides of front seats to serve as entertainment devices for back seat passengers of automobiles.

FIG. 1A illustrates use of the electronic apparatus 1 according to one or more embodiments as a smartphone. The electronic apparatus 1 may include the display panel 10, and a lower cover 90 provided below the display panel 10. The electronic apparatus 1 may include a cover window that covers an upper surface of the display panel 10.

The lower cover 90 may form the exterior of the electronic apparatus 1, and may have an opening that exposes a portion of the display panel 10 on a front surface of the lower cover 90. The lower cover 90 may be assembled with the display panel 10 to have a shape in which a surface corresponding to the display panel 10 is open (e.g., has an opening). The lower cover 90 may form the exterior of a lower surface of the electronic apparatus 1, and a display circuit board, components, a main circuit board, a battery, a driver, and/or the like may be arranged between the display panel 10 and the lower cover 90. The lower cover 90 may include plastic, metal, or both (e.g., simultaneously) plastic and metal.

The electronic apparatus 1 may include a main processor 510, a wireless communication interface 520, an input interface 530, a sensor unit 540, an output interface 550, an interface unit 560, a memory 570, and/or a power supply 580.

The main processor 510 may control all functions of the electronic device 1. For example, the main processor 510 may output digital video data to a display driver via the display circuit board so that the display panel 10 displays an image. The main processor 510 may receive sensing data from a touch sensor driver. The main processor 510 may determine whether there is a user's touch, according to the sensor data, and may execute an operation corresponding to a direct touch and/or proximity touch of the user. The main processor 510 may be an application processor, a central processing unit, and/or a system chip, each realized as an integrated circuit (IC).

A camera 531 processes an image frame such as a still image and/or moving picture obtained by the image sensor in a camera mode, and outputs a result of the processing to the main processor 510. The camera 531 may include at least one selected from among a camera sensor (for example, a charge-coupled device (CCD) and/or a complementary metal-oxide-semiconductor (CMOS)), a photo sensor (or an image sensor), and a laser sensor. The camera 531 may be connected to an image sensor and may process an image input to the image sensor.

The wireless communication interface 520 may include at least one selected from among a broadcast reception module 521, a mobile communication module 522, a wireless Internet module 523, a short-distance communication module 524, and a position information module 525.

The broadcast reception module 521 receives a broadcasting signal and/or broadcasting-related information from an external broadcasting management server via a broadcasting channel. The broadcasting channel may be a satellite channel, a ground wave channel, and/or the like.

The mobile communication module 522 transmits and/or receives a wireless signal to and/or from at least one selected from among a base station, an external terminal, and a server on a mobile communication network established according to technology standards and/or communication methods for mobile communication (for example, Global System for Mobile communication (GSM), Code Division Multi Access (CDMA), Code Division Multi Access 2000 (CDMA2000), Enhanced Voice-Data Optimized or Enhanced Voice-Data Only (EV-DO), Wideband CDMA (WCDMA), High Speed Downlink Packet Access (HSDPA), High Speed Uplink Packet Access (HSUPA), Long Term Evolution (LTE), and/or Long Term Evolution-Advanced (LTE-A)). Examples of the wireless signal may include a voice call signal, a video call signal, and one or more suitable types (kinds) of data according to text/multimedia messages transmission.

The wireless Internet module 523 indicates a module for wireless Internet access. The wireless Internet module 523 may be configured to transmit and/or receive a wireless signal in a communication network based on the wireless Internet technologies. The wireless Internet technologies may be, for example, a Wireless LAN (WLAN), Wireless-Fidelity (Wi-Fi), Wi-Fi Direct, and/or Digital Living Network Alliance (DLNA).

The short-distance communication module 524 is for short-range communication, and thus may support short-distance communication by using at least one technology selected from among Bluetooth™, Radio Frequency Identification (RFID), Infrared Data Association (IrDA), Ultra Wideband (UWB), ZigBee, Near Field Communication (NFC), Wi-Fi, Wi-Fi Direct, and/or Wireless Universal Serial Bus (Wireless USB). The short-distance communication module 524 may support wireless communication between the electronic apparatus 1 and a wireless communication system, between the electronic apparatus 1 and another electronic apparatus, and/or between the electronic apparatus 1 and a network where another electronic apparatus (or an external server) is located, through wireless area networks. The wireless area networks may be wireless personal area networks. The other electronic device may be a wearable device capable of exchanging data with (and/or interoperating with) the electronic apparatus 1.

The position information module 525 is included to obtain a position (e.g., a current position) of the electronic apparatus 1, and thus may include a global positioning system (GPS) module and/or a Wireless Fidelity (WiFi) module.

The input interface 530 may include an image input interface such as a camera 531 for inputting an image signal, an audio input interface such as a microphone 532 for inputting an audio signal, and an input device 533 for receiving information from a user.

The camera 531 processes an image frame such as a still image and/or video obtained by the image sensor in a video call mode and/or an image capture mode. A processed image frame corresponding to a result of the processing may be displayed on the display panel 10 and/or may be stored in the memory 570.

The microphone 532 processes an external audio signal into electrical audio data. The electrical audio data may be used in one or more suitable ways according to a function currently being performed (e.g., an application currently being executed) in the electronic apparatus 1.

The main processor 510 may control an operation of the electronic apparatus 1 to correspond to information that is input via the input device 533. The input device 533 may include a mechanical input unit, such as a button, a dome switch, a jog wheel, and/or a jog switch each located on a rear and/or lateral surface of the electronic apparatus 1, and/or a touch input unit. The touch input unit may be implemented as a touch screen layer of the display panel 10.

The sensor unit 540 may include at least one sensor that senses at least one selected from among information within the electronic apparatus 1, information of a surrounding environment of the electronic apparatus 1, and user information, and generates a sensing signal corresponding to the at least one information. Based on such a sensing signal, the main processor 510 may control driving and/or operation of the electronic apparatus 1 and/or may perform data processing, a function, and/or an operation associated with an application provided in the electronic apparatus 1. The sensor unit 540 may include at least one selected from among a proximity sensor, an illumination sensor, an acceleration sensor, a magnetic sensor, a gravity (G)-sensor, a gyroscope sensor, a motion sensor, an RGB sensor, an infrared (IR) sensor, a finger scan sensor, an ultrasonic sensor, an optical sensor, a battery gauge, an environment sensor (e.g., a barometer, a hygrometer, a thermometer, a radiation sensor, a heat sensor, and/or a gas sensor), and a chemical sensor (e.g., an electronic nose, a healthcare sensor, and/or a biometric sensor).

The output interface 550 is to generate an output associated with sight, hearing, and/or tactile sense, and thus may include at least one selected from among the display panel 10, an audio output interface 551, a haptic module 552, and an optical output interface 553.

The display panel 10 displays (outputs) information that is processed by the electronic apparatus 1. For example, the display panel 10 may display execution screen information of an application being driven by the electronic apparatus 1, and/or may display user interface (UI) and graphical user interface (GUI) information based on the execution screen information. The display panel 10 may include a display layer that displays an image, and a touch screen layer that senses a touch input of a user. Accordingly, the display panel 10 may function as the input device 533 providing an input interface between the electronic apparatus 1 and a user, and also function as the output interface 550 providing an output interface between the electronic apparatus 1 and the user.

The audio output interface 551 may output audio data received from the wireless communication interface 520 in a signal reception mode, a call and/or recording mode, a voice recognition mode, a broadcast reception mode, and/or the like, and/or stored in the memory 570. The audio output interface 551 also outputs an audio signal related with a function performed by the electronic apparatus 1 (for example, a call signal receiving sound and/or a message receiving sound). The audio output interface 551 may include a receiver and a speaker. A least one selected from among the receiver and the speaker may be an audio generation device that is attached to a lower portion of the display panel 10 and vibrates the display panel 10 to output an audio. The audio generation device may be a piezoelectric element or piezoelectric actuator that shrinks and expands according to an electrical signal, and/or an exciter that generates a magnetic force by using a voice coil and vibrates the display panel 10.

The haptic module 552 generates one or more suitable tactile effects that a user may feel. The haptic module 552 may provide a user with vibration as a tactile effect (e.g., tactile aspect). The haptic module 552 may be to transmit a tactile effect through direct contract, and may also be implemented such that a user may feel a tactile effect through a muscle sense such as a finger and/or an arm.

The optical output interface 553 outputs a signal for notifying occurrence of an event, by using the light of a light source. Examples of the event generated in the electronic apparatus 1 may include message reception, call signal reception, a missed call, an alarm, schedule notification, e-mail reception, and information reception through an application. The signal output by the optical output interface 553 is implemented as the electronic apparatus 1 emits light of a single color and/or light beams of a plurality of colors to its front surface and/or rear surface. The outputting of the signal may be terminated if (e.g., when) the electronic apparatus 1 senses that a user confirms an event.

The interface unit 560 serves as a passage with one or more suitable types (kinds) of external apparatuses that are connected to the electronic apparatus 1. The interface unit 560 may include at least one selected from among a wired/wireless headset port, an external charger port, a wired/wireless data port, a memory card port, a port connecting a device including an identification module, an audio input/output (I/O) port, a video I/O port, and an earphone port. When an external apparatus is connected to the interface unit 560, the electronic apparatus 1 may perform an appropriate or suitable control related with the connected external apparatus.

The memory 570 may store data that supports one or more suitable functions of the electronic apparatus 1. The memory 570 may store a plurality of application programs driven by the electronic apparatus 1, pieces of data for operations of the electronic apparatus 1, and instructions. At least some of the plurality of application programs may be downloaded from an external server through wireless communication. The memory 570 may store an application for an operation of the main processor 510, and may temporarily store input/output data, for example, a phone book, a message, a still image, and/or a moving picture. The memory 570 may also store haptic data for various patterns of vibration that are provided to the haptic module 552, and audio data about various audios that are provided to the audio output interface 551. The memory 570 may include at least one type or kind of storage medium selected from among a flash memory type or kind, a hard disk type or kind, a solid state disk (SSD) type or kind, a silicon disk drive (SDD) type or kind, a multimedia card micro type or kind, a card type or kind memory (for example, a secure digital (SD) and/or extreme digital (XD) memory), a random access memory (RAM), a static random access memory (SRAM), a read-only memory (ROM), an electrically erasable programmable ROM (EEPROM), a programmable ROM (PROM), magnetic memory, a magnetic disk, and an optical disk.

Under the control of the main processor 510, the power supply 580 receives external power and internal power and supplies the external and internal power to the components included in the electronic apparatus 1. The power supply 580 may include a battery. The power supply 580 includes a connection port that may be an example of the interface unit 560 to which an external charger supplying power to charge the battery is electrically connected. In one or more embodiments, the power supply 580 may be configured to charge the battery in a wireless manner without using a connection port.

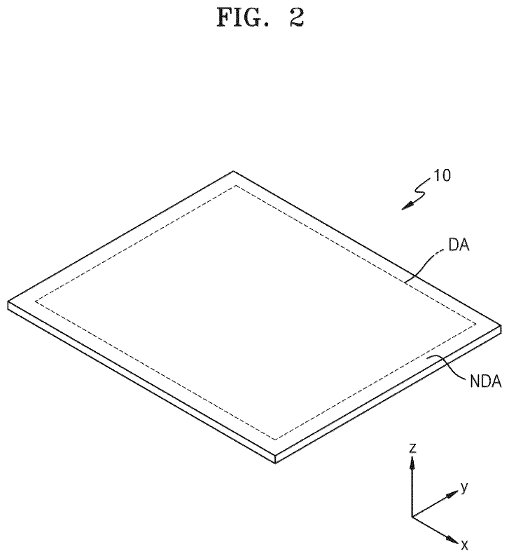

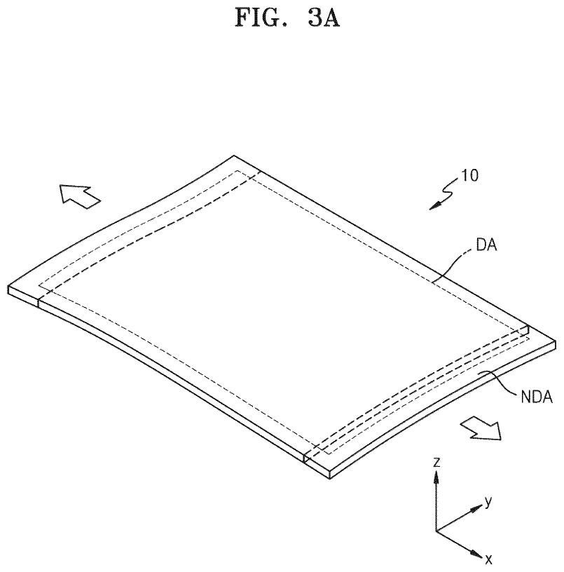

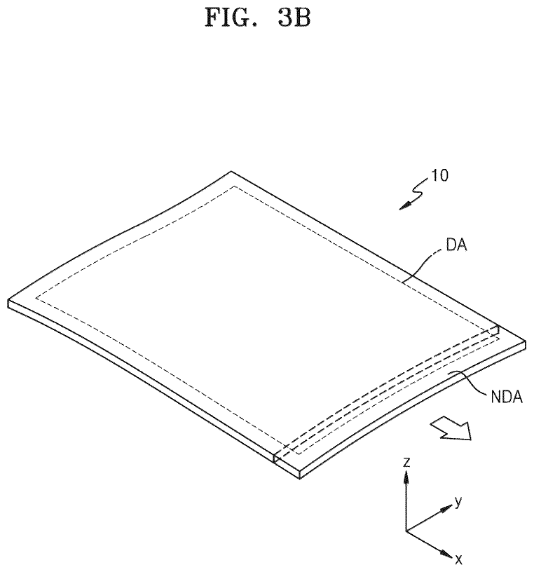

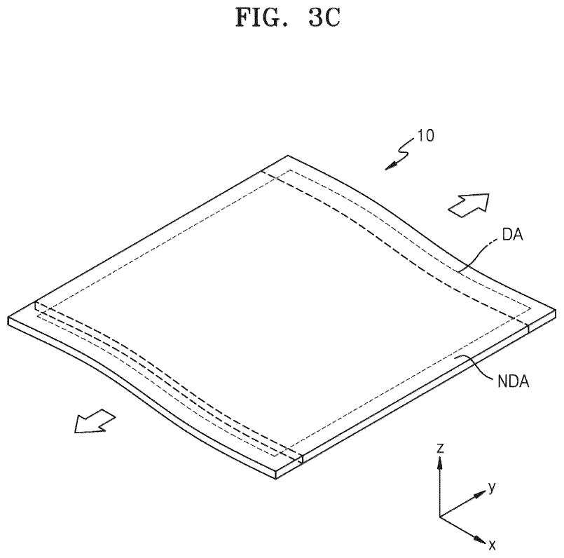

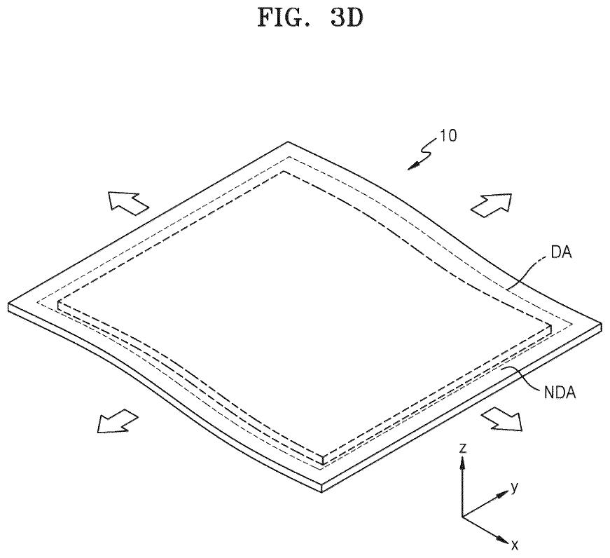

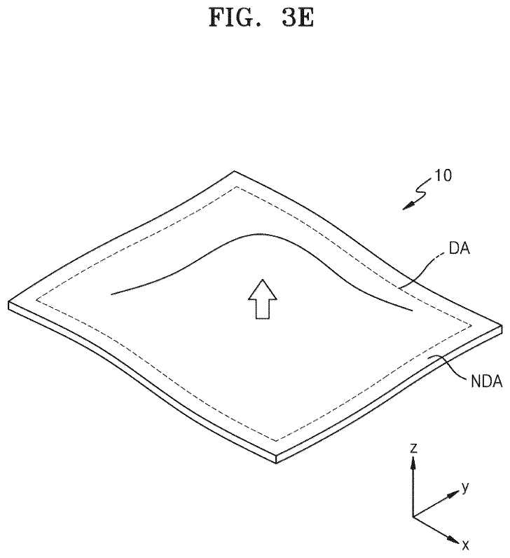

FIG. 2 is a schematic perspective view of the display panel 10 according to one or more embodiments. FIGS. 3A and 3B are perspective views of the display panel 10 of FIG. 2 in a state of being stretched in a first direction. FIG. 3C is a perspective view of the display panel 10 of FIG. 2 in a state of being stretched in a second direction. FIG. 3D is a perspective view of the display panel 10 of FIG. 2 in a state of being stretched in the first direction and the second direction. FIG. 3E is a perspective view of the display panel 10 of FIG. 2 in a state of being stretched in a third direction.

Referring to FIG. 2, the display panel 10 may include a display area DA and a non-display area NDA. The display area DA may include a plurality of pixels. The display panel 10 may provide a set or predetermined image by using light emitted by the plurality of pixels. The non-display area NDA may be arranged outside the display area DA. The non-display area NDA may be around (e.g., may surround) the entirety of the display area DA.

The display panel 10 may expand and/or contract in one or more suitable directions. The display panel 10 may be stretched in the first direction (e.g., an x direction and/or an −x direction) due to an external force applied by an external object and/or a user. According to one or more embodiments, as shown in FIGS. 3A and 3B, the display area DA and/or the non-display area NDA of the display panel 10 may be stretched in the x direction (for example, the x direction and/or the −x direction). For example, the display area DA and/or the non-display area NDA may be stretched in the x direction and the −x direction as shown in FIG. 3A, and/or may be stretched in the x direction with one side of the display panel 10 fixed as shown in FIG. 3B.

The display panel 10 may be stretched in the second direction (e.g., a y direction and/or a −y direction) due to an external force exerted by an external object and/or a user. According to one or more embodiments, as shown in FIG. 3C, the display area DA and/or the non-display area NDA of the display panel 10 may be stretched in the y direction and/or the −y direction. According to another embodiment, the display area DA and/or the non-display area NDA may be stretched in the y direction or the −y direction with one side of the display panel 10 fixed.

The display panel 10 may be stretched in a plurality of directions, for example, the first direction (e.g., the x direction and/or the −x direction) and the second direction (e.g., the y direction and/or the −y direction) due to an external force exerted by an external object and/or a portion of a human body. As shown in FIG. 3D, the display area DA and/or the non-display area NDA of the display panel 10 may be stretched in the ±x direction and the ±y direction.

The display panel 10 may be stretched in the third direction (e.g., a z direction and/or a −z direction) due to an external force exerted by an external object and/or a portion of a human body. According to one or more embodiments, it is shown in FIG. 3E that a portion of the display panel 10, for example, a partial region of the display area DA, protrudes in the +z direction. According to another embodiment, a portion of the display panel 10, for example, a partial region of the display area DA, may protrude in the −z direction (or may be depressed in the −z direction).

Although it is shown in FIGS. 3A through 3E that the display panel 10 is stretched in the first direction, the second direction, and/or the third direction, embodiments are not limited thereto. According to some embodiments, the display panel 10 may be transformed into one or more suitable irregular shapes such as being bent and/or twisted along two or more axes.

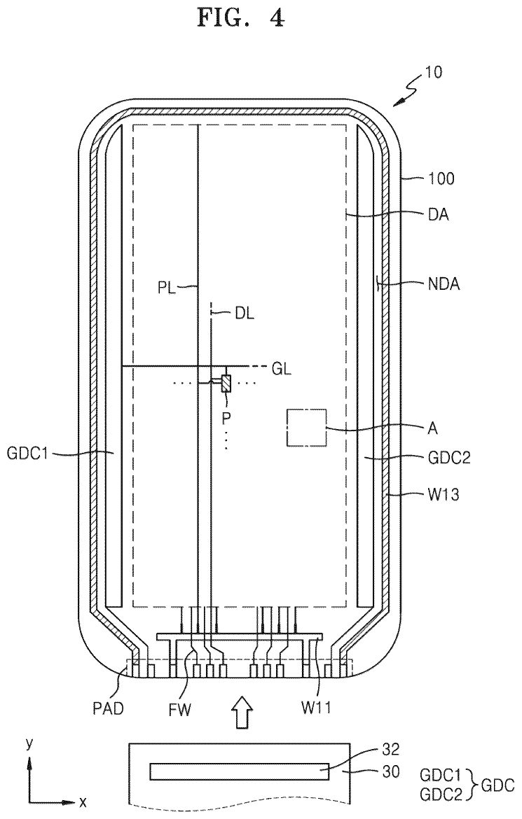

FIG. 4 is a schematic plan view of the display panel 10 according to one or more embodiments.

Referring to FIG. 4, the display panel 10 may include the display area DA and the non-display area NDA outside the display area DA. On the display area DA of a substrate 100, a plurality of pixels PX may be arranged. Each of the plurality of pixels P may display an image by using light emitted from a light-emitting element such as a light-emitting diode. Each of the light-emitting diodes may be to emit, for example, red light, green light, or blue light.

Each of the light-emitting diodes may be electrically connected to a pixel circuit, and each of the pixel circuits may include transistors and a storage capacitor.

Each of the pixel circuits may be electrically connected to peripheral circuits and peripheral wires arranged in the non-display area NDA. The peripheral circuits arranged in the non-display area NDA may include a gate driving circuit GDC and a terminal portion PAD. The peripheral wires may include driving voltage supply wiring W11, common voltage supply wiring W13, and fan-out wiring FW.

The gate driving circuit GDC may include drivers configured to provide electrical signals to respective gate electrodes of the transistors electrically connected to the light-emitting elements. For example, the gate driving circuit GDC may apply a scan signal to each of the pixel circuits corresponding to the pixels P via a gate line GL.

The gate driving circuit GDC may include a first gate driving circuit GDC1 and a second gate driving circuit GDC2 respectively arranged on two opposite (e.g., facing) sides with the display area DA therebetween. The second gate driving circuit GDC2 may be located on a side of the display area DA that is opposite to the side where the first gate driving circuit GDC1 is located, and may be approximately (or substantially) parallel to the first gate driving circuit GDC1. Some of the pixel circuits may be electrically connected to the first gate driving circuit GDC1, and the remaining pixel circuits may be electrically connected to the second gate driving circuit GDC2. According to some embodiments, the second gate driving circuit GDC2 may not be included.

The terminal portion PAD may be arranged on one side of the substrate 100. The terminal portion PAD may be exposed without being covered by an insulating layer, and may be connected to a display circuit board 30. A display driver 32 may be arranged on the display circuit board 30. The display driver 32 may generate a control signal that is transmitted to the first gate driving circuit GDC1 and the second gate driving circuit GDC2. The display driver 32 may generate a data signal, and the generated data signal may be transmitted to the pixel circuits of the pixels P via the fanout wiring FW and data lines DL connected to the fanout wiring FW.

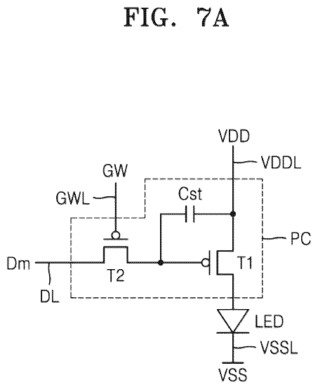

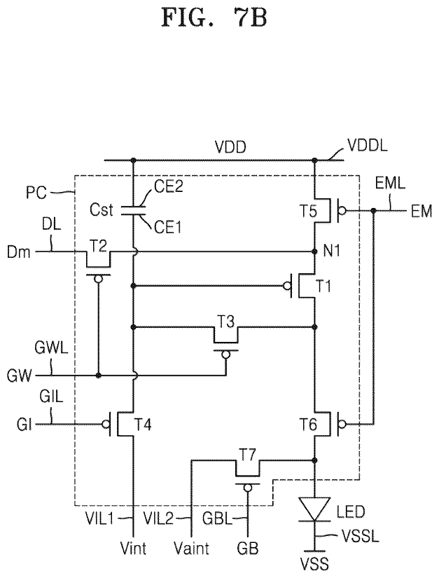

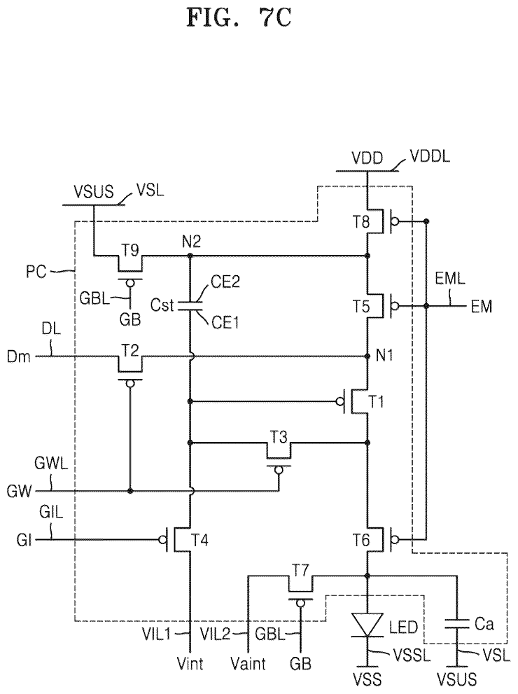

The display driver 32 may supply a first power supply voltage VDD of FIG. 7A to the driving voltage supply wiring W11, and may supply a second power supply voltage VSS of FIG. 7A to the common voltage supply wiring W13. The first power supply voltage VDD of FIG. 7A may be applied to the pixel circuit of a pixel P via a driving voltage line PL connected to the driving voltage supply wiring W11, and the second power supply voltage VSS of FIG. 7A may be connected to the common voltage supply wiring W13 and thus may be applied to an opposite electrode of each light-emitting element. The driving voltage supply wiring W11 may extend on a lower side of the display area DA in the x direction. The common voltage supply wiring W13 may partially surround the display area DA by having a loop shape of which one side is open.

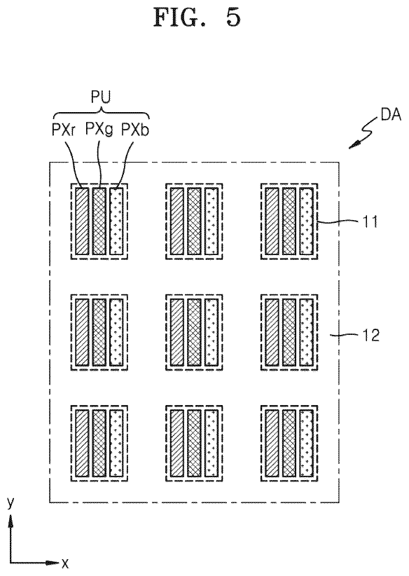

FIG. 5 is a plan view schematically illustrating an arrangement of the pixels of a display panel according to one or more embodiments.

Referring to FIG. 5, a plurality of pixels PXr, PXg, and PXb may be arranged in the display area DA of the display panel 10. The display area DA may include a pixel area 11 and a connection area 12 outside the pixel area 11. A red pixel PXr, a green pixel PXg, and a blue pixel PXb may be arranged in the pixel area 11. The red pixel PXr, the green pixel PXg, and the blue pixel PXb may form one pixel unit PU. In the display area DA, pixel units PU may be arranged repeatedly.

Signal lines electrically connected (e.g., electrically coupled) to adjacent pixels may be arranged in the connection area 12. Each of the signal lines may include a first portion arranged in the pixel area 11 and electrically connected to a pixel circuit, and a second portion arranged in the connection area 12 and connecting adjacent pixel circuits to each other. The first portion and the second portion may include different materials from each other. In the specification, the second portion of each of the signal lines may be referred to as a connection wire.

The connection area 12 may be stretched relatively more than the pixel area 11, if (e.g., when) the display panel 10 is stretched. According to one or more embodiments, connection wires arranged in the connection area 12 may include a material having both (e.g., simultaneously) excellent or suitable elasticity and electrical properties. For example, the connection wires arranged in the connection area 12 may include liquid metal, and/or the like. The pixel areas 11 may be arranged at regular intervals in the first direction (e.g., the x direction) and the second direction (e.g., the y direction).

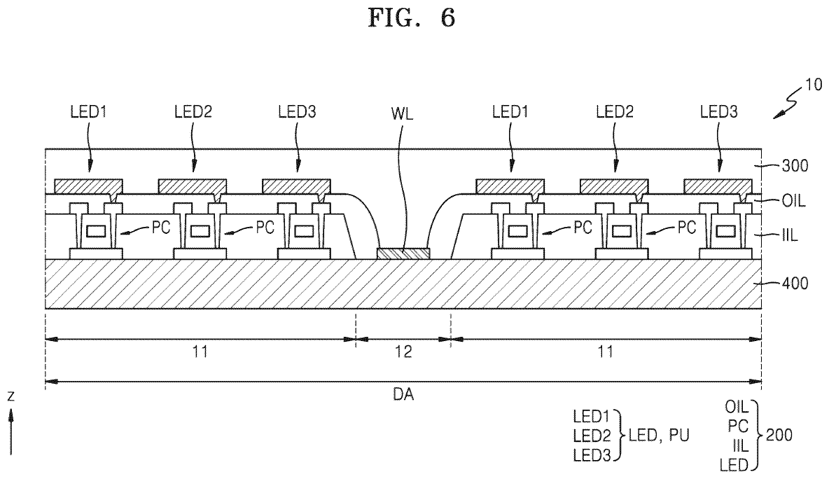

FIG. 6 is a schematic cross-sectional view of a portion of the display panel 10 according to one or more embodiments.

Referring to FIG. 6, the display area DA may include pixel areas 11 and a connection area 12, and the connection area 12 may be an area that connects pixel areas 11 that are arranged adjacent to each other. Each of the pixel areas 11 may include a light-emitting diode LED, and a circuit for driving the light-emitting diode LED, for example, a pixel circuit PC. The connection area 12 may include connection wiring WL included in a signal line that supplies a signal to each of the pixel circuits PC.

The pixel area 11 and the connection area 12 may be formed on a lower elastomer layer 400. For example, the lower elastomer layer 400 may define the pixel areas 11 and the connection area 12. The light-emitting diode LED and the pixel circuit PC may be arranged on the pixel area 11 of the lower elastomer layer 400, and the connection wiring WL may be arranged on the connection area 12 of the lower elastomer layer 400.

The lower elastomer layer 400 may be to absorb stress that may be generated if (e.g., when) the display panel 10 is stretched. The lower elastomer layer 400 may include an elastic polymer. For example, the lower elastomer layer 400 may include at least one selected from among thermoplastic polyurethane, silicon, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and ecoflex.

A display layer 200 may be arranged on the pixel area 11 of the lower elastomer layer 400. The display layer 200 may include an inorganic insulating layer IIL, a pixel circuit PC, an organic insulating layer OIL, and a light-emitting diode LED. The pixel circuit PC may be arranged on the lower elastomer layer 400, and the inorganic insulating layer IIL may be arranged between electrodes included in the pixel circuit PC. The organic insulating layer OIL may be arranged on the inorganic insulating layer IIL to cover the pixel circuit PC. The light-emitting diode LED may be arranged on the organic insulating layer OIL, and may be electrically connected to the pixel circuit PC corresponding to the light-emitting diode LED. The inorganic insulating layer IIL may include an inorganic insulating material, such as silicon nitride and/or silicon oxide, and the organic insulating layer OIL may include an organic insulating material, such as polyimide.

According to one or more embodiments, one pixel unit PU may be arranged on one pixel area 11. As described above, the pixel unit PU may include the red pixel PXr of FIG. 5, the green pixel PXg of FIG. 5, and the blue pixel PXb of FIG. 5. The red pixel PXr of FIG. 5 may include a first light-emitting diode LED1, the green pixel PXg of FIG. 5 may include a second light-emitting diode LED2, and the blue pixel PXb of FIG. 5 may include a third light-emitting diode LED3. For example, the first light-emitting diode LED1 may be to emit red light, the second light-emitting diode LED2 may be to emit green light, and the third light-emitting diode LED3 may be to emit blue light. According to some embodiments, the light-emitting diode LED may be to emit white light.

The connection wiring WL may be arranged on the connection area 12 of the lower elastomer layer 400. According to one or more embodiments, as shown in FIG. 6, the connection wiring WL may be arranged on the lower elastomer layer 400. According to some embodiments, the connection wiring WL may be arranged within (e.g., inside) the lower elastomer layer 400. The connection wiring WL may include a material having both (e.g., simultaneously) excellent or suitable elasticity and electrical properties. According to one or more embodiments, the connection wires arranged in the connection area 12 may include a liquid metal. According to some embodiments, the connection wires may include a metal nanostructure and an elastic polymer. According to one or more other embodiments, the connection wires may include a conductive composite material including an elastomer.

The organic insulating layer OIL may be arranged on the connection area 12 of the lower elastomer layer 400. According to one or more embodiments, the organic insulating layer OIL arranged in the connection area 12 may be a portion of the organic insulating layer OIL arranged in the pixel area 11 that extends to the connection area 12. When the display panel 10 is stretched, the connection area 12 may be deformed relatively more than the pixel area 11. Accordingly, a layer including an inorganic insulating material that is prone to cracking may not exist (e.g., may not be arranged) in the connection area 12, unlike in the pixel area 11.

According to one or more embodiments, an upper elastomer layer 300 may be arranged on the light-emitting diode LED. The upper elastomer layer 300 may be arranged in both (e.g., simultaneously) the pixel area 11 and the connection area 12.

For example, the upper elastomer layer 300 may be arranged to cover the entirety of the display area DA. The upper elastomer layer 300 may cover the light-emitting diode LED and the connection wiring WL. The upper elastomer layer 300 may be to absorb stress that may be generated if (e.g., when) the display panel 10 is stretched. For example, the upper elastomer layer 300 may prevent or reduce transmission of stress generable if (e.g., when) the display panel 10 is stretched from being transmitted to the light-emitting diode LED and the pixel circuit PC.

The upper elastomer layer 300 may include an elastic polymer. The upper elastomer layer 300 may include at least one selected from among thermoplastic polyurethane, silicon, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, and polydimethylsiloxane (PDMS). According to one or more embodiments, the upper elastomer layer 300 may include the same material as that included in the lower elastomer layer 400. However, embodiments are not limited thereto, and the upper elastomer layer 300 may include a different material from that included in the lower elastomer layer 400.

FIGS. 7A through 7C are each an equivalent circuit diagram of pixel(s) of a display panel according to one or more embodiments.

Referring to FIG. 7A, a light-emitting diode LED corresponding to a pixel may be electrically connected to a pixel circuit PC, and the pixel circuit PC may include a first transistor T1, a second transistor T2, and a storage capacitor Cst. The pixel circuit PC may be electrically connected to signal lines and voltage lines. The signal lines may include the gate line GL of FIG. 4, such as a scan signal line GWL and/or a data line DL, and the voltage lines may include a first voltage line VDDL. The first voltage line VDDL may be connected to the driving voltage supply wiring W11 of FIG. 4, and a second voltage line VSSL may be connected to the common voltage supply wiring W13 of FIG. 4.

The second transistor T2 may be electrically connected to the scan signal line GWL and the data line DL. The scan signal line GWL may be configured to provide a scan signal GW to a gate electrode of the second transistor T2. The second transistor T2 may be configured to transfer a data signal Dm to the first transistor T1 according to the scan signal GW input from the scan signal line GWL, wherein the data signal Dm is input from the data line DL.

The storage capacitor Cst may be electrically connected to the second transistor T2 and the first voltage line VDDL, and may store a voltage corresponding to a difference between a voltage received from the second transistor T2 and the first power supply voltage VDD supplied by the first voltage line VDDL.

The first transistor T1, which is a driving transistor, may be configured to control a driving current flowing through the light-emitting diode LED. The first transistor T1 may be connected to the first voltage line VDDL and the storage capacitor Cst. The first transistor T1 may control a driving current flowing from the first voltage line VDDL to the light-emitting diode LED according to a voltage value stored in the storage capacitor Cst. The light-emitting diode LED may be to emit light having a set or predetermined brightness due to the driving current. A first electrode of the light-emitting diode LED may be electrically connected to the first transistor T1, and a second electrode of the light-emitting diode LED may be electrically connected to the second voltage line VSSL configured to supply the second power supply voltage VSS.

In FIG. 7A, the pixel circuit PC includes two transistors and one storage capacitor. However, according to some embodiments, the pixel circuit PC may include three or more transistors.

Referring to FIG. 7B, the pixel circuit PC may include a first transistor T1, a second transistor T2, a third transistor T3, a fourth transistor T4, a fifth transistor T5, a sixth transistor T6, a seventh transistor T7, and a storage capacitor Cst.

The pixel circuit PC is electrically connected to signal lines and voltage lines. The signal lines may include gate lines GL of FIG. 4, such as a scan signal line GWL, a bypass control line GBL, an initialization control line GIL, and/or a light-emission control line EML, and a data line DL. The voltage lines may include first and second initializing voltage lines VIL1 and VIL2 and the first voltage line VDDL. The first voltage line VDDL may be connected to the driving voltage supply wiring W11 of FIG. 4, and the second voltage line VSSL may be connected to the common voltage supply wiring W13 of FIG. 4.

The first voltage line VDDL may be to transmit the first power supply voltage VDD to the first transistor T1. The first initializing voltage line VIL1 may be to transmit, to the pixel circuit PC, a first initializing voltage Vint that initializes the first transistor T1. The second initializing voltage line VIL2 may be to transmit, to the pixel circuit PC, a second initializing voltage Vaint that initializes a first electrode of the light-emitting diode LED.

The first transistor T1 may be electrically connected to the first voltage line VDDL through the fifth transistor T5, and may be electrically connected to the light-emitting diode LED through the sixth transistor T6. The first transistor T1 may serve as a driving transistor, and may receive a data signal Dm according to a switching operation of the second transistor T2 and supply a driving current to the light-emitting diode LED.

The second transistor T2, which is a data write transistor, may be electrically connected to the scan signal line GWL and the data line DL. The second transistor T2 may be electrically connected to the first voltage line VDDL through the fifth transistor T5. The second transistor T2 may be turned on in response to a scan signal GW received through the scan signal line GWL, to perform a switching operation of transmitting the data signal Dm received through the data line DL to a first node N1.

The third transistor T3 may be electrically connected to the scan signal line GWL, and may be electrically connected to the light-emitting diode LED via the sixth transistor T6. The third transistor T3 may be turned on in response to the scan signal GW received through the scan signal line GWL, to diode-connect the first transistor T1.

The fourth transistor T4, which is a first initialization transistor, may be electrically connected to the initialization control line GIL and the first initializing voltage line VIL1. The fourth transistor T4 may be turned on in response to an initialization control signal GI received through the initialization control line GIL, and transmit the first initializing voltage Vint from the first initializing voltage line VIL1 to the gate electrode of the first transistor T1 to thereby initialize the voltage of the gate electrode of the first transistor T1. The initialization control signal GI may correspond to a scan signal of another pixel circuit arranged in a row previous to the row of the current pixel circuit PC.

The fifth transistor T5 may be an operation control transistor, and the sixth transistor T6 may be a light-emission control transistor. The fifth transistor T5 and the sixth transistor T6 may be electrically connected to the light-emission control line EML, and may be concurrently (e.g., simultaneously) turned on according to a light-emission control signal EM received through the light-emission control line EML and form a current path so that the driving current flows from the first voltage line VDDL toward the light-emitting diode LED.

The seventh transistor T7, which is a second initialization transistor, may be electrically connected to the bypass control line GBL, the second initializing voltage line VIL2, and the sixth transistor T6. The seventh transistor T7 may be turned on according to a bypass control signal GB received through the bypass control line GBL, and may be configured to transfer the second initializing voltage Vaint from the second initializing voltage line VIL2 to the first electrode of the light-emitting diode LED to thereby initialize the first electrode of the light-emitting diode LED.

The storage capacitor Cst includes a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may maintain a voltage applied to the gate electrode of the first transistor T1 by storing and maintaining a voltage corresponding to a difference between the voltage of the first voltage line VDDL and the voltage of the gate electrode of the first transistor T1.

Referring to FIG. 7C, the pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel circuit PC may be electrically connected to signal lines and voltage lines. The signal lines may include gate lines GL of FIG. 4, such as a scan signal line GWL, a bypass control line GBL, an initialization control line GIL, and/or a light-emission control line EML, and a data line DL. The voltage lines may include first and second initializing voltage lines VIL1 and VIL2, a sustain voltage line VSL, and the first voltage line VDDL. The first voltage line VDDL may be connected to the driving voltage supply wiring W11 of FIG. 4, and the second voltage line VSSL may be connected to the common voltage supply wiring W13 of FIG. 4.

The first voltage line VDDL may be to transmit the first power supply voltage VDD to the first transistor T1. The first initializing voltage line VIL1 may be to transmit, to the pixel circuit PC, a first initializing voltage Vint that initializes the first transistor T1. The second initializing voltage line VIL2 may be to transmit, to the pixel circuit PC, a second initializing voltage Vaint that initializes a first electrode of the light-emitting diode LED. The sustain voltage line VSL may be configured to provide a sustain voltage VSUS to a second node N2, for example, to the second electrode CE2 of the storage capacitor Cst, during an initialization section and/or a data-write section.

The first transistor T1 may be electrically connected to the first voltage line VDDL through the fifth transistor T5 and the eighth transistor T8, and may be electrically connected to the light-emitting diode LED through the sixth transistor T6. The first transistor T1 may serve as a driving transistor, and may receive a data signal Dm according to a switching operation of the second transistor T2 and supply a driving current to the light-emitting diode LED.

The second transistor T2 may be electrically connected to the scan signal line GWL and the data line DL, and may be electrically connected to the first voltage line VDDL via the fifth transistor T5 and the eighth transistor T8. The second transistor T2 may be turned on in response to a scan signal GW received through the scan signal line GWL, to perform a switching operation of transmitting the data signal Dm received through the data line DL to a first node N1.

The third transistor T3 may be electrically connected to the scan signal line GWL, and may be electrically connected to the light-emitting diode LED via the sixth transistor T6. The third transistor T3 may be turned on in response to the scan signal GW received through the scan signal line GWL to diode-connect the first transistor T1, thereby compensating for a threshold voltage of the first transistor T1.

The fourth transistor T4 may be electrically connected to the initialization control line GIL and the first initializing voltage line VIL1, and may be turned on in response to an initialization control signal GI received through the initialization control line GIL and may transmit the first initializing voltage Vint from the first initializing voltage line VIL1 to the gate electrode of the first transistor T1 to thereby initialize the voltage of the gate electrode of the first transistor T1. The initialization control signal GI may correspond to a scan signal of another pixel circuit arranged in a row previous to the row of the current pixel circuit PC.

The fifth transistor T5, the sixth transistor T6, and the eighth transistor T8 may be electrically connected to the light-emission control line EML, and may be concurrently (e.g., simultaneously) turned on according to a light-emission control signal EM received through the light-emission control line EML and form a current path so that the driving current flows from the first voltage line VDDL toward the light-emitting diode LED.

The seventh transistor T7, which is a second initialization transistor, may be electrically connected to the bypass control line GBL, the second initializing voltage line VIL2, and the sixth transistor T6. The seventh transistor T7 may be turned on according to a bypass control signal GB received through the bypass control line GBL, and may be configured to transfer the second initializing voltage Vaint from the second initializing voltage line VIL2 to the first electrode of the light-emitting diode LED to thereby initialize the first electrode of the light-emitting diode LED.

The ninth transistor T9 may be electrically connected to the bypass control line GBL, the second electrode CE2 of the storage capacitor Cst, and the sustain voltage line VSL. The ninth transistor T9 may be turned on according to the bypass control signal GB transferred through the bypass control line GBL, and may be configured to transfer the sustain voltage VSUS to the second node N2, for example, the second electrode CE2 of the storage capacitor Cst, during the initialization section and/or the data-write section.

Each of the eighth transistor T8 and the ninth transistor T9 may be electrically connected to the second node N2, for example, the second electrode CE2 of the storage capacitor Cst. According to some embodiments, during the initialization section and/or the data-write section, the eighth transistor T8 may be turned off and the ninth transistor T9 may be turned on, and, during an emission section, the eighth transistor T8 may be turned on and the ninth transistor T9 may be turned off. Because, during the initialization section and the data-write section, the sustain voltage VSUS is transferred to the second node N2, uniformity (or substantial uniformity) in brightness of the display apparatus (e.g., long range uniformity (LRU)) according to a voltage drop of the first voltage line VDDL may be improved.

The storage capacitor Cst includes a first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustain voltage line VSL, and the first electrode of the light-emitting diode LED. While the seventh transistor T7 and the ninth transistor T9 are being turned on, the auxiliary capacitor Ca stores and maintains a voltage corresponding to a difference between the voltage of the first electrode of the light-emitting diode LED and the voltage of the sustain voltage line VSL, thereby preventing or reducing a black brightness from rising if (e.g., when) the sixth transistor T6 is turned off.

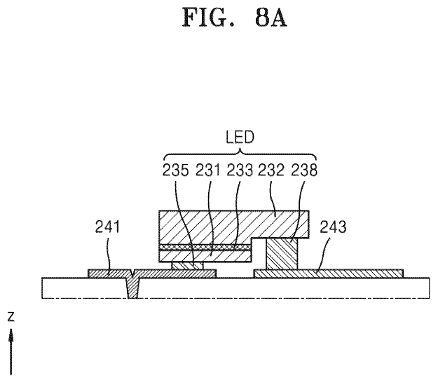

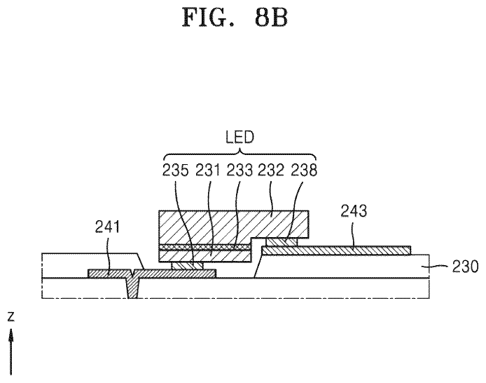

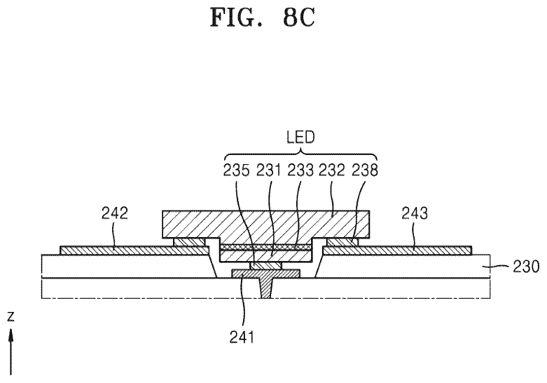

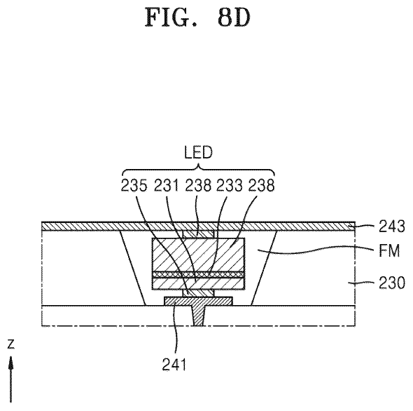

FIGS. 8A through 8D are each a schematic cross-sectional view of s light-emitting diode of a display panel according to one or more embodiments.

Referring to FIG. 8A, a light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be electrically connected to a first electrode pad 241 and a second electrode pad 243, respectively, arranged on the same layer. The second electrode pad 243 may be a portion of the second voltage line VSSL of FIG. 7A, or may be a conductive layer electrically connected to the second voltage line VSSL of FIG. 7A.

According to some embodiments, the first semiconductor layer 231 may include a p-type semiconductor layer. The p-type semiconductor layer may be selected from among semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, and/or AlInN, and may be doped with a p-type dopant such as Mg, Zn, Ca, Sr, and/or Ba.

The second semiconductor layer 232 may include, for example, an n-type semiconductor layer. The n-type semiconductor layer may be selected from among semiconductor materials having a composition formula of InₓAl_{y}Ga_{1-x-y}N (0≤x≤1, 0≤y≤1, 0≤x+y≤1), for example, GaN, AlN, AlGaN, InGaN, InN, InAlGaN, and/or AlInN, and may be doped with an n-type dopant such as Si, Ge, and/or Sn.

The intermediate layer 233, in which electrons and holes are recombined, may transit (e.g., transition) to a suitably low energy level due to recombination between electrons and holes, and may generate light having a wavelength corresponding to the suitably low energy level. The intermediate layer 233 may be formed by including a semiconductor material having a composition formula of InₓAl_{y}Ga_{1-x-y}N (0≤x≤1, 0≤y≤1, 0≤x+y≤1), and may have a single quantum well structure or a multi-quantum well (MQW) structure. In one or more embodiments, the intermediate layer 233 may have a quantum wire structure or a quantum dot structure.

It has been described with reference to FIG. 8A that the first semiconductor layer 231 includes a p-type semiconductor layer and the second semiconductor layer 232 includes an n-type semiconductor layer, but embodiments are not limited thereto. According to some embodiments, the first semiconductor layer 231 may include an n-type semiconductor layer, and the second semiconductor layer 232 may include a p-type semiconductor layer.

Although it is shown in FIG. 8A that the first electrode pad 241 and the second electrode pad 243 are arranged on the same layer, embodiments are not limited thereto. Referring to FIG. 8B, the first electrode pad 241 and the second electrode pad 243 may be arranged on different layers. For example, a bank layer 230 having an opening overlapping at least a portion of the first electrode pad 241 may be arranged on the first electrode pad 241, and the second electrode pad 243 may be arranged on an upper surface of the bank layer 230. The structure of the light-emitting diode LED shown in FIG. 7B is the same as that described above with reference to FIG. 7A.

According to one or more embodiments, as shown in FIG. 8C, second electrode pads 243 may be arranged on both (e.g., simultaneously) sides (e.g., opposite sides) of the first electrode pad 241, respectively, in the cross-sectional view. A bank layer 230 may include an opening overlapping at least a portion of the first electrode pad 241, and the second electrode pad 243 may be arranged around the opening of the bank layer 230. According to some embodiments, in a plan view, the second electrode pad 243 may have a closed loop shape that entirely surrounds the opening of the bank layer 230 and/or the first electrode pad 241. The structure of the light-emitting diode LED shown in FIG. 7C is the same as that described above with reference to FIG. 7A.

Although FIGS. 8A through 8C illustrate that the first electrode 235 and the second electrode 238 of the light-emitting diode LED face the same direction (e.g., a downward direction or a −z direction), embodiments are not limited thereto. As shown in FIG. 8D, the first electrode 235 and the second electrode 238 of the light-emitting diode LED may face opposite directions.

The bank layer 230 may include an opening exposing at least a portion of the first electrode pad 241, and a thickness of the bank layer 230 may be substantially the same as a thickness of the light-emitting diode LED. The opening of the bank layer 230 may be filled with a filling material FM, and the second electrode pad 243 may be arranged on the upper surface of the bank layer 230 so as to be electrically connected (e.g., in contact) with the second electrode 238 of the light-emitting diode LED. The filling material may be an organic material having insulating properties.

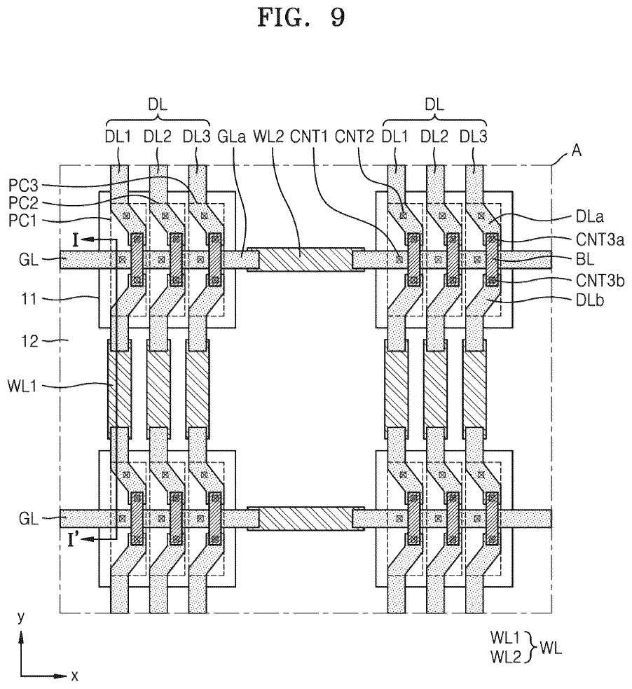

FIG. 9 is a schematic plan view of a portion of a display panel according to one or more embodiments.

Referring to FIG. 9, the display area DA of FIG. 4 may include a plurality of pixel areas 11, and a connection area 12 around (e.g., surrounding) each of the plurality of pixel areas 11. The plurality of pixel areas 11 may be repeatedly arranged in the first direction (e.g., the x direction) and the second direction (e.g., the y direction). A distance between adjacent pixel areas 11 in the first direction (e.g., the x direction) may have a constant (or substantially constant) interval, and a distance between adjacent pixel areas 11 in the second direction (e.g., the y direction) may also have a constant (or substantially constant) interval.

As described above with reference to FIG. 5, at least one pixel may be arranged in the pixel area 11. The pixel may be one selected from among the red pixel PXr of FIG. 5, the green pixel PXg of FIG. 5, and the blue pixel PXb of FIG. 5. For example, a pixel unit PU including a group of pixels may be provided in the pixel area 11. The pixel unit PU may include the red pixel PXr of FIG. 5, the green pixel PXg of FIG. 5, and the blue pixel PXb of FIG. 5.

Each pixel may include the light-emitting diode LED of FIG. 6 and the pixel circuit PC for driving the light-emitting diode LED. For example, the red pixel PXr of FIG. 5 may include the first light-emitting diode LED1 of FIG. 6 and a first pixel circuit PC1 electrically connected to the first light-emitting diode LED1 of FIG. 6. The green pixel PXg of FIG. 5 may include the second light-emitting diode LED2 of FIG. 6 and a second pixel circuit PC2 electrically connected to the second light-emitting diode LED2 of FIG. 6. The blue pixel PXb of FIG. 5 may include the third light-emitting diode LED3 of FIG. 6 and a third pixel circuit PC3 electrically connected to the third light-emitting diode LED3 of FIG. 6. For example, the first, second, and third light-emitting diodes LED1, LED2, and LED3 of FIG. 6 and the first, second, and third pixel circuits PC1, PC2, and PC3 may be arranged in the pixel area 11.

The pixel area 11 may have a larger modulus (e.g., modulus of elasticity) than the connection area 12 around the pixel area 11. Accordingly, if (e.g., when) the display panel is stretched, the pixel area 11 may be less deformed (e.g., may be deformed to a relatively lesser degree) than the connection area 12. The pixel area 11 may be referred to as an island portion and/or a low-deformation portion. The pixel area 11, which is an area where light-emitting elements are arranged, may also be referred to as an emission area.

The connection area 12 may be arranged to surround the pixel area 11, and may have a smaller modulus (e.g., modulus of elasticity) than the pixel area 11. The connection area 12 may be an area where relatively major deformation occurs according to stretching of the display panel. The connection area 12 may be arranged between a plurality of pixel areas 11, and may be referred to as a connection portion and/or bridge portion that connects the pixel areas 11 to each other. The connection area 12 may also be referred to as a main deformation portion and/or a high-deformation portion. The connection area 12, which is an area in the display area DA where no light-emitting elements are arranged, may be referred to as a non-light-emitting area. Connection wiring WL that electrically connect adjacent pixel circuits to each other may be arranged in the connection area 12.

In the display area DA of FIG. 4, signal lines connected to each of the first, second, and third pixel circuits PC1, PC2, and PC3 may be arranged. The signal lines may include first, second, and third data lines DL1, DL2, and DL3 each extending in the second direction (e.g., the y direction) and a gate line GL extending in the first direction (e.g., the x direction).

For example, a data line DL may include a first portion DLa arranged in the pixel area 11, a bridge line BL, a second portion DLb, and first connection wiring WL1 arranged in the connection area 12. The first portion DLa of the data line DL may be electrically connected to a pixel circuit through a second contact hole CNT2.

The bridge line BL, which is arranged in an intersection between the data line DL and the gate line GL, may be a pattern that connects the first portion DLa and the second portion DLb of the data line DL to each other. The bridge line BL may be arranged on a different layer than a layer on which the first portion DLa and the second portion DLb are arranged. One end of the bridge line BL may be connected to the first portion DLa through a 3-1 contact hole CNT3a, and the other end of the bridge line BL may be connected to the second portion DLb through a 3-2 contact hole CNT3b.

The first connection wiring WL1 may connect a second portion DLb arranged in an n-th row and a first portion DLa arranged in an (n+1)th row. According to one or more embodiments, as shown in FIG. 9, the first connection wiring WL1 may be in direct contact with each of the first portion DLa and the second portion DLb. However, embodiments are not limited thereto, and, if (e.g., when) an insulating layer is located between the first portion DLa and the first connection wiring WL1, the first portion DLa and the first connection wiring WL1 may be electrically connected to each other through a contact hole.

The gate line GL may include a first portion GLa arranged in the pixel area 11, and second connection wiring WL2 arranged in the connection area 12. The first portion GLa of the gate line GL may be electrically connected to a pixel circuit through a first contact hole CNT1.

The second connection wiring WL2 may connect a first portion GLa arranged in an m-th column and a first portion GLa arranged in an (m+1)th column. According to one or more embodiments, as shown in FIG. 9, the second connection wiring WL2 may be in direct contact with the first portion GLa. However, embodiments are not limited thereto, and, if (e.g., when) an insulating layer is located between the first portion GLa and the second connection wiring WL2, the first portion GLa and the second connection wiring WL2 may be electrically connected to each other through a contact hole.

The connection wiring WL arranged in the connection area 12 may have a smaller modulus (e.g., modulus of elasticity) than the portions DLa, BL, DLb, and GLa of of the signal lines arranged in the pixel area 11. For example, the connection wiring WL may include liquid metal, or may include a metal nanostructure and an elastic polymer. In one or more embodiments, the connection wiring WL may include a conductive composite material including an elastomer. The first portion GLa of the gate line GL, and the first portion DLa, the second portion DLb, and the bridge line BL of the data line DL may each include a metal thin film formed as a triple layer of a titanium (Ti)/aluminum (Al)/titanium (Ti) structure. As described above, as the connection wiring WL includes a material having a smaller modulus than wirings arranged in the pixel area 11, if (e.g., when) the display panel 10 of FIG. 1 is stretched, relatively high deformation may occur in the connection wiring WL and the connection area 12.

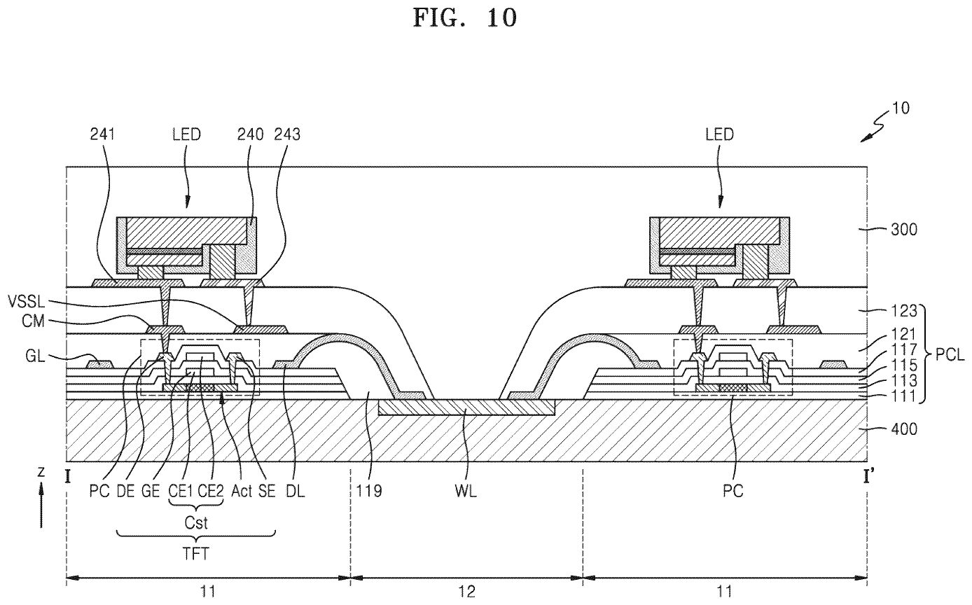

FIG. 10 is a schematic cross-sectional view of a portion of the display panel 10 according to one or more embodiments.

Referring to FIG. 10, the display panel 10 may include a lower elastomer layer 400. As described above, the lower elastomer layer 400 may be to absorb stress that is generated if (e.g., when) the display panel 10 is stretched. The lower elastomer layer 400 may include the same material as described above with reference to FIG. 6.

The display panel 10 may define pixel areas 11 and a connection area 12 between the pixel areas 11. A pixel circuit layer PCL including a pixel circuit PC and a light-emitting diode LED arranged on the pixel circuit layer PCL may be arranged in each of the pixel areas 11 of the lower elastomer layer 400.

A buffer layer 111 may be arranged on the lower elastomer layer 400, and the pixel circuit PC may be arranged on the buffer layer 111. The buffer layer 111 may include an inorganic insulating material such as silicon oxide, silicon nitride, and/or silicon oxynitride.

A thin-film transistor TFT may include a semiconductor layer Act, a gate electrode GE, a source electrode SE, and a drain electrode DE. In FIG. 10, the thin-film transistor TFT is a top gate type or kind in which the gate electrode GE is arranged on a semiconductor layer Act with a gate insulating layer 113 therebetween. However, according to some embodiments, the thin-film transistor TFT may be a bottom gate type or kind.

The semiconductor layer Act may include polysilicon. In one or more embodiments, the semiconductor layer Act may include amorphous silicon, an oxide semiconductor, and/or an organic semiconductor. The gate electrode GE may include a metal thin film including a suitably low resistance metal material. The gate electrode GE may include a conductive material including molybdenum (Mo), aluminum (Al), copper (Cu), and/or titanium (Ti), and may be formed as a multi-layer or single layer including any of the aforementioned materials. For example, the gate electrode GE may be provided as a metal thin film formed of a triple layer of a titanium (Ti)/aluminum (Al)/titanium (Ti) structure.

The gate insulating layer 113 between the semiconductor layer Act and the gate electrode GE may include an inorganic insulating material such as silicon oxide, silicon nitride, silicon oxynitride, aluminum oxide, and/or titanium oxide. The gate insulating layer 113 may be a single layer or multi-layer including any of the aforementioned materials.

The source electrode SE and the drain electrode DE may be located on the same layer, for example, on a second interlayer insulating layer 117, and may include the same materials. Each of the source electrode SE and the drain electrode DE may include a metal thin film including a suitably low resistance metal material. Each of the source electrode SE and the drain electrode DE may include a conductive material including Mo, Al, Cu, and/or Ti, and may be formed as a multi-layer or single layer including any of the aforementioned materials. For example, similar to the gate electrode GE, each of the source electrode SE and the drain electrode DE may be provided as a metal thin film formed of a triple layer of a titanium (Ti)/aluminum (Al)/titanium (Ti) structure. The second interlayer insulating layer 117 may include an inorganic insulating material such as silicon oxide, silicon nitride, silicon oxynitride, aluminum oxide, and/or titanium oxide, and may be a single layer or multiple layers including any of the aforementioned materials.

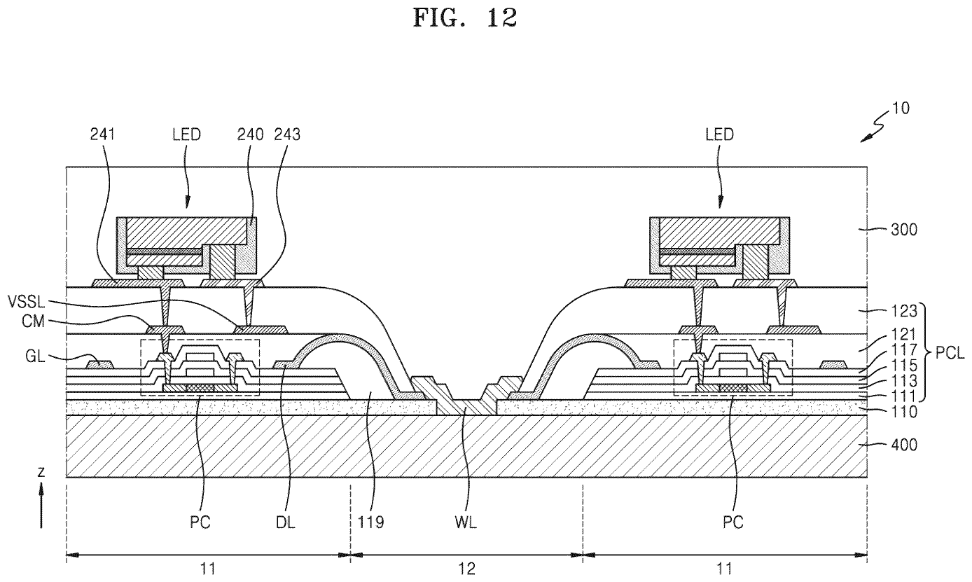

The storage capacitor Cst may include a first electrode CE1 and a second electrode CE2 overlapping each other with a first interlayer insulating layer 115 therebetween. The storage capacitor Cst and the thin-film transistor TFT may overlap each other. With regard to this, FIG. 12 illustrates a case where the gate electrode GE of the thin-film transistor TFT is the first electrode CE1 of the storage capacitor Cst. According to one or more other embodiments, the storage capacitor Cst and the thin-film transistor TFT may not overlap each other. The storage capacitor Cst may be covered by the second interlayer insulating layer 117.

The first interlayer insulating layer 115 may be arranged between the gate insulating layer 113 and the second interlayer insulating layer 117. The first interlayer insulating layer 115 may include an inorganic insulating material such as silicon oxide, silicon nitride, silicon oxynitride, aluminum oxide, and/or titanium oxide, and may be a single layer or multiple layers including any of the aforementioned materials.

The second electrode CE2 of the storage capacitor Cst may include a conductive material, and may be formed as a multi-layer or single layer. The second electrode CE2 may include a metal thin film including a suitably low resistance metal material. The second electrode CE2 may include a conductive material including molybdenum (Mo), aluminum (Al), copper (Cu), and/or titanium (Ti), and may be a multi-layer or single layer including any of the aforementioned materials. For example, the second electrode CE2 may be provided as a metal thin film formed of a triple layer of a titanium (Ti)/aluminum (Al)/titanium (Ti) structure.

A first organic insulating layer 121 may be arranged on the second interlayer insulating layer 117, and a second organic insulating layer 123 may be arranged on the first organic insulating layer 121. In an outer region of the pixel area 11 that is adjacent to the connection area 12, a sub-organic insulating layer 119 may be located between the second interlayer insulating layer 117 and the first organic insulating layer 121. Each of the sub-organic insulating layer 119, the first organic insulating layer 121, and the second organic insulating layer 123 may include an organic insulating material such as polyimide.

The inorganic insulating layer IIL of FIG. 6 including the buffer layer 111, the gate insulating layer 113, the first interlayer insulating layer 115, and the second interlayer insulating layer 117 may be arranged only in the pixel area 11, and may not be arranged in the connection area 12. For example, some areas of the inorganic insulating layer IIL of FIG. 6 that overlap the connection area 12 may be removed. At this time, a step (e.g., a stepped or uneven structure) that may be generated between the pixel area 11 and the connection area 12 may be filled by the sub-organic insulating layer 119. The second organic insulating layer 123 may extend in the pixel area 11, and may also be partially arranged in the connection area 12.

A gate line GL and a data line DL may be arranged on the second interlayer insulating layer 117, and the first organic insulating layer 121 may be arranged on the gate line GL and the data line DL. According to one or more embodiments, a portion of the data line DL arranged in the pixel area 11 may extend to the connection area 12, and may come into direct contact with the connection wiring WL. The portion of the data line DL extending to the connection area 12 may be arranged on the sub-organic insulating layer 119. According to one or more embodiments, an end of the portion of the data line DL extending to the connection area 12 may come into direct contact with the connection wiring WL.

A connection electrode CM and a second voltage line VSSL may be arranged on the first organic insulating layer 121. The connecting electrode CM may electrically connect the thin-film transistor TFT to the light-emitting element LED. The second voltage line VSSL may be connected to the common voltage supply wiring W13 of FIG. 4 to transmit the second power voltage VSS of FIG. 7A to the second electrode 238. Each of the connection electrode CM and the second voltage line VSSL may include a metal thin film including a suitably low resistance metal material. Each of the connection electrode CM and the second voltage line VSSL may include a conductive material including molybdenum (Mo), aluminum (Al), copper (Cu), and/or titanium (Ti), and may be formed as a multi-layer or single layer including the aforementioned materials. For example, each of the connection electrode CM and the second voltage line VSSL may be provided as a metal thin film formed as a triple layer of a titanium (Ti)/aluminum (Al)/titanium (Ti) structure.

A first electrode pad 241 and a second electrode pad 243 may be arranged on the second organic insulating layer 123. The first electrode pad 241 may be electrically connected to the thin-film transistor TFT via the connection electrode CM between the first organic insulating layer 121 and the second organic insulating layer 123. The light-emitting element LED on the first electrode pad 241 and the second electrode pad 243 may be the same as the inorganic light-emitting diode described above with reference to FIG. 8B. The light-emitting element LED, which is the inorganic light-emitting diode of FIG. 8B, may include the first semiconductor layer 231 of FIG. 8B, the second semiconductor layer 232 of FIG. 8B, the intermediate layer 233 of FIG. 8B between the first semiconductor layer 231 of FIG. 8B and the second semiconductor layer 232 of FIG. 8B, the first electrode 235 of FIG. 8B electrically connected to the first semiconductor layer 231 of FIG. 8B, and the second electrode 238 of FIG. 8B electrically connected to the second semiconductor layer 232 of FIG. 8B. The light-emitting element LED may be covered by a protective layer 240. The protective layer 240 may include an organic insulating material such as polyimide.

The connection wiring WL may be arranged on the connection area 12 of the display panel 10. According to one or more embodiments, the connection wiring WL may be arranged on a lower surface of the display layer 200 of FIG. 6, as shown in FIG. 10. For example, a side surface of the connection wiring WL and a lower surface of the connection wiring WL may be surrounded by the lower elastomer layer 400. As the connection wiring WL has a structure embedded in the lower elastomer layer 400, the lower elastomer layer 400 may be to absorb stress that may be concentrated on the connection wiring WL if (e.g., when) the display panel 10 is stretched.

In one or more embodiments, because the connection area 12 of the display panel 10 may be subject to significant deformation, an inorganic insulating layer may not be arranged on the connection area 12 of the lower elastomer layer 400, and instead, organic insulating layers may be arranged thereon. For example, the sub-organic insulating layer 119, the first organic insulating layer 121, and the second organic insulating layer 123 arranged in the pixel area 11 may extend on the connection area 12.

An upper elastomer layer 300 may be arranged on the light-emitting diode LED and the connection wiring WL. The upper elastomer layer 300 may cover the light-emitting element LED and the connection wiring WL, and may be to absorb stress that may be transmitted to the light-emitting element LED and the connection wiring WL.

According to one or more embodiments, the upper elastomer layer 300 may include the same material as that included in the lower elastomer layer 400. However, embodiments are not limited thereto. According to another embodiment, the upper elastomer layer 300 may include a different material from that included in the lower elastomer layer 400.

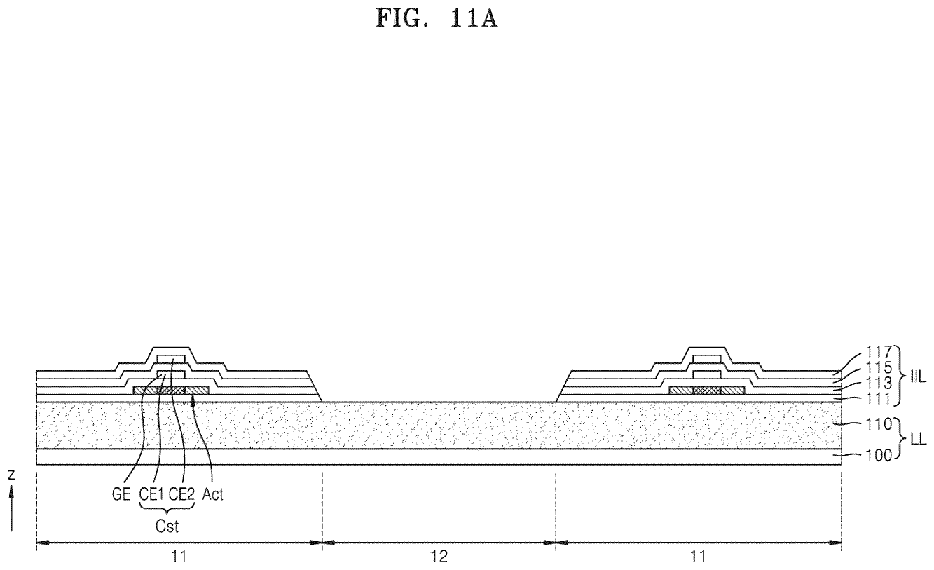

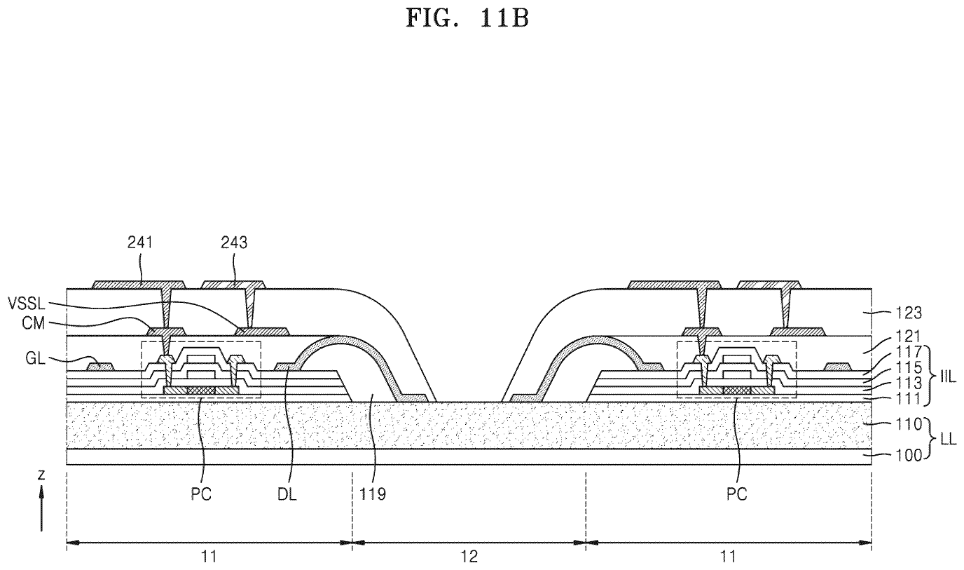

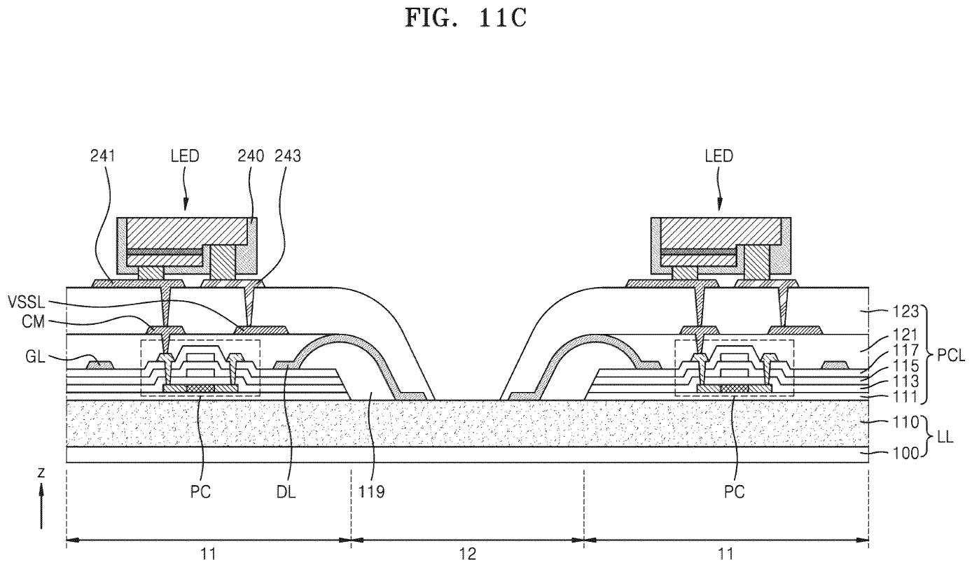

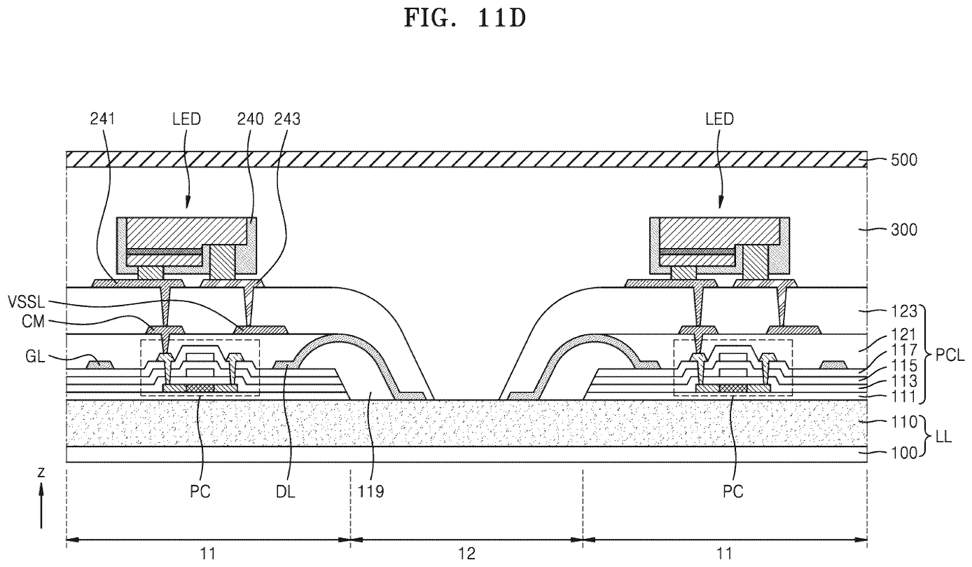

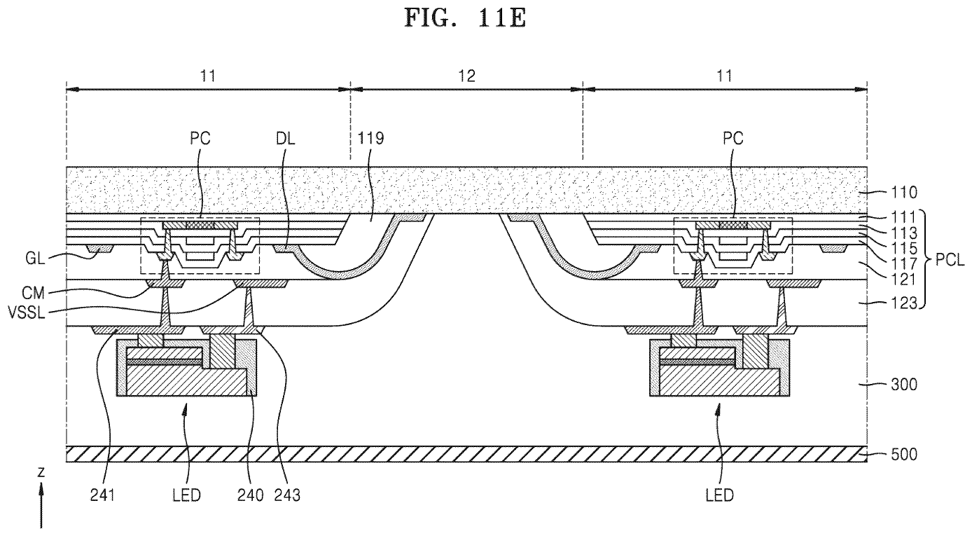

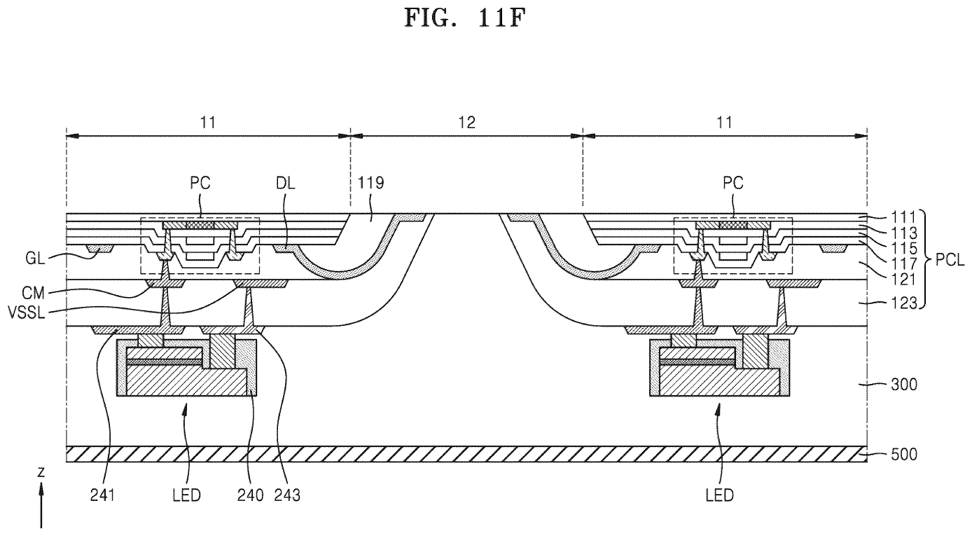

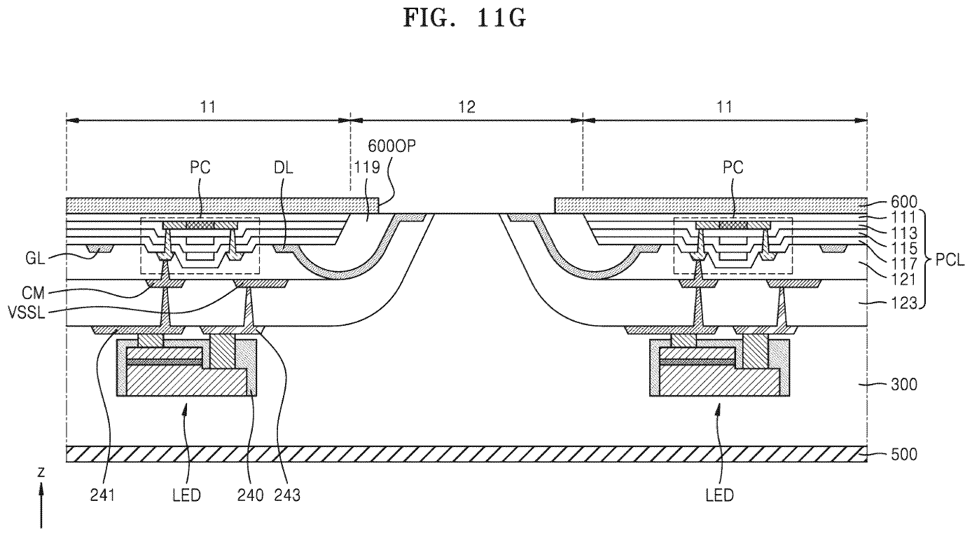

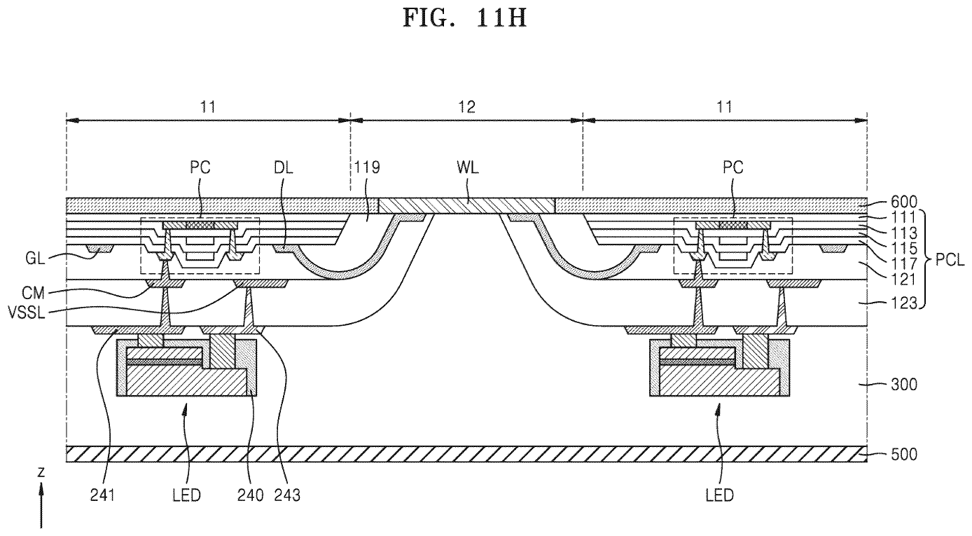

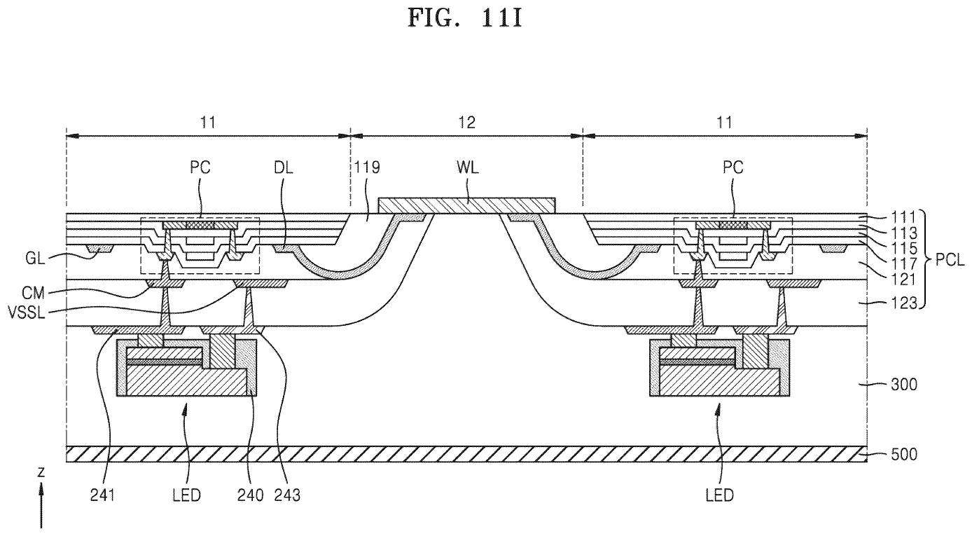

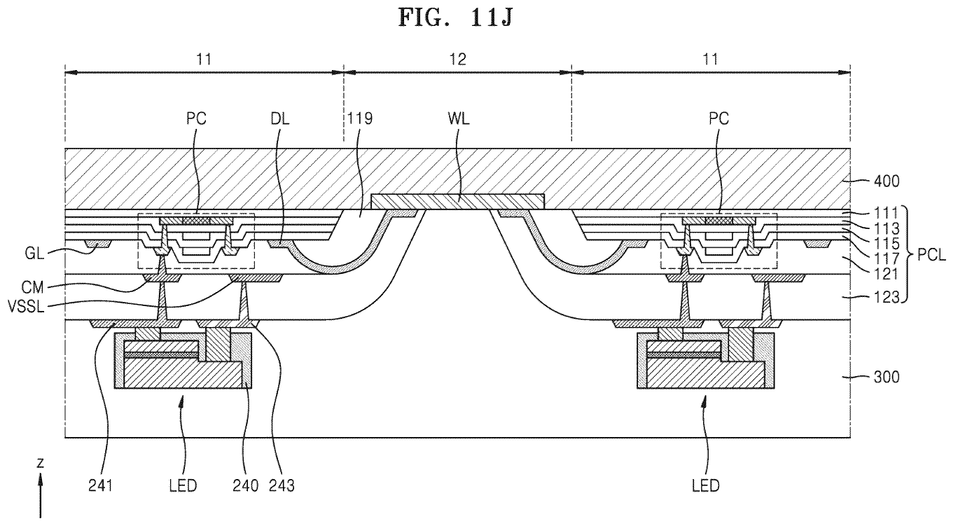

FIGS. 11A through 11J are cross-sectional views illustrating a method of manufacturing a display panel, according to one or more embodiments. In the description of the method of manufacturing the display panel, according to one or more embodiments, the description of the display panel described above with reference to FIGS. 9 and 10 may be applied. Descriptions of the same components in FIGS. 11A through 11J as those described above with reference to FIGS. 9 and 10 will not be provided.

First, referring to FIG. 11A, a lower layer LL may be formed to form the display panel 10 of FIG. 10. The lower layer LL may be a layer temporarily arranged to form the display panel 10 of FIG. 10 that is stretchable. For example, the lower layer LL may be arranged to support the display layer 200 (e.g., as shown in FIG. 6) while forming the display layer 200, but may be removed after forming the display layer 200.

According to one or more embodiments, the lower layer LL may include a substrate 100, and a base layer 110 arranged on the substrate 100. The substrate 100 may be a rigid substrate. For example, the substrate 100 may be a transparent glass substrate containing SiO₂ as a main component, and/or a substrate including a polymer resin such as reinforced plastic. The base layer 110 may include polymer resin. For example, the base layer 110 may include polyethersulfone, polyacrylate, polyetherimide, polyethylene naphthalate, polyethylene terephthalate, polyphenylene sulfide, polyarylate, polyimide, polycarbonate, cellulose acetate propionate, and/or the like. According to one or more embodiments, a thickness of the base layer 110 may be greater than a thickness of the substrate 100.

A portion of an inorganic insulating layer IIL and a portion of the thin film transistor TFT of FIG. 10 may be formed on the lower layer LL. For example, a buffer layer 111, an active layer Act, a gate insulating layer 113, a gate electrode GE, a first interlayer insulating layer 115, a second electrode CE2, and a second interlayer insulating layer 117 may be sequentially stacked on the lower layer LL.

However, the inorganic insulating layer IIL may be arranged only in the pixel area 11, and may not be arranged in the connection area 12. For example, a portion of the inorganic insulating layer IIL that overlaps the connection area 12 may be removed by etching.

Next, referring to FIG. 11B, the sub-organic insulating layer 119 may be formed on the second interlayer insulating layer 117. The sub-organic insulating layer 119 may cover a side surface of the inorganic insulating layer IIL from which a portion has been removed. The sub-organic insulating layer 119 may prevent or reduce wiring disconnection from occurring due to a step difference between the inorganic insulating layer IIL and the lower layer LL. The source electrode SE of FIG. 10 and the drain electrode DE of FIG. 10 of the pixel circuit PC may be formed on the second interlayer insulating layer 117, and the gate line GL and the data line DL may be formed on the second interlayer insulating layer 117 and the sub-organic insulating layer 119.

The first organic insulating layer 121 may be formed on the pixel circuit PC, and the connection electrode CM and the second voltage line VSSL may be formed on the first organic insulating layer 121. The second organic insulating layer 123 may be formed on the connection electrode CM, and the first electrode pad 241 and the second electrode pad 243 may be formed on the second organic insulating layer 123. According to one or more embodiments, the first organic insulating layer 121 may be formed only in the pixel area 11, and the second organic insulating layer 123 may extend from the pixel area 11 such that a portion thereof may also be formed in the connection area 12. However, as shown in FIG. 11B, second organic insulating layers 123 arranged adjacent to each other may be spaced apart from each other within the connection area 12.

Next, referring to FIG. 11C, a light-emitting diode LED may be formed on the pixel circuit layer PCL. The light-emitting diode LED may be arranged in the pixel area 11. The light-emitting diode LED may be an inorganic light-emitting diode, as described above with reference to FIG. 8A. The light-emitting diode LED may be covered by the protective layer 240.

Next, referring to FIG. 11D, the upper elastomer layer 300 may be formed to cover the light-emitting diode LED. The upper elastomer layer 300 may include the same material as the material described above with reference to FIG. 6. The upper elastomer layer 300 may be to absorb stress that may be transmitted to the light-emitting diode LED and the pixel circuit PC, if (e.g., when) the display panel 10 of FIG. 10 is stretched. The upper elastomer layer 300 may function to planarize (or substantially planarize) the display panel 10 of FIG. 10. The upper elastomer layer 300 may be formed through a thermal curing process, after the material constituting the upper elastomer layer 300 is deposited. The thermal curing process may heat the display panel 10 of FIG. 10 at 150° C. or higher for 30 minutes to 2 hours. However, embodiments are not limited thereto, and the upper elastomer layer 300 may be cured through any suitable thermal curing process.

A carrier film 500 may be formed on the upper elastomer layer 300. In some embodiments, the carrier film 500 may be attached to an upper surface of the upper elastomer layer 300 through an adhesive layer located between the upper elastomer layer 300 and the carrier film 500. The carrier film 500 may be a protective film capable of preventing or reducing scratches and/or damages from occurring on the display panel 10 of FIG. 10 during the manufacturing process. For example, the carrier film 500 may include an insulating film. However, this is merely an example, and the method of attaching the carrier film 500 may be changed in one or more suitable ways.

Next, referring to FIG. 11E, after the substrate 100 is detached from the lower layer LL of FIG. 11D, the display panel 10 of FIG. 10 may be inverted. For example, the substrate 100 may be removed from the base layer 110. By radiating a laser to another surface of the substrate 100 that is opposite to one surface of the substrate 100 that is in contact with the base layer 110, a bonding force between the substrate 100 and the base layer 110 may be weakened. Accordingly, the substrate 100 may be peeled off from the base layer 110. However, this is merely an example, and the method of removing the substrate 100 may be changed in one or more suitable ways.

After the substrate 100 is detached, the display panel 10 of FIG. 10 may be inverted (e.g., upside down) such that an upper surface and a lower surface are reversely arranged. For example, the display panel 10 of FIG. 10 may be inverted such that the carrier film 500 is arranged on the bottom and the base layer 110 is arranged on the top.

Next, referring to FIG. 11F, the base layer 110 may be removed while the display panel 10 of FIG. 10 is inverted. The base layer 110 may be entirely removed through a dry etching process. As the base layer 110 is removed, a lower surface of the pixel circuit layer PCL may be exposed. The lower surface of the pixel circuit layer PCL may be seen as an upper surface of the pixel circuit layer PCL, because the display panel 10 of FIG. 10 is inverted.

Next, referring to FIG. 11G, a sacrificial layer 600 may be formed on the lower surface of the pixel circuit layer PCL, while the display panel 10 of FIG. 10 is inverted. The sacrificial layer 600 may be patterned to have an opening 600OP that overlaps the connection area 12. According to one or more embodiments, the sacrificial layer 600 may be formed through a dispensing process and/or an inkjet printing process. However, this is merely an example, and the method of forming the sacrificial layer 600 may be changed in one or more suitable ways.

The connection wiring WL of FIG. 10 may be arranged in an opening 600OP of the sacrificial layer 600. For example, the sacrificial layer 600 may be a layer temporarily used to pattern the connection wiring WL of FIG. 10. According to one or more embodiments, if (e.g., when) the connection wiring WL of FIG. 10 is formed of liquid metal, the sacrificial layer 600 may include a liquid metal adhesion inhibitor. However, this is merely an example, and the material of the sacrificial layer 600 may not be limited as long as it is a material having hydrophobicity.

Next, referring to FIG. 11H, the connection wiring WL may be formed within the opening 600OP of the sacrificial layer 600. In a plan view, an area of the connection wiring WL may be equal to an area of respective portions of an organic insulating layer and the upper elastomer layer 300 whose respective upper surfaces are exposed through the opening 600OP. For example, a length of the connection wiring WL may be the same as a combined length of the exposed upper surfaces of the organic insulating layer and the upper elastomer layer 300 through the opening 600OP. According to one or more embodiments, the connection wiring WL may include liquid metal, and a material for forming the connection wiring WL may be applied using, for example, a roller and/or a stamp. However, because detailed patterning (e.g., precise and/or intricate patterning) may be relatively difficult to implement if (e.g., when) using, for example, a roller or a stamp, the material for forming the connection wiring WL may be applied up to an area around the opening 600OP. At this time, if (e.g., when) the sacrificial layer 600 includes a liquid metal adhesion inhibitor as described above, the material for forming the connection wiring WL may not be arranged on the sacrificial layer 600, but may be arranged only within the opening 600OP. For example, the connection wiring WL may be patterned through an opening of the sacrificial layer 600 including a hydrophobic material.

Next, referring to FIG. 11I, the sacrificial layer 600 of FIG. 11H may be removed. The sacrificial layer 600 of FIG. 11H including a hydrophobic material, such as a liquid metal adhesion inhibitor, may be removed through a cleaning process using water. Accordingly, only the connection wiring WL formed within the opening 600OP of FIG. 11H of the sacrificial layer 600 of FIG. 11H may remain on the lower surface of the display panel 10 of FIG. 10.

For example, according to the method of manufacturing a display panel, according to one or more embodiments, detailed patterning of the connection wiring WL is possible, and also the sacrificial layer 600 of FIG. 11H may be completely (or substantially) removed and thus a material capable of reducing the stretchability of the display panel 10 of FIG. 10 does not remain, so that the stretchability of the display panel 10 of FIG. 10 may be improved. When the sacrificial layer 600 of FIG. 11H including a hydrophobic material remains, a bonding strength of the sacrificial layer 600 with its upper layer may be weakened. Accordingly, as the sacrificial layer 600 of FIG. 11H is removed, the display panel 10 of FIG. 10 according to one or more embodiments may also secure (or attain) improved structural stability.

Next, referring to FIG. 11J, the lower elastomer layer 400 may be formed on the lower surface of the pixel circuit layer PCL. The lower elastomer layer 400 may be arranged to cover the connection wiring WL. The lower elastomer layer 400 may include the same material as the material described above with reference to FIG. 6.

The lower elastomer layer 400 may function to seal a lower portion of the display panel 10 of FIG. 10, and may be to absorb stress that may occur if (e.g., when) the display panel 10 of FIG. 10 is stretched.

After the lower elastomer layer 400 is formed, the display panel of FIG. 11J may be inverted again so that the structure of the display panel 10 of FIG. 10 is restored. Thereafter, the carrier film 500 of FIG. 11I attached to the upper surface of the display panel 10 of FIG. 10 may be removed. The carrier film 500 of FIG. 11I may be removed using a peeling tape. However, this is merely an example, and the method of removing the carrier film 500 of FIG. 11J may suitably vary.

FIG. 12 is a schematic cross-sectional view of a portion of a display panel according to one or more other embodiments. Other features in FIG. 12 except for the features of the base layer 110 and the connection wiring WL are the same as those described above with reference to FIGS. 9 and 10. Descriptions of the same components in FIG. 12 as those described above with reference to FIGS. 9 and 10 will not be provided, and differences therebetween will now be mainly explained.

Referring to FIG. 12, the display panel 10 may include the lower elastomer layer 400. The display panel 10 may define pixel areas 11 and a connection area 12 between the pixel areas 11. A pixel circuit layer PCL including a pixel circuit PC and a light-emitting diode LED arranged on the pixel circuit layer PCL may be arranged in each of the pixel areas 11 of the lower elastomer layer 400.

According to one or more embodiments, the base layer 110 may be located between the lower elastomer layer 400 and the pixel circuit layer PCL. For example, the base layer 110 may be located between the lower elastomer layer 400 and the buffer layer 111. The base layer 110 may include polymer resin. For example, the base layer 110 may include polyethersulfone, polyacrylate, polyetherimide, polyethylene naphthalate, polyethylene terephthalate, polyphenylene sulfide, polyarylate, polyimide, polycarbonate, cellulose acetate propionate, and/or the like.

According to one or more embodiments, the base layer 110 may include an opening that overlaps the connection area 12, and the connection wiring WL may be arranged within an opening of the base layer 110. For example, the connection wiring WL may be arranged on the upper surface of the lower elastomer layer 400 exposed through the opening of the base layer 110. The connection wiring WL may fill the opening of the base layer 110, and also may be arranged on an upper surface of an end (e.g., edge portion) of the base layer 110. For example, the connection wiring WL may cover a side surface of the base layer 110 and a portion of an upper surface of the base layer 110.

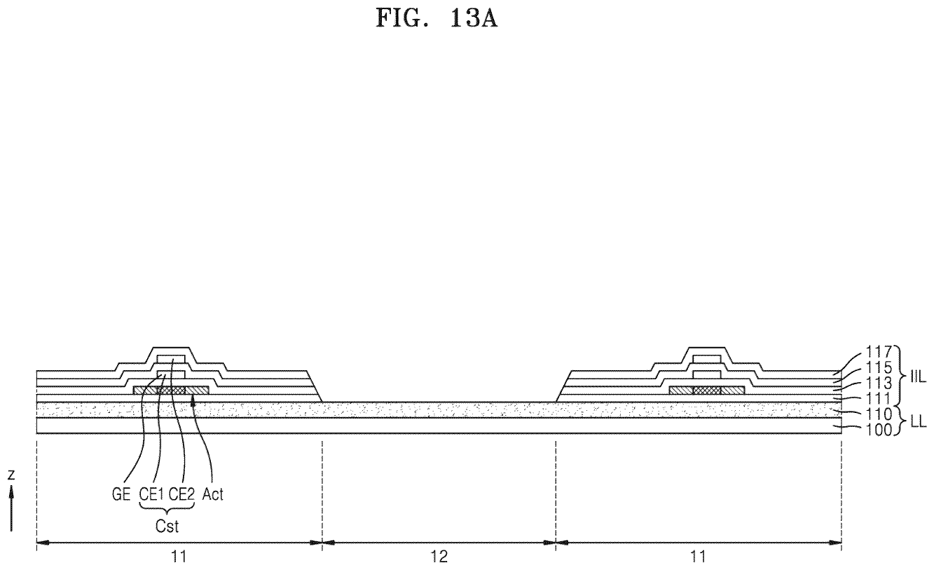

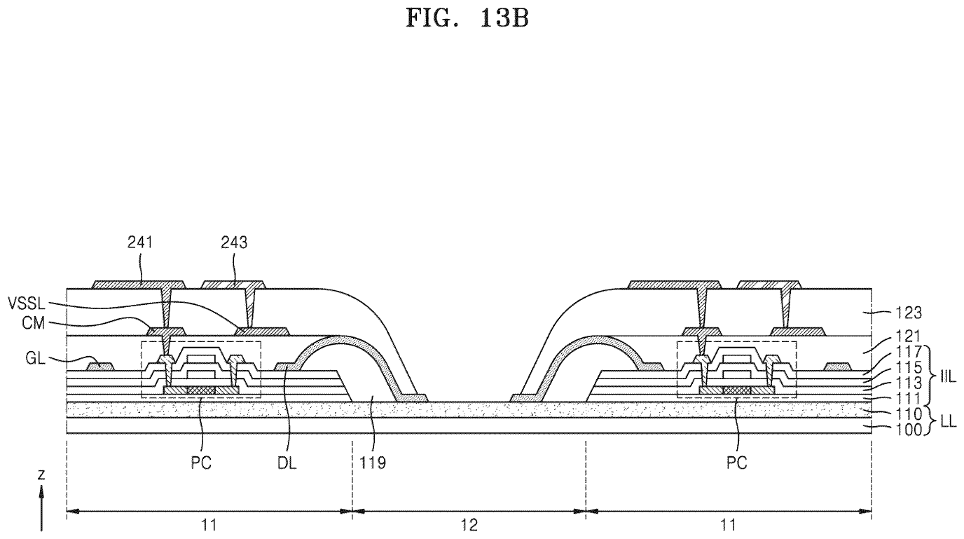

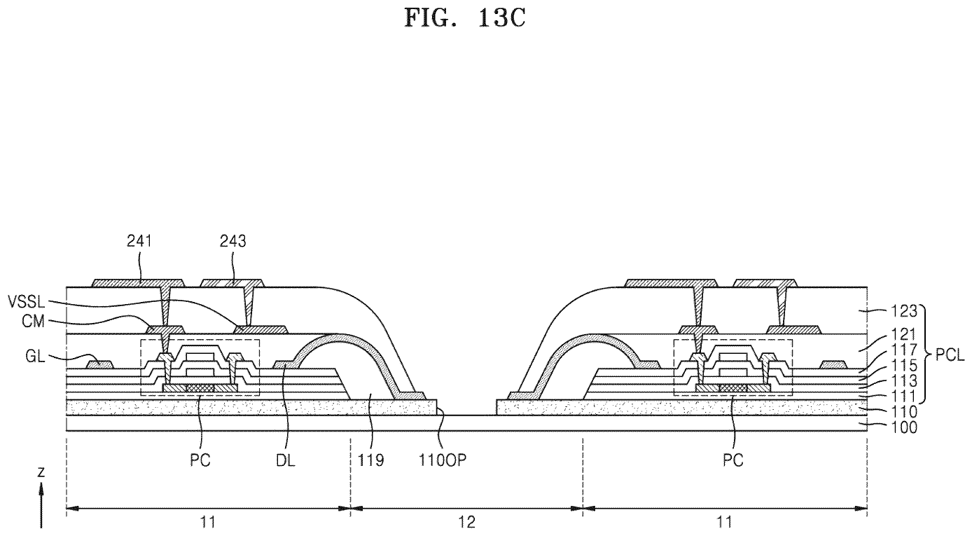

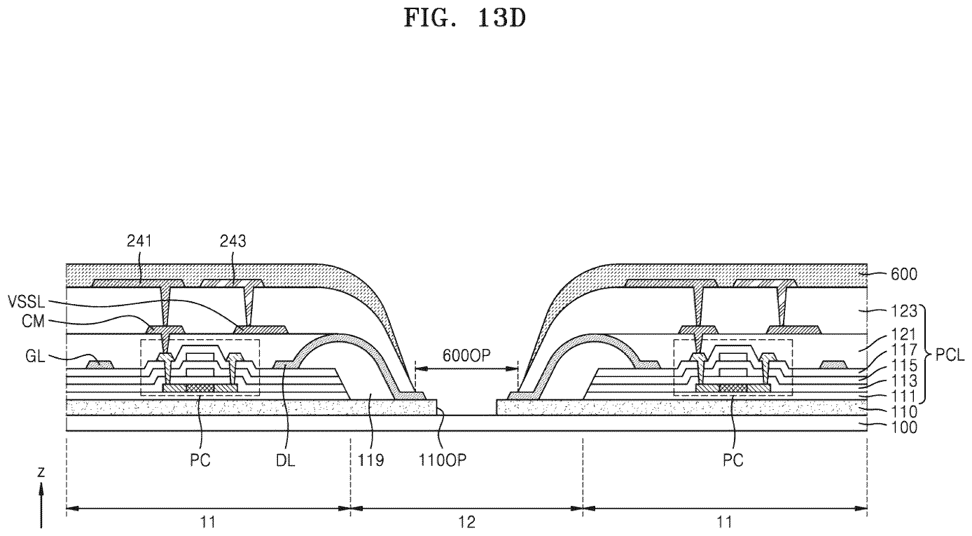

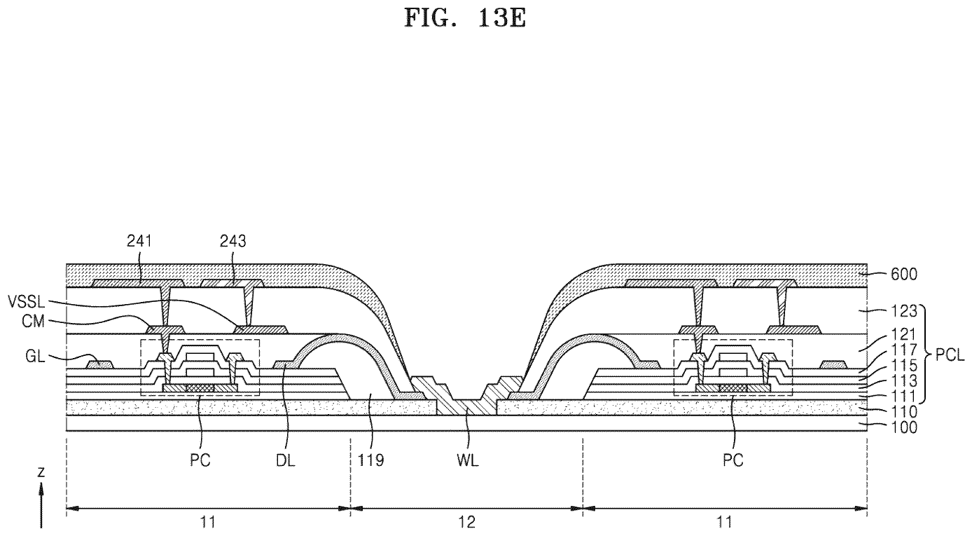

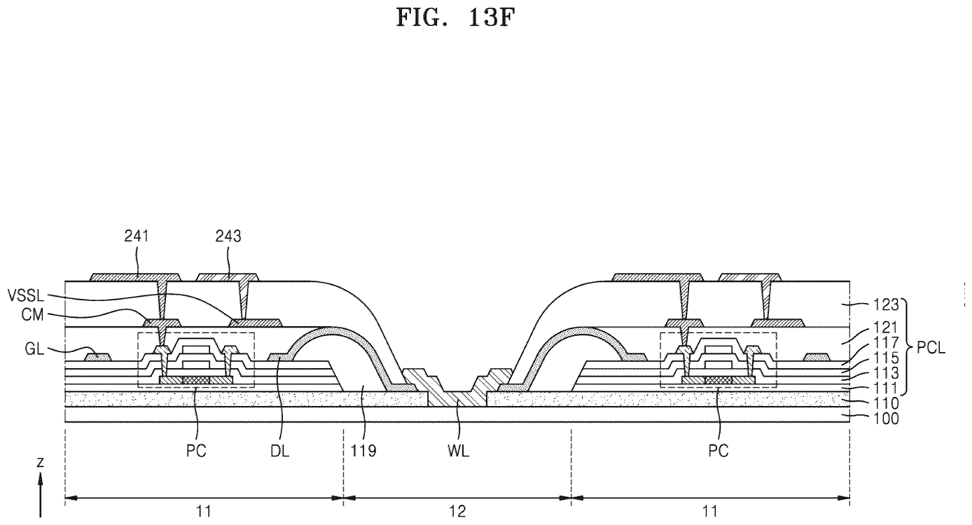

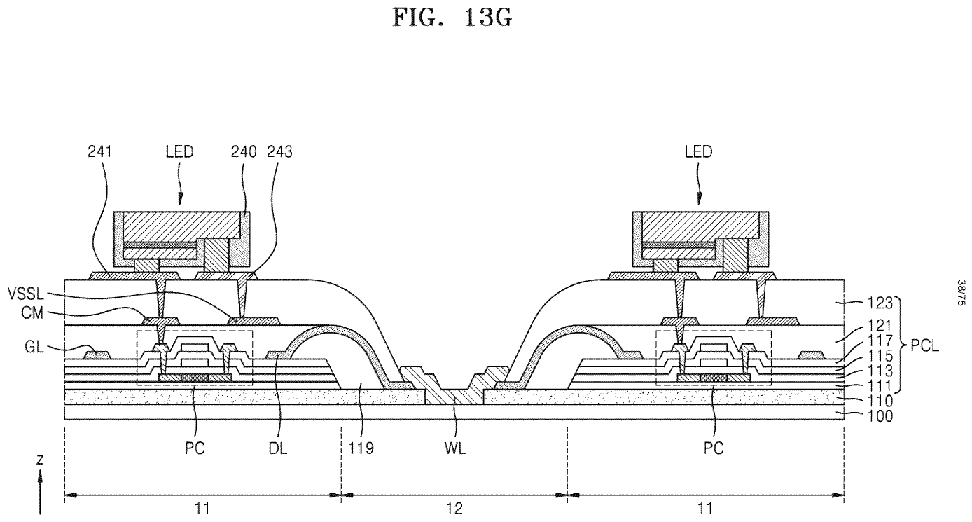

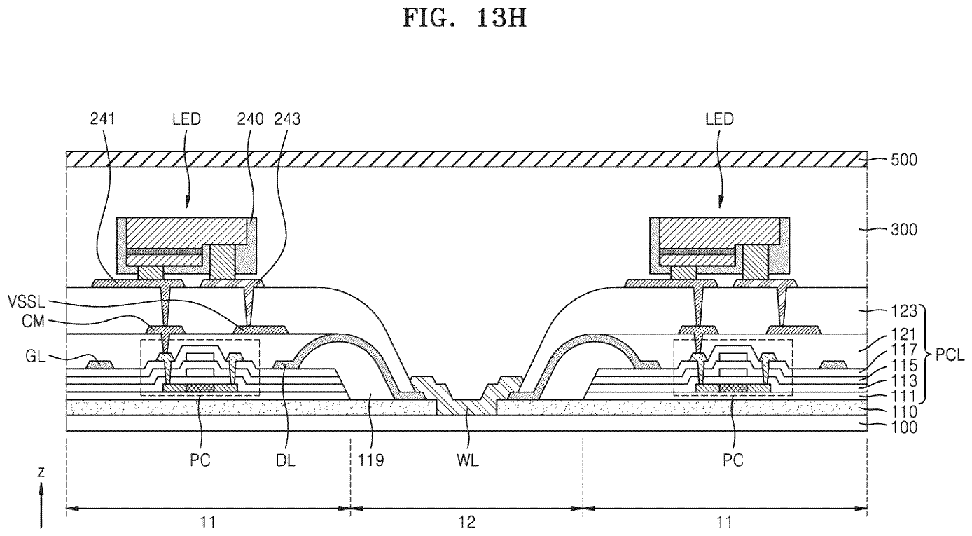

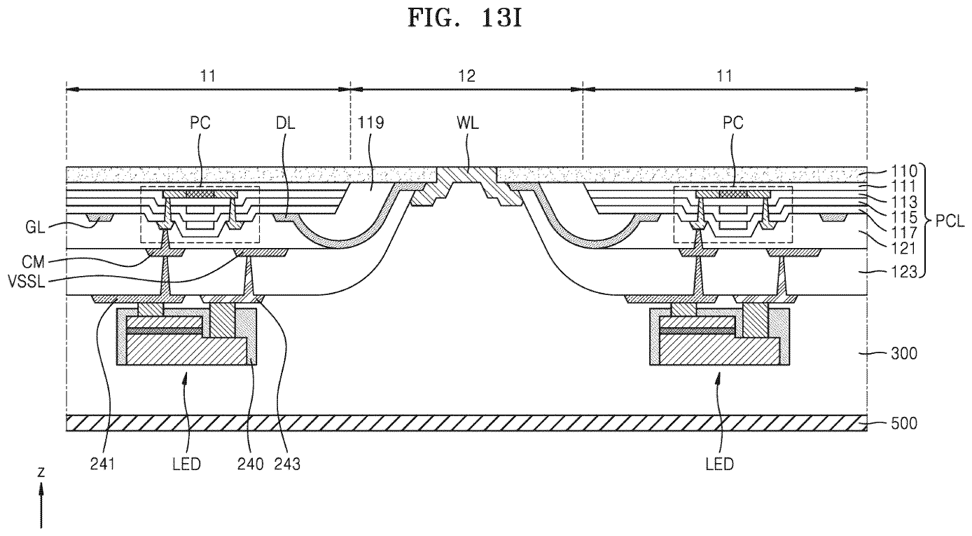

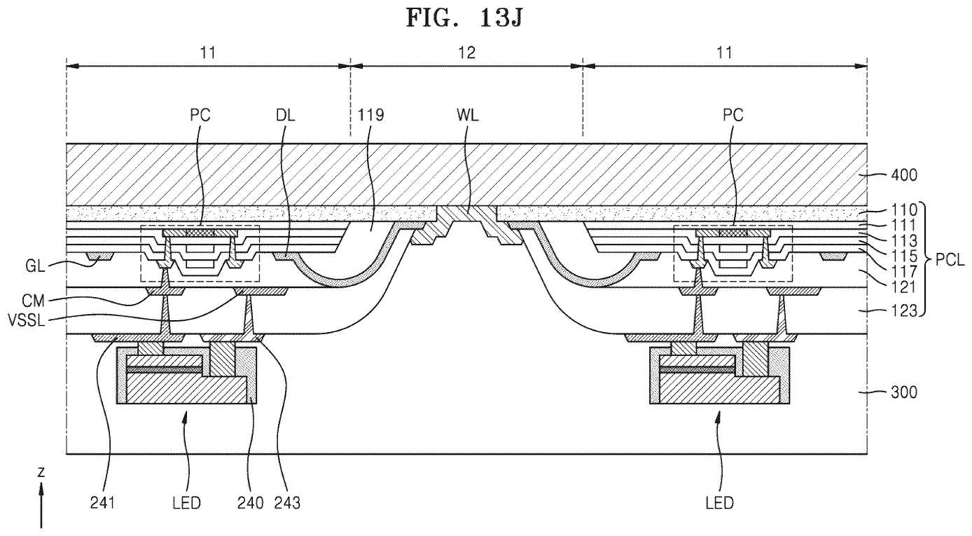

FIGS. 13A through 13J are cross-sectional views illustrating a method of manufacturing a display panel, according to one or more other embodiments. In the description of the method of manufacturing the display panel, according to the embodiments, the description of the display panel described above with reference to FIG. 12 may be applied. Descriptions of the same components in FIGS. 13A through 13J as those described above with reference to FIGS. 9 through 12 will not be provided, and differences therebetween will now be mainly explained.

First, referring to FIG. 13A, a lower layer LL may be formed to form the display panel 10 of FIG. 12. According to one or more embodiments, the lower layer LL may include a substrate 100, and a base layer 110 arranged on the substrate 100.

A portion of an inorganic insulating layer IIL and a portion of the thin-film transistor TFT (e.g., as described in connection with FIG. 10) may be formed on the lower layer LL. However, the inorganic insulating layer IIL may be arranged only in the pixel area 11, and may not be arranged in the connection area 12. For example, a portion of the inorganic insulating layer IIL that overlaps the connection area 12 may be removed by etching.

Next, referring to FIG. 13B, the sub-organic insulating layer 119 may be formed on the second interlayer insulating layer 117. The sub-organic insulating layer 119 may cover a side surface of the inorganic insulating layer IIL from which a portion has been removed. The source electrode SE and the drain electrode DE (e.g., as described in connection with FIG. 10) of the pixel circuit PC may be formed on the second interlayer insulating layer 117, and the gate line GL and the data line DL may be formed on the second interlayer insulating layer 117 and the sub-organic insulating layer 119.

The first organic insulating layer 121 may be formed on the pixel circuit PC, and the connection electrode CM and the second voltage line VSSL may be formed on the first organic insulating layer 121. The second organic insulating layer 123 may be formed on the connection electrode CM, and the first electrode pad 241 and the second electrode pad 243 may be formed on the second organic insulating layer 123.

Next, referring to FIG. 13C, an opening 110OP may be formed in the base layer 110. For example, a partial area of the base layer 110 that overlaps the connection area 12 may be removed. The partial area of the base layer 110 may be removed through a dry etching process. As the opening 110OP is formed in the base layer 110, a portion of an upper surface of the substrate 100 may be exposed.

Next, referring to FIG. 13D, the sacrificial layer 600 may be formed on the pixel circuit layer PCL. The sacrificial layer 600 may be patterned to have an opening 600OP that overlaps the connection area 12. The opening 600OP of the sacrificial layer 600 may partially overlap the opening 110OP of the base layer 110. According to one or more embodiments, the sacrificial layer 600 may be formed through a dispensing process and/or an inkjet printing process. However, this is merely an example, and the method of forming the sacrificial layer 600 may suitably vary.

The connection wiring WL of FIG. 12 may be arranged in the opening 600OP of the sacrificial layer 600. For example, the sacrificial layer 600 may be a layer temporarily used to pattern the connection wiring WL of FIG. 12. According to one or more embodiments, if (e.g., when) the connection wiring WL of FIG. 12 is formed of liquid metal, the sacrificial layer 600 may include a liquid metal adhesion inhibitor.

However, this is merely an example, and the material of the sacrificial layer 600 may not be limited as long as it is a material having hydrophobicity.

Next, referring to FIG. 13E, the connection wiring WL may be formed within the opening 600OP of FIG. 13D of the sacrificial layer 600. Because the opening 600OP of FIG. 13D of the sacrificial layer 600 partially overlaps with the opening 110OP of FIG. 13D of the base layer 110, the connection wiring WL may fill the opening 110OP of FIG. 13D of the base layer 110. For example, the connection wiring WL may fill the opening 110OP of FIG. 13D of the base layer 110, and may cover up to the upper surface of the base layer 110 exposed through the opening 600OP of FIG. 13D of the sacrificial layer 600.

According to one or more embodiments, the connection wiring WL may include liquid metal, and a material for forming the connection wiring WL may be applied using, for example, a roller and/or a stamp. However, because detailed patterning may be relatively difficult to implement if (e.g., when) using, for example, a roller and/or a stamp, the material for forming the connection wiring WL may be applied up to an area around the opening 600OP of FIG. 13D. At this time, if (e.g., when) the sacrificial layer 600 includes a liquid metal adhesion inhibitor as described herein above, the material for forming the connection wiring WL may not be arranged on the sacrificial layer 600, but may be arranged only within the opening 600OP of FIG. 13D. For example, the connection wiring WL may be patterned through an opening of the sacrificial layer 600 including a hydrophobic material.

Next, referring to FIG. 13F, the sacrificial layer 600 of FIG. 13E may be removed. The sacrificial layer 600 of FIG. 13E including a hydrophobic material, such as a liquid metal adhesion inhibitor, may be removed through a cleaning process using water. Accordingly, only the connection wiring WL formed within an opening of the sacrificial layer 600 of FIG. 13E may remain in the connection area 12.

For example, according to the method of manufacturing a display panel according to the embodiments, detailed patterning (e.g., precise and/or intricate patterning) of the connection wiring WL may be possible, and also the sacrificial layer 600 of FIG. 13E may be completely (or substantially) removed and thus a material capable of reducing the stretchability of the display panel 10 of FIG. 12 does not remain, so that the stretchability of the display panel 10 of FIG. 12 may be improved. When the sacrificial layer 600 of FIG. 13E including a hydrophobic material remains, a bonding strength of the sacrificial layer 600 with its upper layer may be weakened. Accordingly, as the sacrificial layer 600 of FIG. 13E is removed, the display panel 10 of FIG. 12 according to the present embodiments may also secure (or attain) improved structural stability of the display panel 10 of FIG. 12.

Next, referring to FIG. 13G, a light-emitting diode LED may be formed on the pixel circuit layer PCL. The light-emitting diode LED may be arranged in the pixel area 11. The light-emitting diode LED may be an inorganic light-emitting diode, as described above with reference to FIG. 8A. The light-emitting diode LED may be covered by the protective layer 240.

Next, referring to FIG. 13H, the upper elastomer layer 300 may be formed to cover the light-emitting diode LED and the connection wiring WL. The upper elastomer layer 300 may include the same material as the material described herein with reference to FIG. 6. The upper elastomer layer 300 may be formed through a thermal curing process, after the material constituting the upper elastomer layer 300 is deposited.

A carrier film 500 may be formed on the upper elastomer layer 300. In some embodiments, the carrier film 500 may be attached to the upper surface of the upper elastomer layer 300 through an adhesive layer located between the upper elastomer layer 300 and the carrier film 500. However, this is merely an example, and the method of curing the upper elastomer layer 300 and/or the method of attaching the carrier film 500 may suitably vary.

Next, referring to FIG. 13I, after the substrate 100 of FIG. 13H is detached from the lower layer LL of FIG. 13A, the display panel 10 of FIG. 12 may be inverted. For example, the substrate 100 of FIG. 13H may be removed from the base layer 110. By radiating a laser to another surface of the substrate 100 of FIG. 13H that is opposite to one surface of the substrate 100 of FIG. 13H that is in contact with the base layer 110, a bonding force between the substrate 100 of FIG. 13H and the base layer 110 may be weakened. After the substrate 100 of FIG. 13H is detached, the display panel 10 of FIG. 12 may be inverted such that an upper surface and a lower surface are reversely arranged. For example, the display panel 10 of FIG. 12 may be inverted such that the carrier film 500 is arranged on the bottom and the base layer 110 is arranged on the top.

Next, referring to FIG. 13J, the lower elastomer layer 400 may be formed on the lower surface of the base layer 110 and the lower surface of the connection wiring WL, while the display panel 10 of FIG. 12 is inverted. The lower elastomer layer 400 may encapsulate the bottom of the display panel 10 of FIG. 12.

After the lower elastomer layer 400 is formed, the display panel of FIG. 13J may be inverted again so that the structure of the display panel 10 of FIG. 12 is restored. Thereafter, the carrier film 500 of FIG. 13I attached to the upper surface of the display panel 10 of FIG. 12 may be removed. The carrier film 500 of FIG. 13I may be removed using a peeling tape. However, this is merely an example, and the method of removing the carrier film 500 of FIG. 13I may suitably vary.

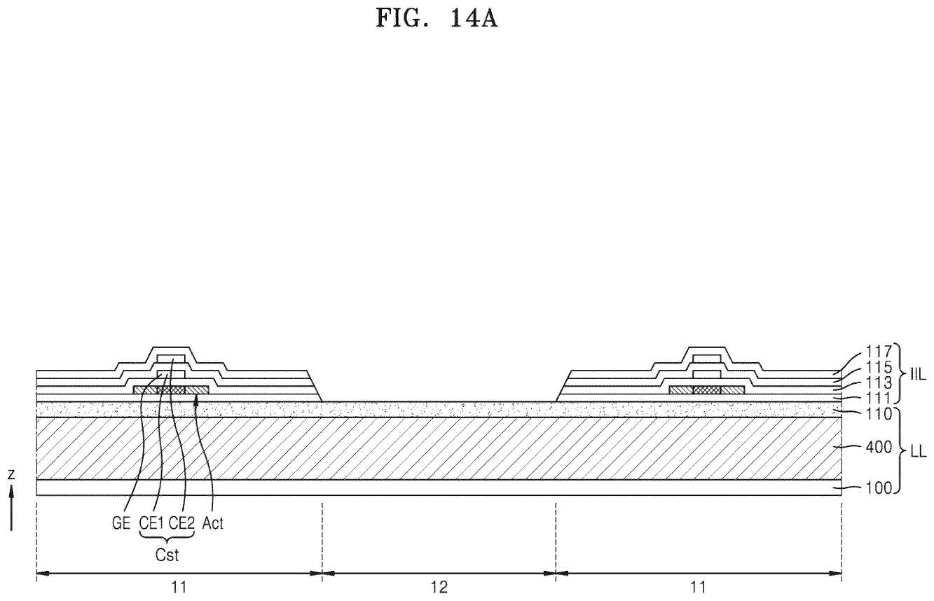

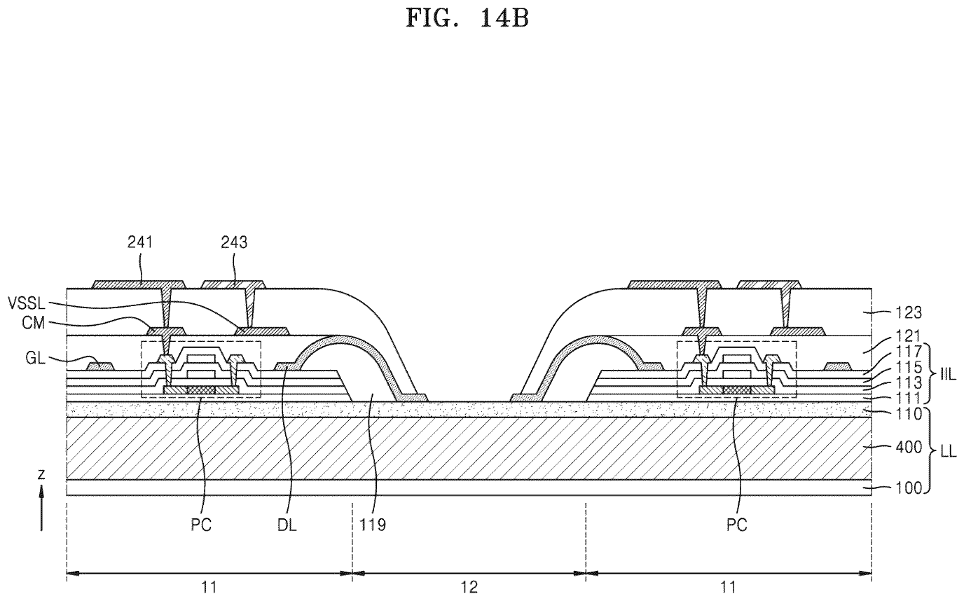

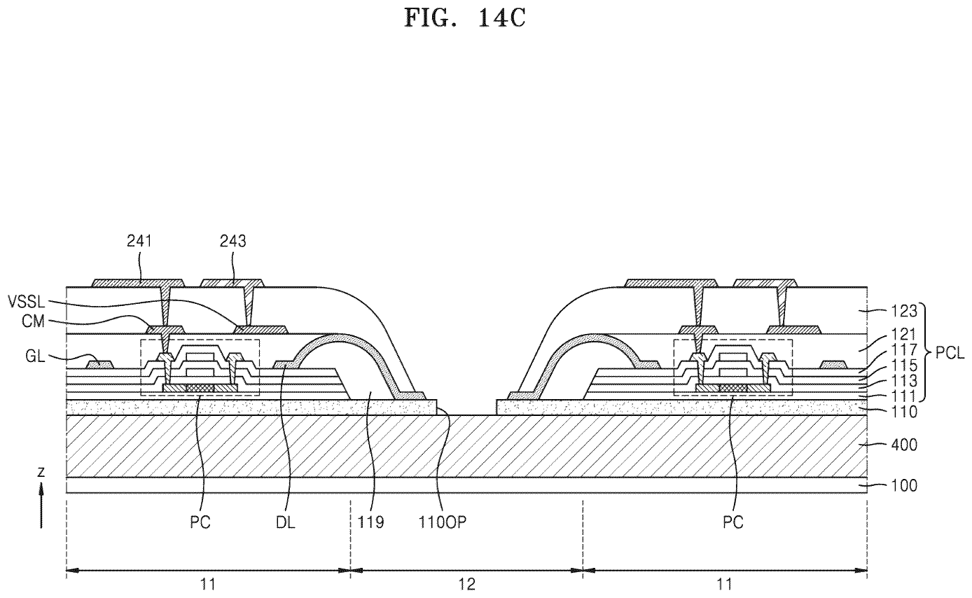

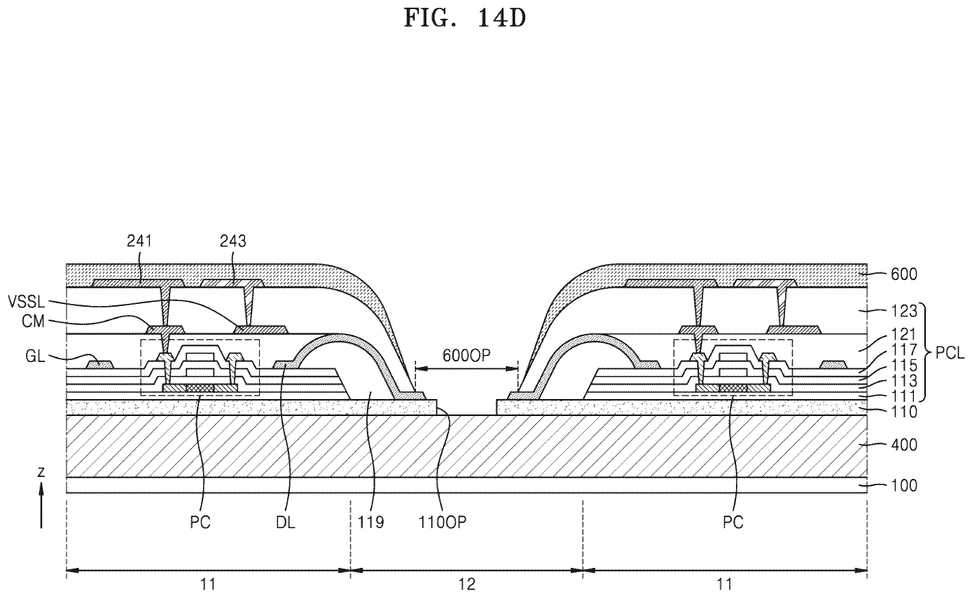

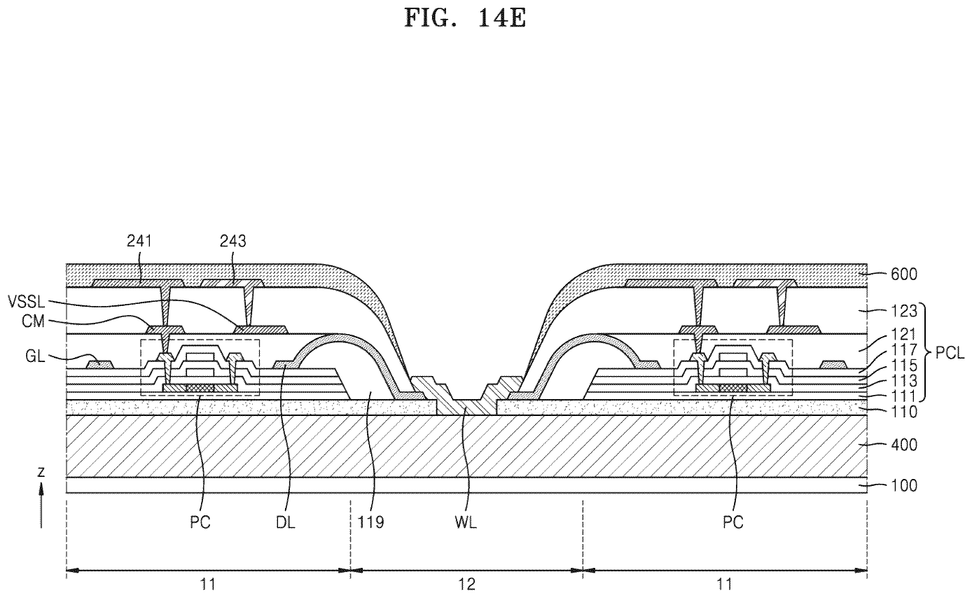

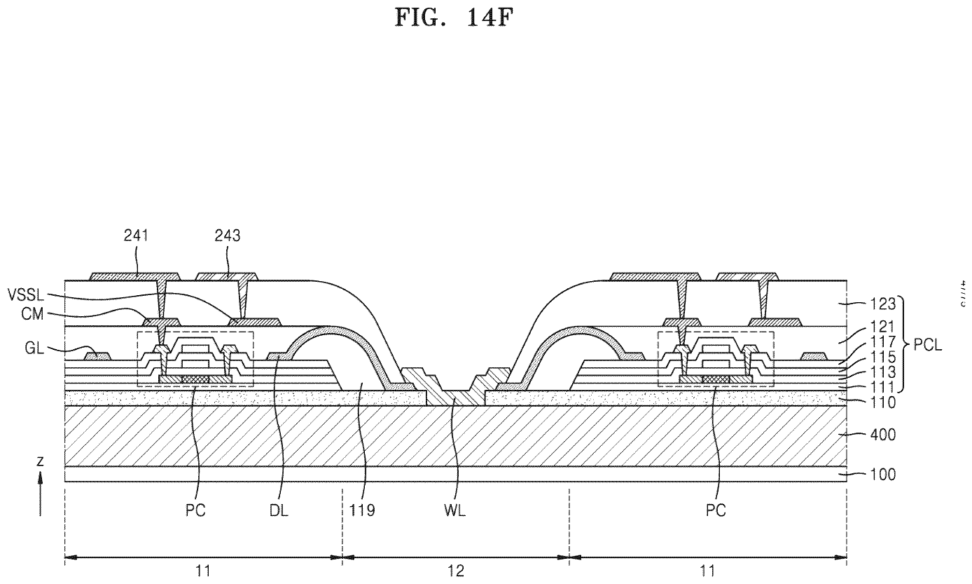

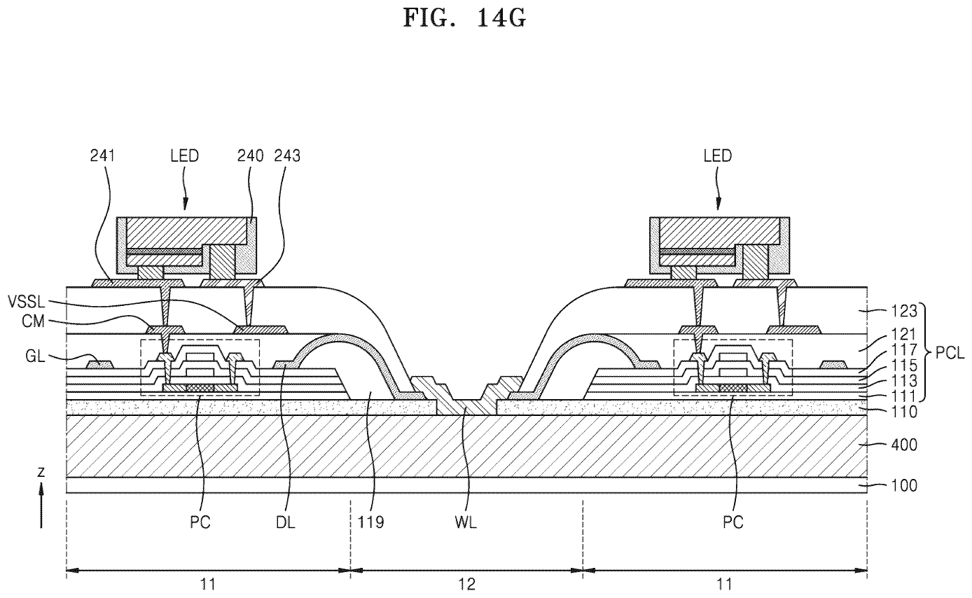

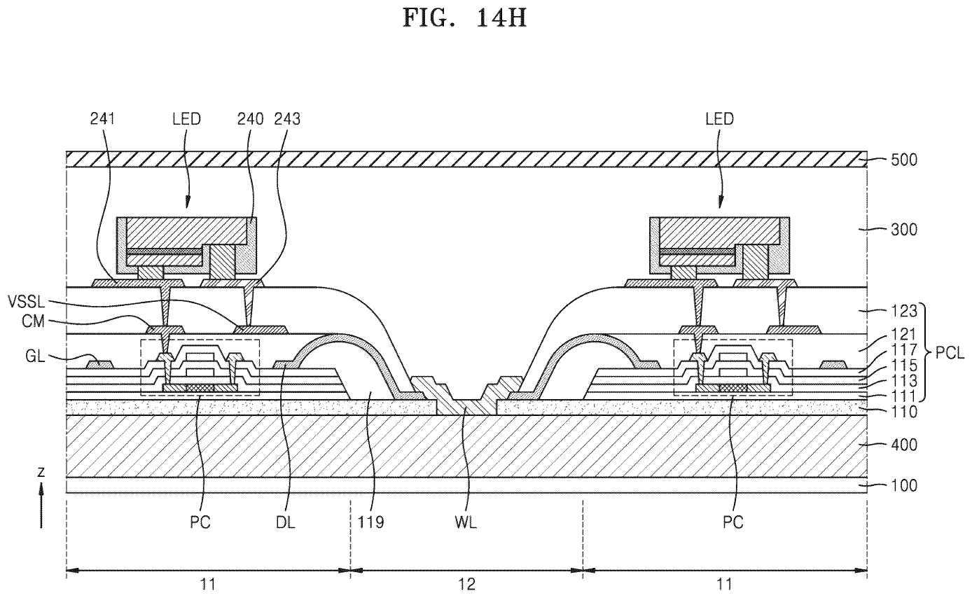

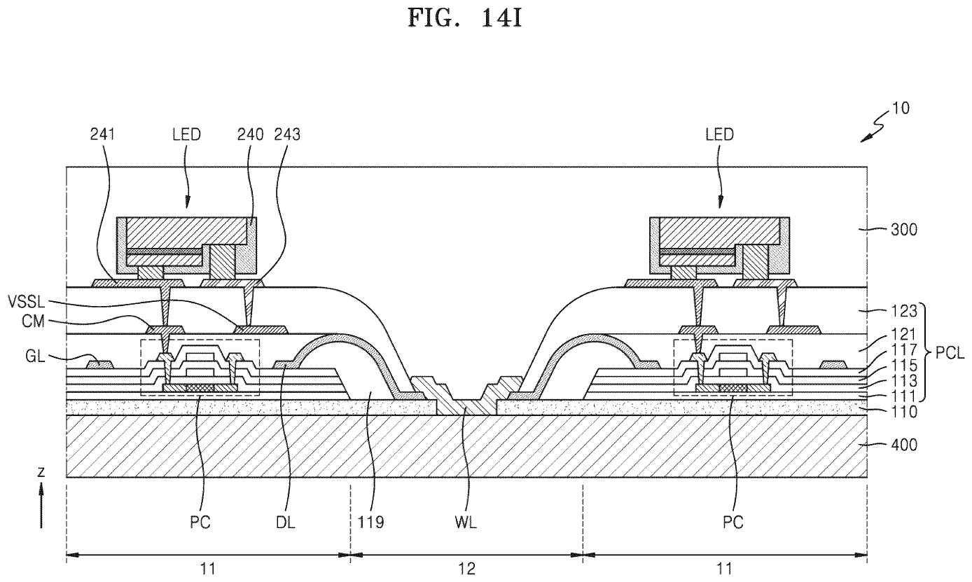

FIGS. 14A through 14I are cross-sectional views illustrating a method of manufacturing a display panel, according to one or more other embodiments. In the description of the method of manufacturing the display panel, according to the embodiments, the description of the display panel described above with reference to FIG. 12 may be applied. Descriptions of the same components in FIGS. 14A through 14I as those described above with reference to FIGS. 9 through 12 will not be provided, and differences therebetween will now be mainly explained.

First, referring to FIG. 14A, a lower layer LL may be formed to form the display panel 10 of FIG. 12. The lower layer LL may be a layer temporarily arranged to form the display panel 10 of FIG. 12 that is stretchable. The lower layer LL may include a substrate 100, a lower elastomer layer 400 arranged on the substrate 100, and a base layer 110 arranged on the lower elastomer layer 400.

A portion of an inorganic insulating layer IIL and a portion of the thin-film transistor TFT (e.g., as described in connection with FIG. 10) may be formed on the lower layer LL. However, the inorganic insulating layer IIL may be arranged only in the pixel area 11, and may not be arranged in the connection area 12. For example, a portion of the inorganic insulating layer IIL that overlaps the connection area 12 may be removed by etching.

Next, referring to FIG. 14B, the sub-organic insulating layer 119 may be formed on the second interlayer insulating layer 117. The sub-organic insulating layer 119 may cover a side surface of the inorganic insulating layer IIL from which a portion has been removed. The source electrode SE and the drain electrode DE (e.g., as described in connection with FIG. 10) of the pixel circuit PC may be formed on the second interlayer insulating layer 117, and the gate line GL and the data line DL may be formed on the second interlayer insulating layer 117 and the sub-organic insulating layer 119.

The first organic insulating layer 121 may be formed on the pixel circuit PC, and the connection electrode CM and the second voltage line VSSL may be formed on the first organic insulating layer 121. The second organic insulating layer 123 may be formed on the connection electrode CM, and the first electrode pad 241 and the second electrode pad 243 may be formed on the second organic insulating layer 123.

Next, referring to FIG. 14C, an opening 110OP may be formed in the base layer 110. For example, a partial area of the base layer 110 that overlaps the connection area 12 may be removed. The partial area of the base layer 110 may be removed through a dry etching process. As the opening 110OP is formed in the base layer 110, a portion of an upper surface of the lower elastomer layer 400 may be exposed.

Next, referring to FIG. 14D, the sacrificial layer 600 may be formed on the pixel circuit layer PCL. The sacrificial layer 600 may be patterned to have an opening 600OP that overlaps the connection area 12. The opening 600OP of the sacrificial layer 600 may partially overlap the opening 110OP of the base layer 110. According to one or more embodiments, the sacrificial layer 600 may be formed through a dispensing process and/or an inkjet printing process. However, this is merely an example, and the method of forming the sacrificial layer 600 may suitably vary.

The connection wiring WL of FIG. 12 may be arranged in the opening 600OP of the sacrificial layer 600. For example, the sacrificial layer 600 may be a layer temporarily used to pattern the connection wiring WL of FIG. 12. According to one or more embodiments, if (e.g., when) the connection wiring WL of FIG. 12 is formed of liquid metal, the sacrificial layer 600 may include a liquid metal adhesion inhibitor. However, this is merely an example, and the material of the sacrificial layer 600 may not be limited as long as it is a material having hydrophobicity.

Next, referring to FIG. 14E, the connection wiring WL may be formed within the opening 600OP of FIG. 14D of the sacrificial layer 600. Because the opening 600OP of FIG. 14D of the sacrificial layer 600 partially overlaps with the opening 110OP of FIG. 14D of the base layer 110, the connection wiring WL may fill the opening 110OP of FIG. 14D of the base layer 110. For example, the connection wiring WL may fill the opening 110OP of FIG. 14D of the base layer 110, and may cover up to the upper surface of the base layer 110 exposed through the opening 600OP of FIG. 14D of the sacrificial layer 600.

According to one or more embodiments, the connection wiring WL may include liquid metal, and a material for forming the connection wiring WL may be applied using, for example, a roller and/or a stamp. However, because detailed patterning may be relatively difficult to implement if (e.g., when) using, for example, a roller and/or a stamp, the material for forming the connection wiring WL may be applied up to an area around the opening 600OP of FIG. 14D. At this time, if (e.g., when) the sacrificial layer 600 includes a liquid metal adhesion inhibitor, the material for forming the connection wiring WL may not be arranged on the sacrificial layer 600, but may be arranged only within the opening 600OP of FIG. 14D. For example, the connection wiring WL may be patterned through an opening of the sacrificial layer 600 including a hydrophobic material.

Next, referring to FIG. 14F, the sacrificial layer 600 of FIG. 14E may be removed. The sacrificial layer 600 of FIG. 14E including a hydrophobic material, such as a liquid metal adhesion inhibitor, may be removed through a cleaning process using water. Accordingly, only the connection wiring WL formed within an opening of the sacrificial layer 600 of FIG. 14E may remain in the connection area 12.

For example, according to the method of manufacturing a display panel, according to the embodiments, detailed patterning of the connection wiring WL may be possible, and also the sacrificial layer 600 of FIG. 14E may be completely (or substantially) removed and thus a material capable of reducing the stretchability of the display panel 10 of FIG. 12 does not remain, so that the stretchability of the display panel 10 of FIG. 12 may be improved. When the sacrificial layer 600 of FIG. 14E including a hydrophobic material remains, a bonding strength of the sacrificial layer 600 with its upper layer may be weakened. Accordingly, as the sacrificial layer 600 of FIG. 14E is removed, the display panel 10 of FIG. 12 according to the embodiments may also secure (or attain) improved structural stability.

Next, referring to FIG. 14G, a light-emitting diode LED may be formed on the pixel circuit layer PCL. The light-emitting diode LED may be arranged in the pixel area 11. The light-emitting diode LED may be an inorganic light-emitting diode, as described above with reference to FIG. 8A. The light-emitting diode LED may be covered by the protective layer 240.

Next, referring to FIG. 14H, the upper elastomer layer 300 may be formed to cover the light-emitting diode LED and the connection wiring WL. The upper elastomer layer 300 may include the same material as the material described above with reference to FIG. 6. The upper elastomer layer 300 may be formed through a thermal curing process, after the material constituting the upper elastomer layer 300 is deposited.

A carrier film 500 may be formed on the upper elastomer layer 300. In some embodiments, the carrier film 500 may be attached to the upper surface of the upper elastomer layer 300 through an adhesive layer located between the upper elastomer layer 300 and the carrier film 500. However, this is merely an example, and the method of curing the upper elastomer layer 300 and the method of attaching the carrier film 500 may suitably vary.

Next, referring to FIG. 14I, the substrate 100 may be detached. For example, the substrate 100 of FIG. 14H may be removed from the lower elastomer layer 400. By radiating a laser to another surface of the substrate 100 of FIG. 14H that is opposite to one surface of the substrate 100 of FIG. 14H that is in contact with the lower elastomer layer 400, a bonding force between the substrate 100 of FIG. 14H and the lower elastomer layer 400 may be weakened.

After the substrate 100 of FIG. 14H is detached, the carrier film 500 of FIG. 14H attached to the upper surface of the display panel 10 may also be removed. The carrier film 500 of FIG. 14H may be removed using a peeling tape. However, this is merely an example, and the method of removing the substrate 100 of FIG. 14H and the method of removing the carrier film 500 of FIG. 14H may suitably vary.

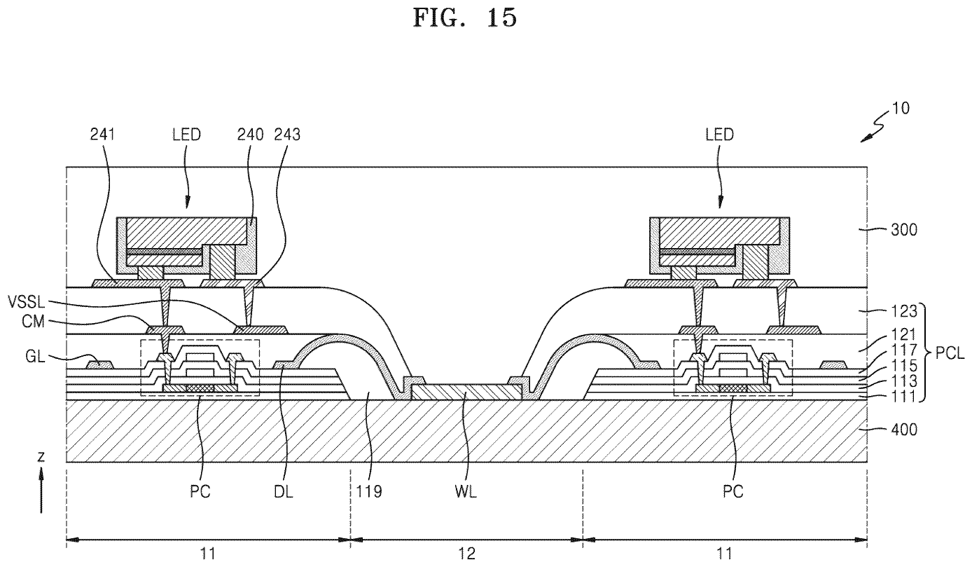

FIG. 15 is a schematic cross-sectional view of a portion of a display panel according to one or more other embodiments. Other features in FIG. 15 except for the features of the connection wiring WL are the same as those described above with reference to FIGS. 9 and 10. Descriptions of the same components in FIG. 15 as those described above with reference to FIGS. 9 and 10 will not be provided, and differences therebetween will now be mainly explained.

Referring to FIG. 15, the display panel 10 may include the lower elastomer layer 400. The display panel 10 may define pixel areas 11 and a connection area 12 between the pixel areas 11. A pixel circuit layer PCL including a pixel circuit PC and a light-emitting diode LED arranged on the pixel circuit layer PCL may be arranged in each of the pixel areas 11 of the lower elastomer layer 400.

According to one or more embodiments, the connection wiring WL may be arranged in the connection area 12 of the lower elastomer layer 400. The connection wiring WL may be arranged on an upper surface of the lower elastomer layer 400, as shown in FIG. 15. For example, only the lower surface of the connection wiring WL may be in contact with the lower elastomer layer 400, and the side surface of the connection wiring WL may be covered with the data line DL or the sub-organic insulating layer 119.

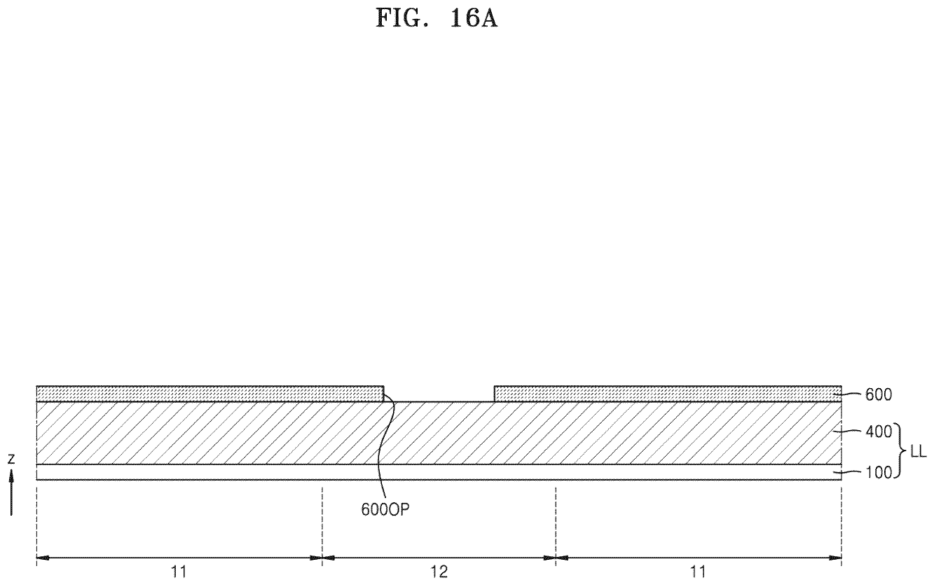

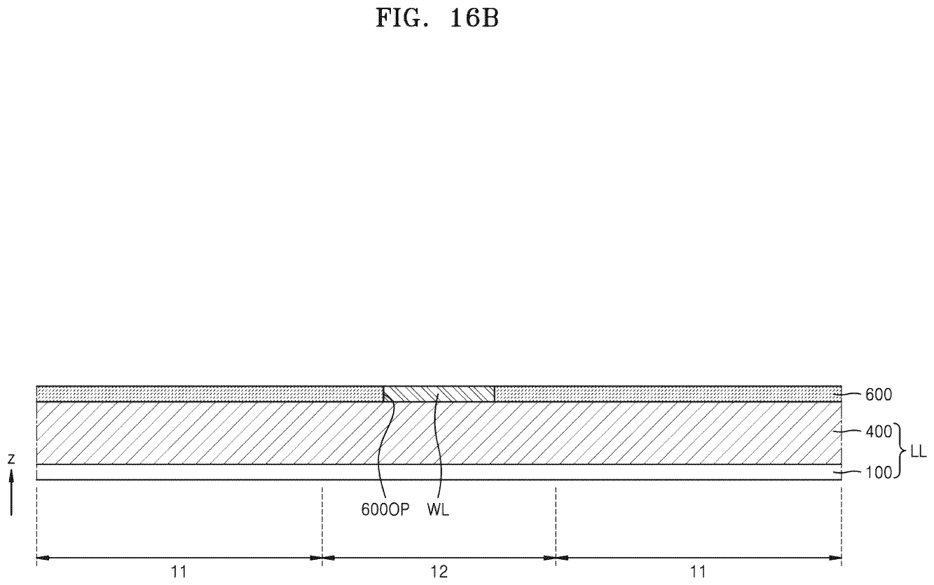

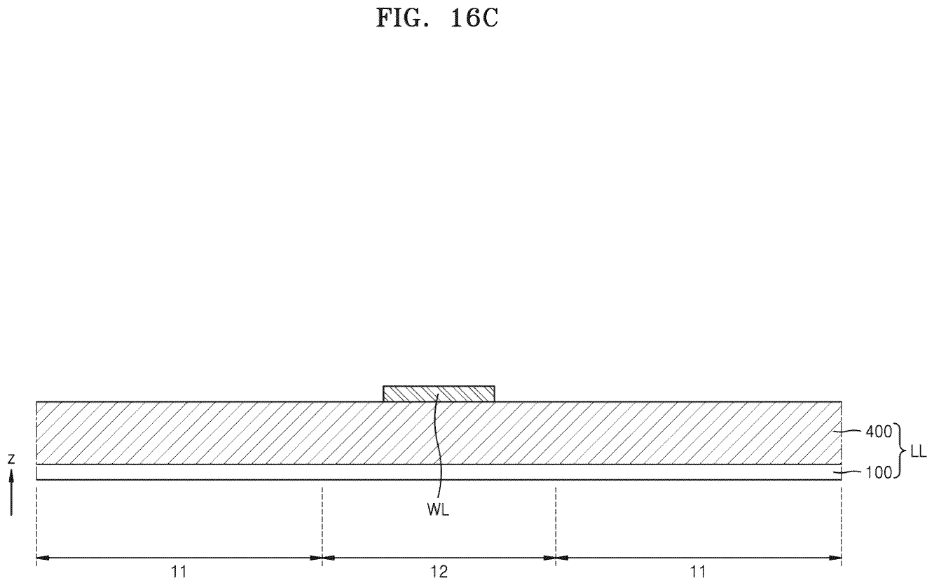

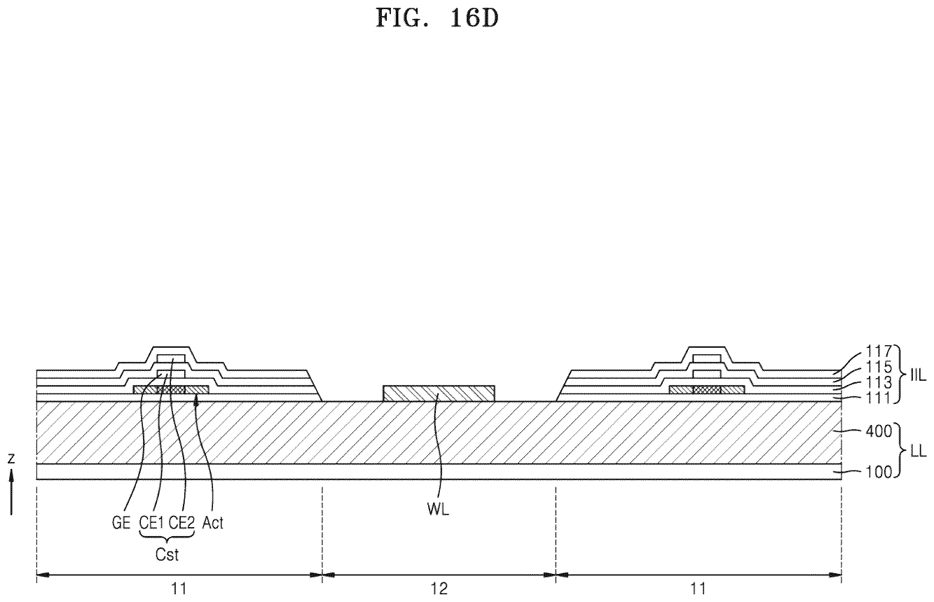

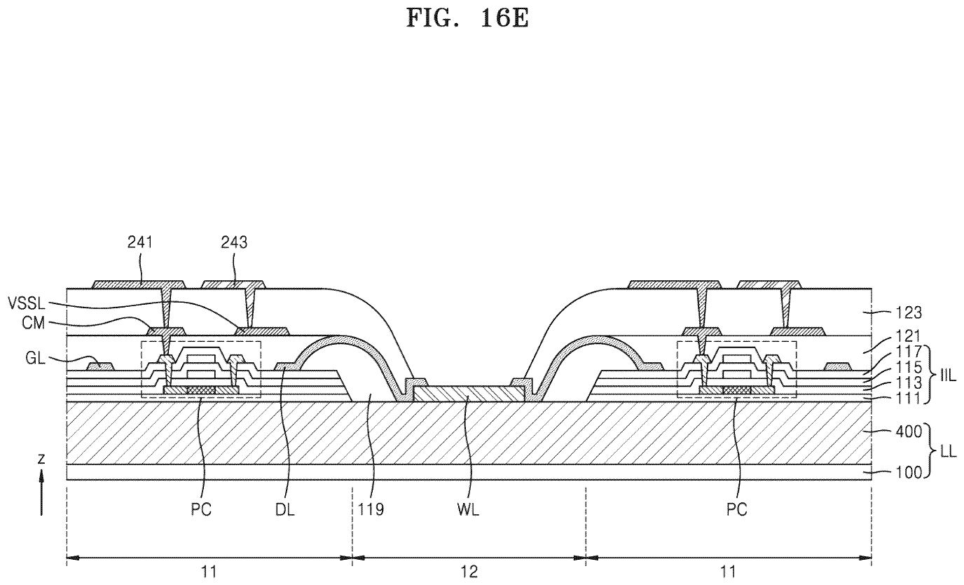

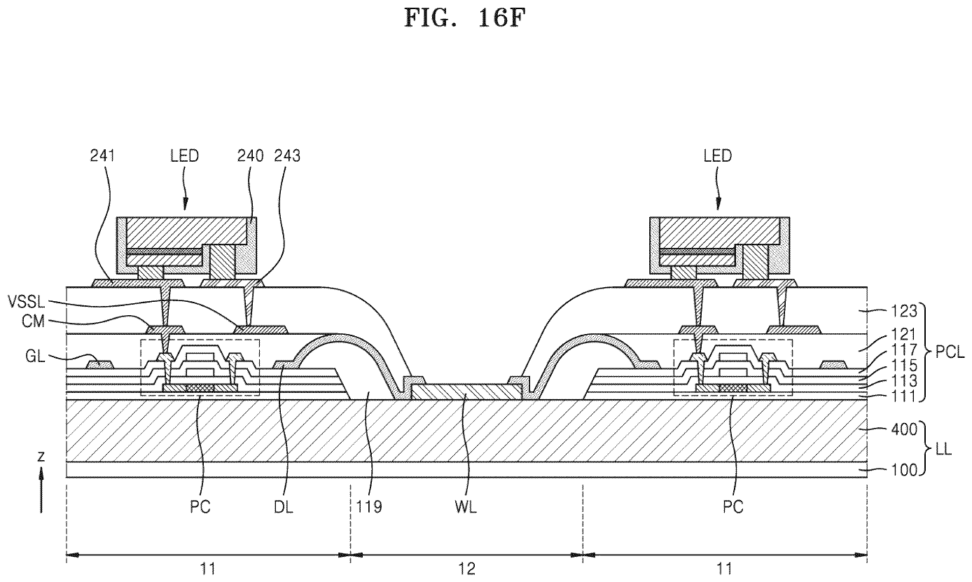

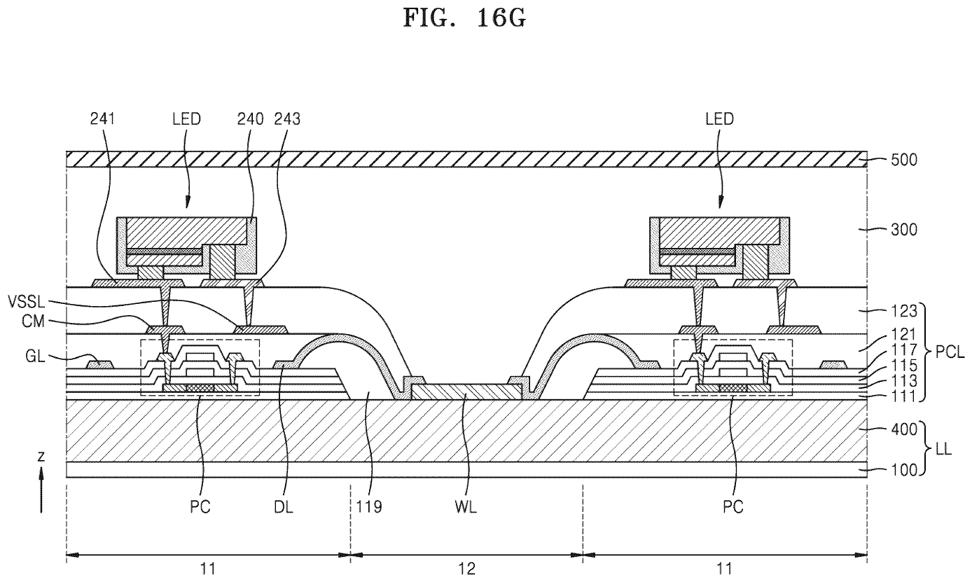

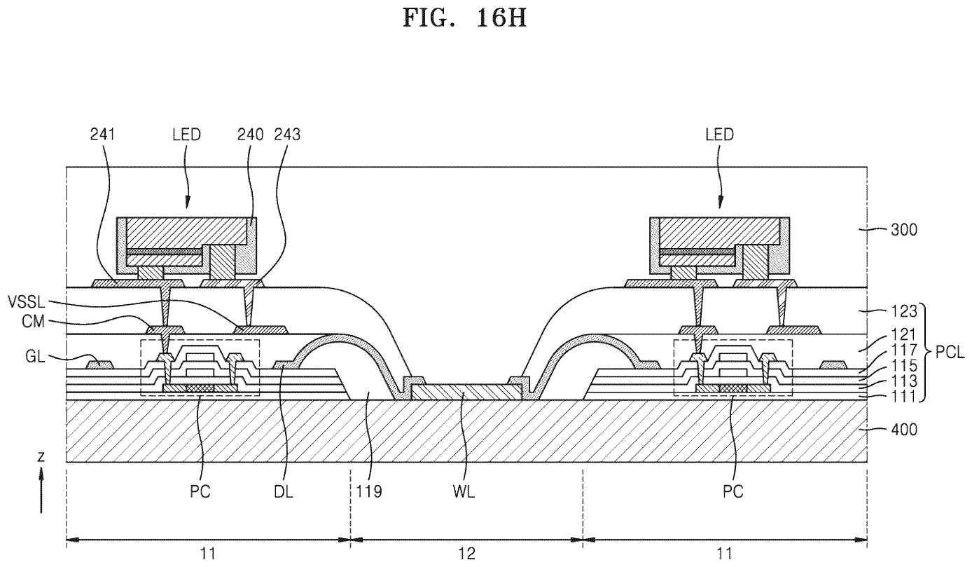

FIGS. 16A through 16H are cross-sectional views illustrating a method of manufacturing a display panel, according to the one or more other embodiments. In the description of the method of manufacturing the display panel, according to the embodiments, the description of the display panel described above with reference to FIG. 15 may be applied. Descriptions of the same components in FIGS. 16A through 16H as those described above with reference to FIGS. 9, 10, and 15 will not be provided, and differences therebetween will now be mainly explained.

First, referring to FIG. 16A, a lower layer LL may be formed to form the display panel 10 of FIG. 15. According to one or more embodiments, the lower layer LL may include a substrate 100, and a lower elastomer layer 400 arranged on the substrate 100.

A sacrificial layer 600 may be formed on the lower layer LL. The sacrificial layer 600 may be patterned to have an opening 600OP that overlaps the connection area 12. According to one or more embodiments, the sacrificial layer 600 may be formed through a dispensing process and/or an inkjet printing process. However, this is merely an example, and the method of forming the sacrificial layer 600 may suitably vary.

The connection wiring WL of FIG. 15 may be arranged in the opening 600OP of the sacrificial layer 600. For example, the sacrificial layer 600 may be a layer temporarily used to pattern the connection wiring WL of FIG. 15. According to one or more embodiments, if (e.g., when) the connection wiring WL of FIG. 15 is formed of liquid metal, the sacrificial layer 600 may include a liquid metal adhesion inhibitor. However, this is merely an example, and the material of the sacrificial layer 600 may not be limited as long as it is a material having hydrophobicity.

Next, referring to FIG. 16B, the connection wiring WL may be formed within the opening 600OP of the sacrificial layer 600. In a plan view, an area of the connection wiring WL may be equal to an area of the lower elastomer layer 400 whose upper surface is exposed through the opening 600OP. For example, a length of the connection wiring WL may be the same as a length of the exposed upper surface of the lower elastomer layer 400 through the opening 600OP. According to one or more embodiments, the connection wiring WL may include liquid metal, and a material for forming the connection wiring WL may be applied using, for example, a roller or a stamp. However, because detailed patterning may be relatively difficult to implement if (e.g., when) using, for example, a roller and/or a stamp, the material for forming the connection wiring WL may be applied up to an area around the opening 600OP. At this time, if (e.g., when) the sacrificial layer 600 includes a liquid metal adhesion inhibitor as described above, the material for forming the connection wiring WL may not be arranged on the sacrificial layer 600, but may be arranged only within the opening 600OP. For example, the connection wiring WL may be patterned through an opening of the sacrificial layer 600 including a hydrophobic material.

Next, referring to FIG. 16C, the sacrificial layer 600 of FIG. 16B may be removed. The sacrificial layer 600 of FIG. 16B including a hydrophobic material, such as a liquid metal adhesion inhibitor, may be removed through a cleaning process using water. Accordingly, only the connection wiring WL formed within the opening 600OP of FIG. 16B of the sacrificial layer 600 of FIG. 16B may remain on the upper surface of the lower elastomer layer 400.

For example, according to the method of manufacturing a display panel, according to the one or more embodiments, detailed patterning of the connection wiring WL may be possible, and also the sacrificial layer 600 of FIG. 16B may be completely (or substantially) removed and thus a material capable of reducing the stretchability of the display panel 10 of FIG. 15 does not remain, so that the stretchability of the display panel 10 of FIG. 15 may be improved. When the sacrificial layer 600 of FIG. 16B including a hydrophobic material remains, a bonding strength of the sacrificial layer 600 with its upper layer may be weakened. Accordingly, as the sacrificial layer 600 of FIG. 16B is removed, the display panel 10 of FIG. 15 according to the embodiments may also secure (or attain) improved structural stability.

Next, referring to FIG. 16D, a portion of an inorganic insulating layer IIL and a portion of the thin-film transistor TFT of FIG. 10 may be formed on the lower layer LL. However, the inorganic insulating layer IIL may be arranged only in the pixel area 11, and may not be arranged in the connection area 12. For example, a portion of the inorganic insulating layer IIL that overlaps the connection area 12 may be removed by etching.

Next, referring to FIG. 16E, the sub-organic insulating layer 119 may be formed on the second interlayer insulating layer 117. The sub-organic insulating layer 119 may cover a side surface of the inorganic insulating layer IIL from which a portion has been removed. The source electrode SE and the drain electrode DE (e.g., as described in connection with FIG. 10) of the pixel circuit PC may be formed on the second interlayer insulating layer 117, and the gate line GL and the data line DL may be formed on the second interlayer insulating layer 117 and the sub-organic insulating layer 119.

The first organic insulating layer 121 may be formed on the pixel circuit PC, and the connection electrode CM and the second voltage line VSSL may be formed on the first organic insulating layer 121. The second organic insulating layer 123 may be formed on the connection electrode CM, and the first electrode pad 241 and the second electrode pad 243 may be formed on the second organic insulating layer 123.

Next, referring to FIG. 16F, a light-emitting diode LED may be formed on the pixel circuit layer PCL. The light-emitting diode LED may be arranged in the pixel area 11. The light-emitting diode LED may be an inorganic light-emitting diode, as described above with reference to FIG. 8A. The light-emitting diode LED may be covered by the protective layer 240.

Next, referring to FIG. 16G, the upper elastomer layer 300 may be formed to cover the light-emitting diode LED and the connection wiring WL. The upper elastomer layer 300 may include the same material as the material described herein above with reference to FIG. 6. The upper elastomer layer 300 may be formed through a thermal curing process, after the material constituting the upper elastomer layer 300 is deposited.

A carrier film 500 may be formed on the upper elastomer layer 300. Although not shown in FIG. 16G, the carrier film 500 may be attached to the upper surface of the upper elastomer layer 300 through an adhesive layer located between the upper elastomer layer 300 and the carrier film 500. However, this is merely an example, and the method of curing the upper elastomer layer 300 and the method of attaching the carrier film 500 may suitably vary.

Next, referring to FIG. 16H, the substrate 100 may be detached. For example, the substrate 100 of FIG. 16G may be removed from the lower elastomer layer 400. By radiating a laser to another surface of the substrate 100 of FIG. 16G that is opposite to one surface of the substrate 100 of FIG. 16G that is in contact with the lower elastomer layer 400, a bonding force between the substrate 100 of FIG. 16G and the lower elastomer layer 400 may be weakened.

After the substrate 100 of FIG. 16G is detached, the carrier film 500 of FIG. 16G attached to the upper surface of the display panel 10 of FIG. 15 may also be removed. The carrier film 500 of FIG. 16G may be removed using a peeling tape. However, this is merely an example, and the method of removing the substrate 100 of FIG. 16G and the method of removing the carrier film 500 of FIG. 16G may suitably vary.

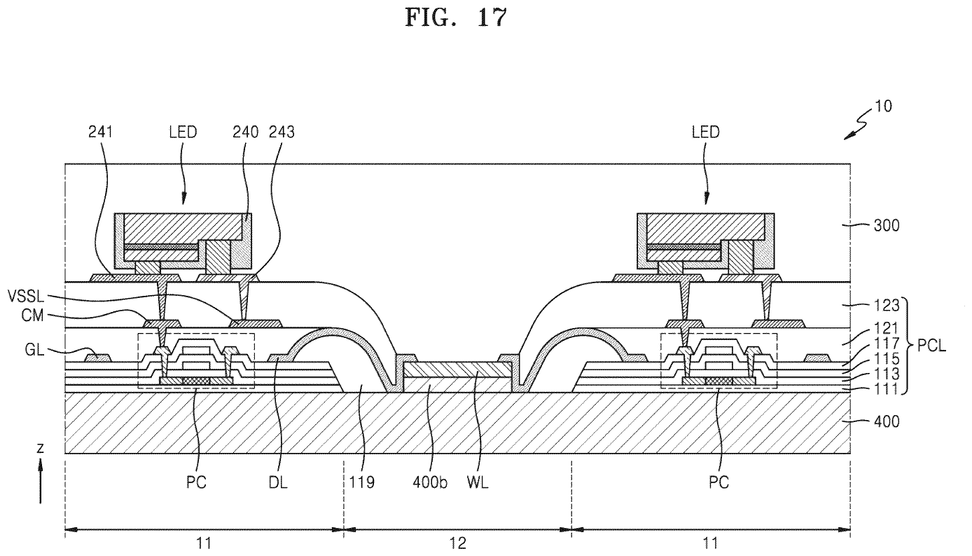

FIG. 17 is a schematic cross-sectional view of a portion of a display panel according to one or more other embodiments. Other features in FIG. 17 except for the features of the connection wiring WL are the same as those described above with reference to FIGS. 9 and 10. Descriptions of the same components in FIG. 17 as those described above with reference to FIGS. 9 and 10 will not be provided, and differences therebetween will now be mainly explained.

Referring to FIG. 17, the display panel 10 may include the lower elastomer layer 400. The display panel 10 may define pixel areas 11 and a connection area 12 between the pixel areas 11. A pixel circuit layer PCL including a pixel circuit PC and a light-emitting diode LED arranged on the pixel circuit layer PCL may be arranged in each of the pixel areas 11 of the lower elastomer layer 400.

According to one or more embodiments, a sub-elastomer layer 400b may be arranged in the connection area 12 of the lower elastomer layer 400. The sub-elastomer layer 400b may be arranged to overlap only a portion of the connection area 12, unlike the lower elastomer layer 400 being arranged on the entire display area DA (e.g., as described in connection with FIG. 4).

According to one or more embodiments, the sub-elastomer layer 400b may include the same material as that included in the lower elastomer layer 400. For example, the sub-elastomer layer 400b may include at least one selected from among thermoplastic polyurethane, silicon, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and ecoflex. However, embodiments are not limited thereto, and the sub-elastomer layer 400b may include a different material from that included in the lower elastomer layer 400.

According to one or more embodiments, the connection wiring WL may be arranged on the sub-elastomer layer 400b. The sub-elastomer layer 400b and the connection wiring WL may be arranged to overlap each other in a plan view. In a plan view, an area of the connection wiring WL may be equal to an area of the sub-elastomer layer 400b, or may be less than the area of the sub-elastomer layer 400b. For example, a lower surface of the connection wiring WL may be in contact with only the sub-elastomer layer 400b.

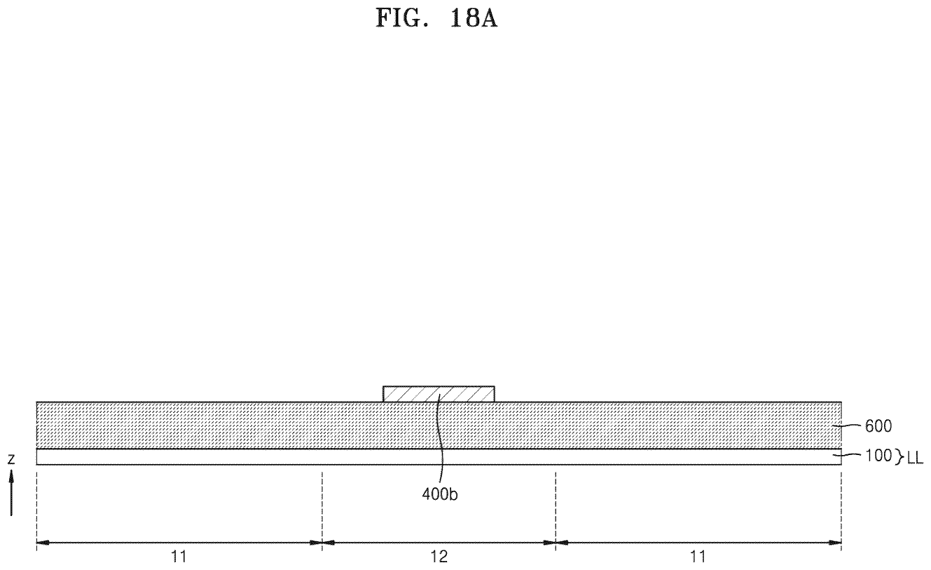

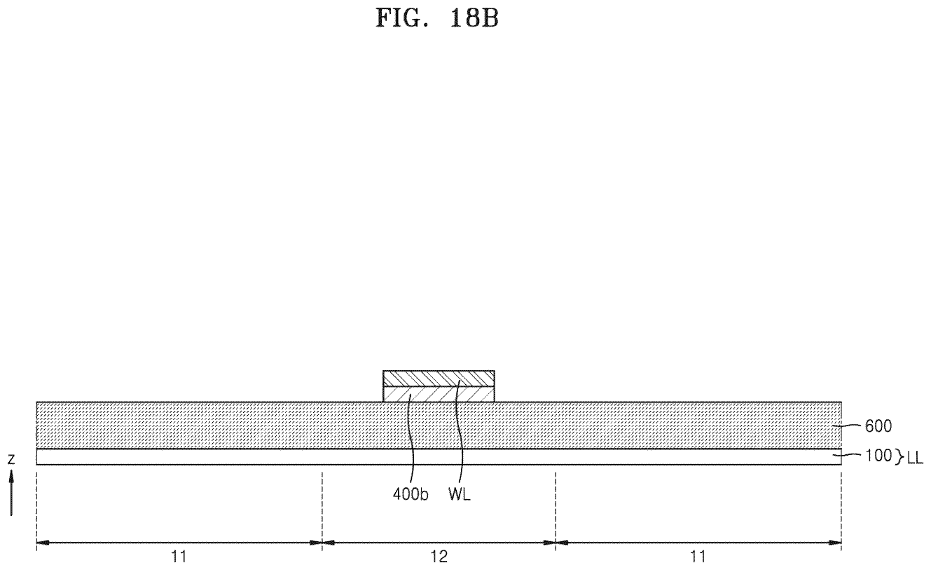

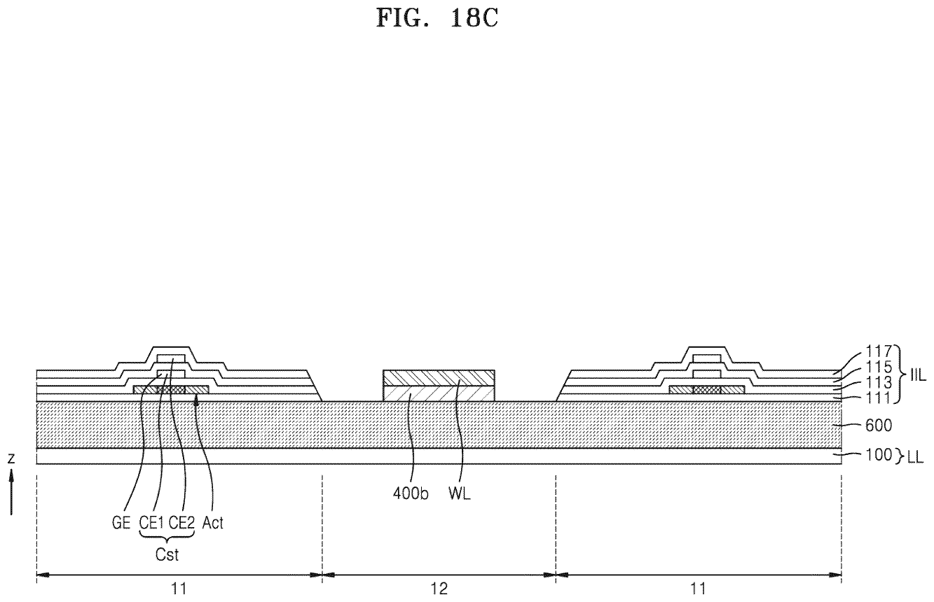

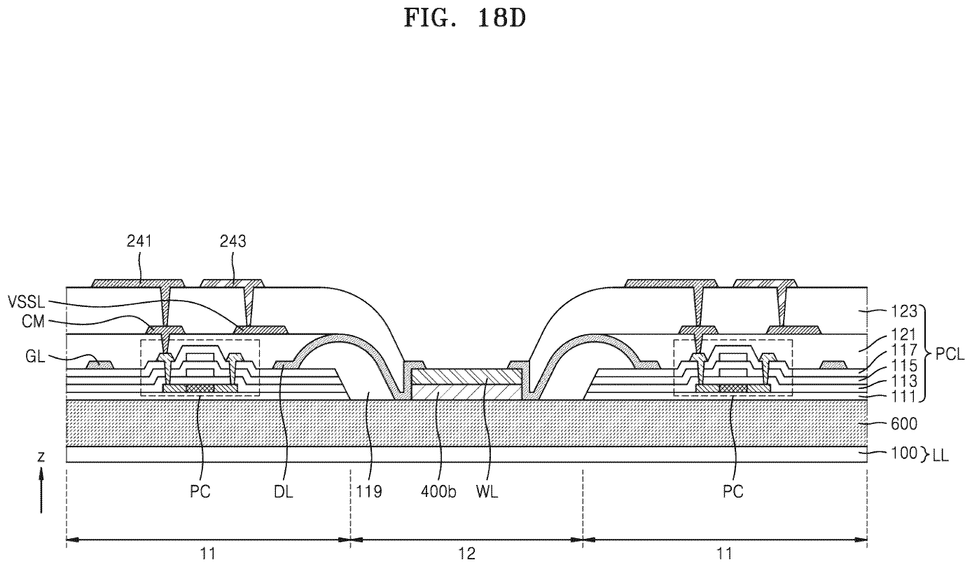

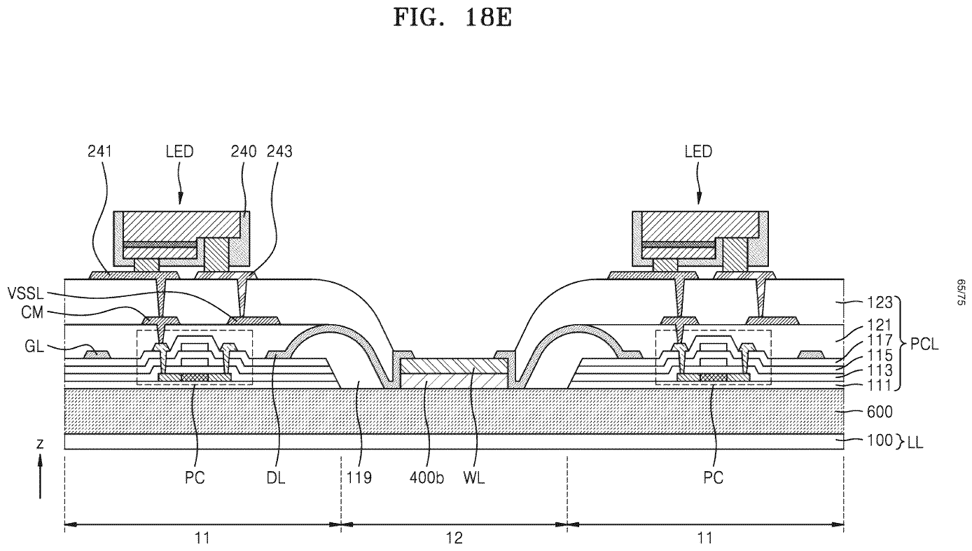

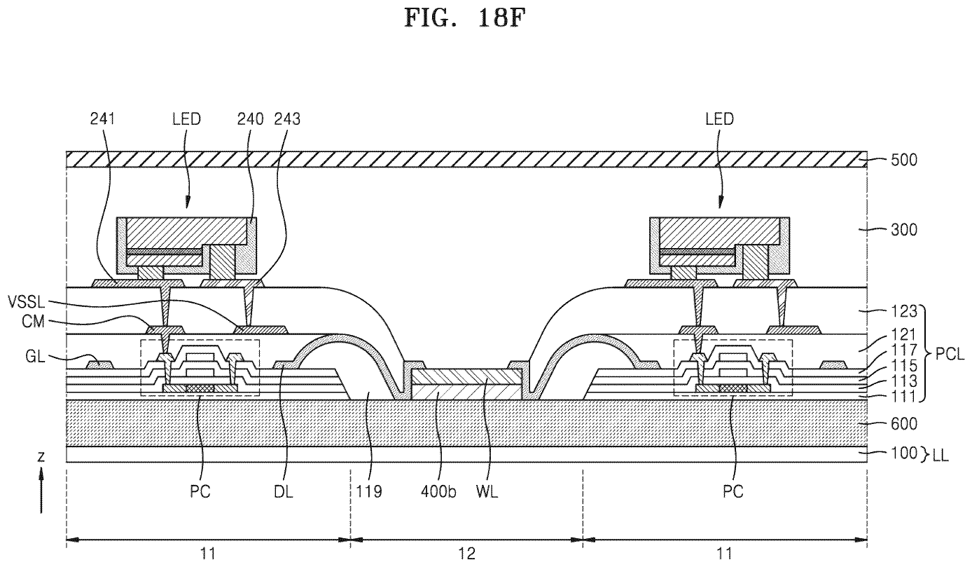

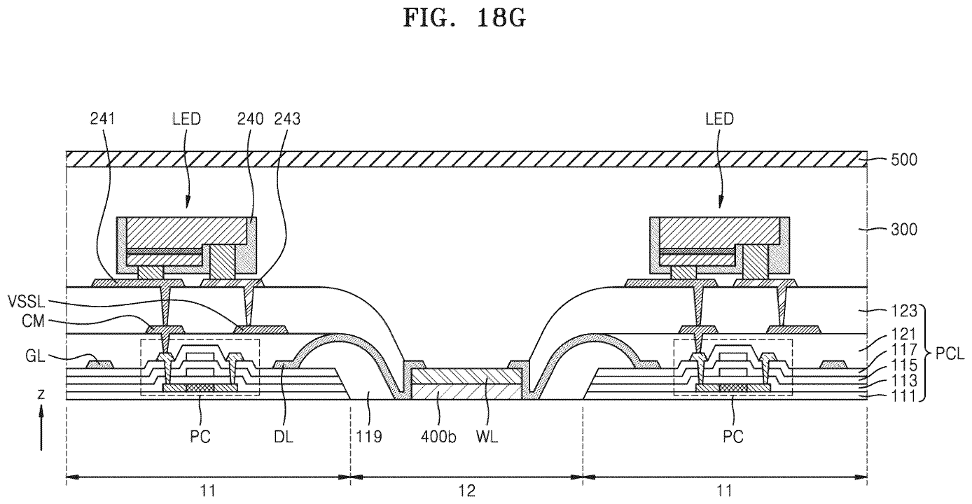

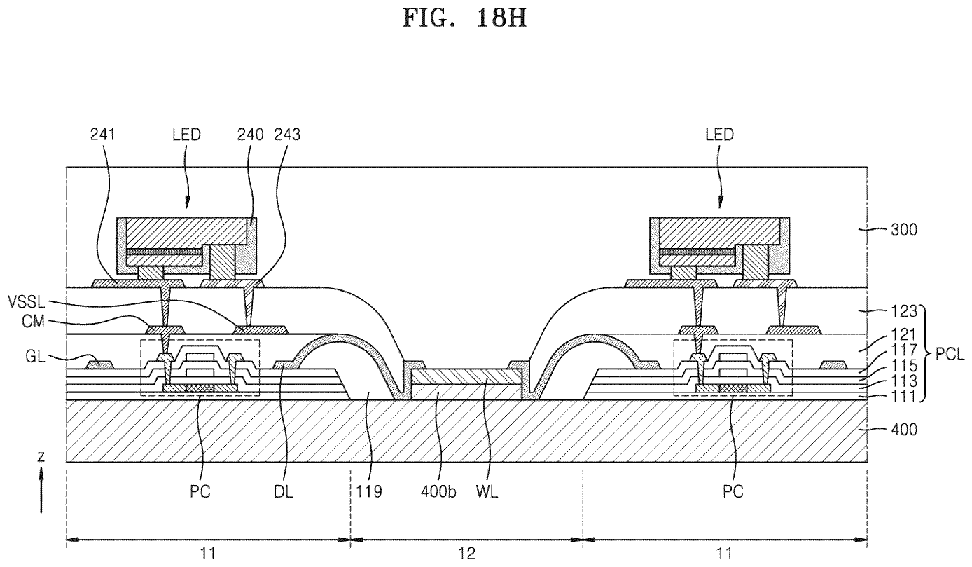

FIGS. 18A through 18H are cross-sectional views illustrating a method of manufacturing a display panel, according to the one or more other embodiments. In the description of the method of manufacturing the display panel, according to the embodiments, the description of the display panel described above with reference to FIG. 17 may be applied. Descriptions of the same components in FIGS. 18A through 18H as those described above with reference to FIGS. 9, 10, and 17 will not be provided, and differences therebetween will now be mainly explained.

First, referring to FIG. 18A, a lower layer LL may be formed to form the display panel 10 of FIG. 17. According to one or more embodiments, the lower layer LL may include the substrate 100. A sacrificial layer 600 may be formed on the substrate 100, which is the lower layer LL. According to one or more embodiments, the sacrificial layer 600 may be formed through a dispensing process and/or an inkjet printing process. However, this is merely an example, and the method of forming the sacrificial layer 600 may vary. According to one or more embodiments, if (e.g., when) the connection wiring WL of FIG. 17 is formed of liquid metal, the sacrificial layer 600 may include a liquid metal adhesion inhibitor. However, this is merely an example, and the material of the sacrificial layer 600 may not be limited as long as it is a material having hydrophobicity.

The sub-elastomer layer 400b may be formed on the sacrificial layer 600. The sub-elastomer layer 400b may be patterned so as to overlap only a portion of the connection area 12. For example, the sub-elastomer layer 400b may be a material that is pre-deposited in an area that needs the connection wiring WL of FIG. 17. According to one or more embodiments, a thickness of the sub-elastomer layer 400b may be less than a thickness of the lower elastomer layer 400 of FIG. 17.

Next, referring to FIG. 18B, the connection wiring WL may be formed on an upper surface of the sub-elastomer layer 400b. In a plan view, an area of the connection wiring WL may be equal to an area of the upper surface of the sub-elastomer layer 400b, or may be less than the area of the upper surface of the sub-elastomer layer 400b.

According to one or more embodiments, the connection wiring WL may include liquid metal, and a material for forming the connection wiring WL may be applied using, for example, a roller and/or a stamp. However, because detailed patterning may be relatively difficult to implement if (e.g., when) using, for example, a roller and/or a stamp, the material for forming the connection wiring WL may be applied up to an area around the sub-elastomer layer 400b. At this time, if (e.g., when) the sacrificial layer 600 includes a liquid metal adhesion inhibitor as described above, the material for forming the connection wiring WL may not be arranged on the sacrificial layer 600, but may be arranged only on the upper surface of the sub-elastomer layer 400b. For example, the connection wiring WL may be patterned through the sacrificial layer 600 and the sub-elastomer layer 400b.

Next, referring to FIG. 18C, a portion of an inorganic insulating layer IIL and a portion of the thin-film transistor TFT (e.g., as described in connection with FIG. 10) may be formed on the sacrificial layer 600. However, the inorganic insulating layer IIL may be arranged only in the pixel area 11, and may not be arranged in the connection area 12. For example, a portion of the inorganic insulating layer IIL that overlaps the connection area 12 may be removed by etching.

Next, referring to FIG. 18D, the sub-organic insulating layer 119 may be formed on the second interlayer insulating layer 117. The sub-organic insulating layer 119 may cover a side surface of the inorganic insulating layer IIL from which a portion has been removed. The source electrode SE and the drain electrode DE (e.g., as described in connection with FIG. 10) of the pixel circuit PC may be formed on the second interlayer insulating layer 117, and the gate line GL and the data line DL may be formed on the second interlayer insulating layer 117 and the sub-organic insulating layer 119.

The first organic insulating layer 121 may be formed on the pixel circuit PC, and the connection electrode CM and the second voltage line VSSL may be formed on the first organic insulating layer 121. The second organic insulating layer 123 may be formed on the connection electrode CM, and the first electrode pad 241 and the second electrode pad 243 may be formed on the second organic insulating layer 123.

Next, referring to FIG. 18E, a light-emitting diode LED may be formed on the pixel circuit layer PCL. The light-emitting diode LED may be arranged in the pixel area 11. The light-emitting diode LED may be an inorganic light-emitting diode, e.g., as described above with reference to FIG. 8A. The light-emitting diode LED may be covered by the protective layer 240.

Next, referring to FIG. 18F, the upper elastomer layer 300 may be formed to cover the light-emitting diode LED and the connection wiring WL. The upper elastomer layer 300 may include the same material as the material described herein above with reference to FIG. 6. The upper elastomer layer 300 may be formed through a thermal curing process, after the material constituting the upper elastomer layer 300 is deposited.

A carrier film 500 may be formed on the upper elastomer layer 300. In some embodiments, the carrier film 500 may be attached to the upper surface of the upper elastomer layer 300 through an adhesive layer located between the upper elastomer layer 300 and the carrier film 500. However, this is merely an example, and the method of curing the upper elastomer layer 300 and the method of attaching the carrier film 500 may suitably vary.

Next, referring to FIG. 18G, the lower layer LL of FIG. 18F may be removed from the structure of FIG. 18F. For example, the substrate 100 of FIG. 18F may be detached from the structure of FIG. 18F. By radiating a laser to another surface of the substrate 100 of FIG. 18F that is opposite to one surface of the substrate 100 of FIG. 18F that is in contact with the sacrificial layer 600, a bonding force between the substrate 100 of FIG. 18F and the sacrificial layer 600 may be weakened.

After the substrate 100 of FIG. 18F is detached, the sacrificial layer 600 may be removed. The sacrificial layer 600 of FIG. 18F including a hydrophobic material, such as a liquid metal adhesion inhibitor, may be removed through a cleaning process using water. As the entire sacrificial layer 600 of FIG. 18F is removed, a lower surface of the pixel circuit layer PCL, a lower surface of the sub-organic insulating layer 119, and a lower surface of the sub-elastomer layer 400b may be exposed.

For example, according to the method of manufacturing a display panel according to the one or more other embodiments, detailed patterning of the connection wiring WL may be possible, and also the sacrificial layer 600 of FIG. 18F may be completely (e.g., substantially) removed and thus a material capable of reducing the stretchability of the display panel 10 of FIG. 17 does not remain, so that the stretchability of the display panel 10 of FIG. 17 may be improved. When the sacrificial layer 600 of FIG. 18F including a hydrophobic material remains, a bonding strength of the sacrificial layer 600 with its upper layer may be weakened. Accordingly, as the sacrificial layer 600 of FIG. 18F is removed, the display panel 10 of FIG. 17 according to the embodiments may also secure (or attain) improved structural stability.

Next, referring to FIG. 18H, the lower elastomer layer 400 may be formed on the lower surface of the pixel circuit layer PCL, the lower surface of the sub-organic insulating layer 119, and the lower surface of the sub-elastomer layer 400b. The lower elastomer layer 400 may encapsulate the bottom of the display panel 10 of FIG. 17.

After the lower elastomer layer 400 is formed, the carrier film 500 of FIG. 18G attached to the upper surface of the display panel 10 may be removed. The carrier film 500 of FIG. 18G may be removed using a peeling tape. However, this is merely an example, and the method of removing the carrier film 500 of FIG. 18G may suitably vary.

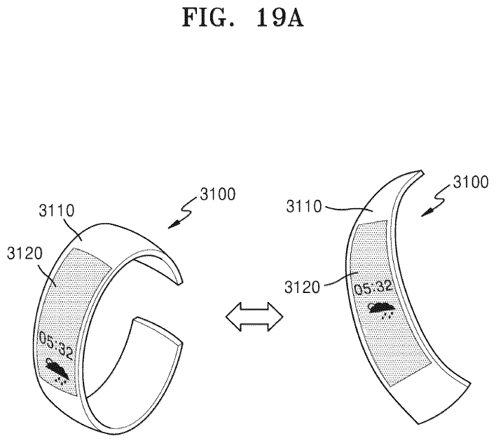

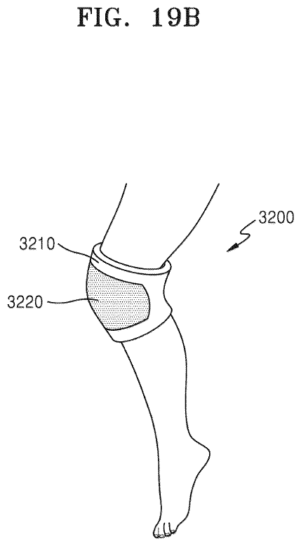

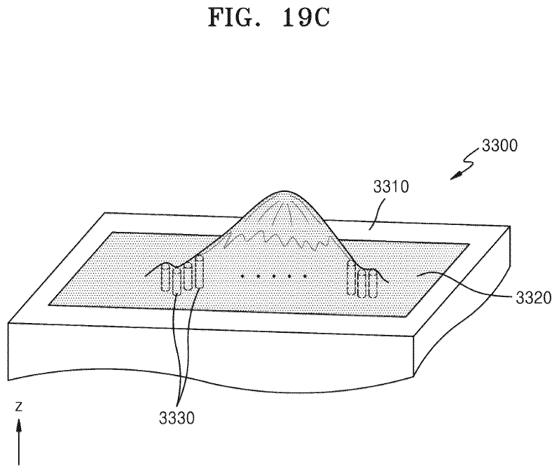

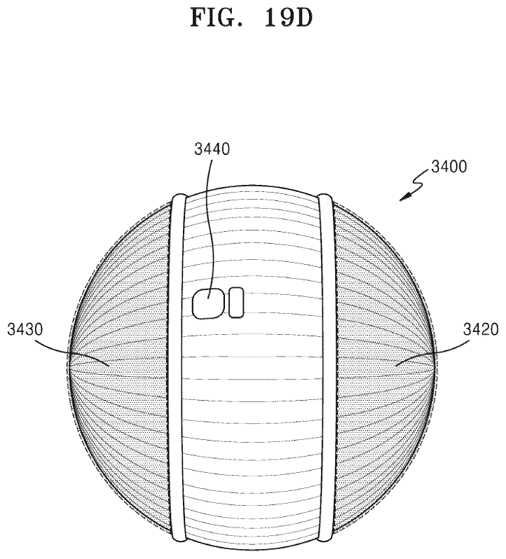

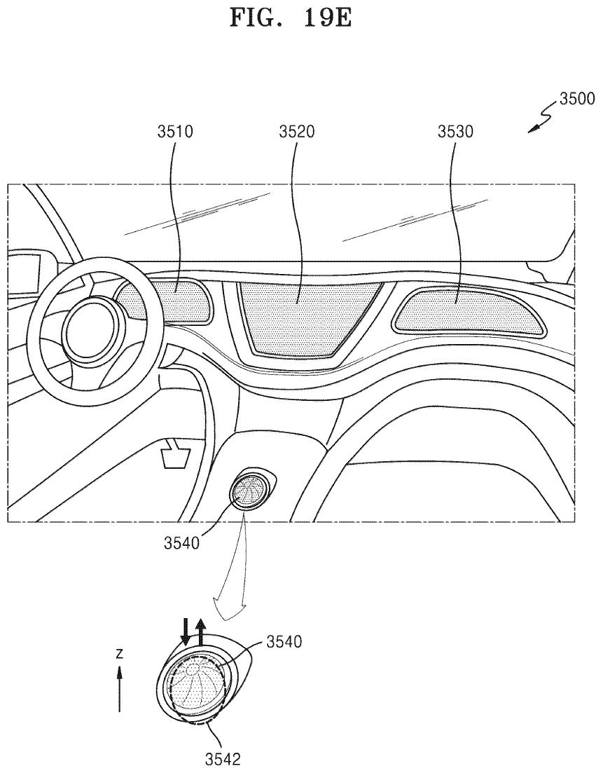

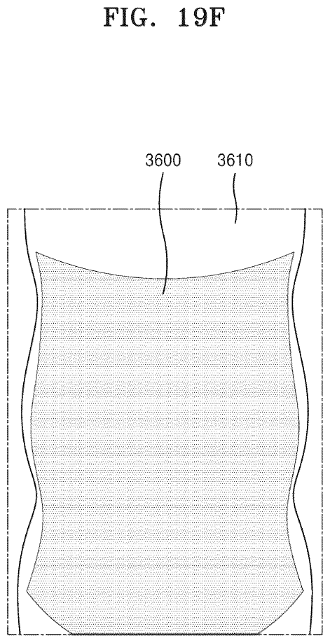

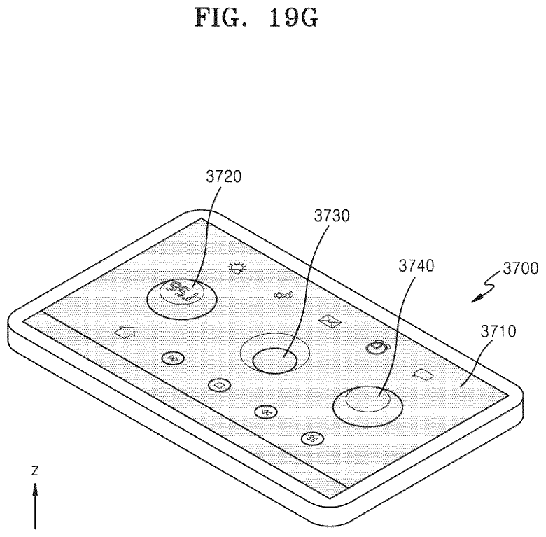

FIGS. 19A through 19G are each a schematic perspective view of embodiments of an electronic apparatus including a display panel according to one or more embodiments.

Referring to FIG. 19A, the display panel according to one or more embodiments may be utilized in a wearable electronic apparatus 3100 that may be worn on a portion of a user's body. The wearable electronic apparatus 3100 may include a body portion 3110, and a display 3120 provided in the body portion 3110.

The display panel according to one or more embodiments may be used as a display 3120 of the wearable electronic apparatus 3100. As shown in FIG. 19A, the wearable electronic apparatus 3100 may be transformed. According to one or more embodiments, the wearable electronic apparatus 3100 may be used as a smartwatch and/or a smartphone according to the user's selection.

FIG. 19B shows a medical electronic apparatus 3200. According to one or more embodiments, the medical electronic apparatus 3200 may include a body portion 3210 and an emission portion 3220. The display panel according to one or more embodiments may be used as the emission portion 3220 of the medical electronic apparatus 3200. The emission portion 3220 may be configured to emit light in a set or certain wavelength band (e.g., an infrared ray or a visible ray) to a patient's body.

According to one or more embodiments, the body portion 3210 may have a stretchable fiber material, and may have a structure that may be worn on the body of the user who uses the emission portion 3220.

FIG. 19C shows an educational electronic apparatus 3300. According to one or more embodiments, the educational electronic apparatus 3300 may include a display 3320 provided inside a frame 3310. The display 3320 may use the display panel according to one or more embodiments. Images such as sea with waves, a mountain covered with snow, and/or a volcano with flowing lava may be provided through the display 3320, and in this case, the display 3320 may extend in a height direction (e.g., a z direction) to reflect the height of waves, mountains, and/or volcanoes. According to some embodiments, because the height of a portion of the display 3320 sequentially varies in a direction in which the lava flows, the display 3320 may show the movements of lava three-dimensionally. The educational electronic apparatus 3300 may include a plurality of pins 3330 (or stroke portions) arranged on the backside of the display 3320 such that the display 3320 extends in the height direction. As the pins 3330 move in the third direction (e.g., a z direction or a −z direction), the image displayed on the display 3320 may be implemented to have a three-dimensional height. Although FIG. 19C describes the educational electronic apparatus 3300, the purpose of the electronic apparatus is not limited as long as the electronic apparatus provides set or predetermined image information.

Although the electronic apparatuses shown in FIGS. 19A through 19C are described as electronic apparatuses whose shapes are variable, embodiments are not limited thereto. As in embodiments described in more detail herein below, the display panel according to one or more embodiments may be used in an electronic apparatus in which a portion (e.g., a screen) capable of displaying images is fixed.

FIG. 19D shows a robot 3400 as an electronic apparatus according to one or more embodiments. The robot 3400 may recognize an object and/or move by using a camera 3440, and may display set or predetermined images to a user through displays 3420 and 3430. According to some embodiments, because display panels according to one or more embodiments may be stretched in one or more suitable directions as described above, the display apparatuses may be assembled to a body frame having a hemispherical shape, and thus, the robot 3400 may include the displays 3420 and 3430 each having a hemispherical shape.

FIG. 19E shows a vehicle display apparatus 3500 as an electronic apparatus according to one or more embodiments. The vehicle display apparatus 3500 may include a cluster 3510, a center information display (CID) 3520, and/or a co-driver display 3530. Because the display panel according to one or more embodiments may be stretched in one or more suitable directions, the display apparatus may be used as the cluster 3510, the CID 3520, and/or the co-driver display 3530 regardless of the shape of an internal frame of the vehicle.

Although it is shown in FIG. 19E that the cluster 3510, the CID 3520, and/or the co-driver display 3530 are separated from each other, embodiments are not limited thereto. According to some embodiments, two or more selected from among the cluster 3510, the CID 3520, and the co-driver display 3530 may be integrally connected to each other.

According to some embodiments, the vehicle display apparatus 3500 may include a button 3540 that may display set or predetermined images. Referring to an enlarged view of FIG. 19E, the button 3540 having a hemispherical shape may include an object 3542 that provides the feeling of using the button while moving in the z direction or −z direction, and a display apparatus arranged on the object 3542. According to some embodiments, if (e.g., when) the object 3542 has a surface rounded three-dimensionally (e.g., convex surface), the display apparatus may also have a surface rounded three-dimensionally (e.g., convex surface).

FIG. 19F shows that the electronic apparatus according to one or more embodiments is an electronic apparatus 3600 for advertising and/or exhibition. According to some embodiments, the electronic apparatus 3600 for advertising and/or exhibition may be installed on a structure 3610 that is fixed, such as on a wall and/or pillar. When the structure 3610 includes an uneven surface as shown in FIG. 19F, the electronic apparatus 3600 for advertising and/or exhibition may also be arranged along the uneven surface of the structure 3610. According to some embodiments, the electronic apparatus 3600 for advertising and/or exhibition may be installed on the structure 3610 by using a heat shrink film and/or the like.

FIG. 19G shows that the electronic apparatus according to one or more embodiments is a controller 3700. The controller 3700 may include an image type or kind button. For example, the controller 3700 may include first, second, and third bottom regions 3720, 3730, and 3740 in which a partial region of a display 3710 protrudes in a z direction or −z direction (or is recessed in the z direction). According to some embodiments, the first and third button regions 3720 and 3740 may each protrude in the z direction, and the second button region 3730 may protrude in the −z direction (e.g., be recessed in the z direction).

According to some embodiments, a method of manufacturing a display panel having improved stretchability and implementing quality images, and a method of manufacturing an electronic apparatus including the display panel may be provided. These effects are only examples, and the effects of the disclosure are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope of the present disclosure as defined by the following claims and equivalents thereof.

What is claimed is:

1. A method of manufacturing a display panel comprising a pixel area and a connection area surrounding the pixel area, the method comprising:
forming a lower layer comprising a substrate;
forming, on the lower layer, a pixel circuit layer comprising an inorganic insulating layer and a pixel circuit to overlap the pixel area;
removing a portion of the inorganic insulating layer that overlaps the connection area;
forming a light-emitting diode on the pixel circuit layer;
forming connection wiring that overlaps the connection area by utilizing a sacrificial layer; and
removing the sacrificial layer.

2. The method of claim 1, wherein the sacrificial layer comprises a hydrophobic material.

3. The method of claim 1, wherein the removing of the sacrificial layer comprises removing the sacrificial layer through a cleaning process utilizing water.

4. The method of claim 1, wherein
the forming of the pixel circuit layer comprises forming a signal line electrically connected to the pixel circuit, and
the signal line in the pixel area extends to the connection area and is in direct contact with the connection wiring.

5. The method of claim 4, wherein the signal line is a gate line extending along a first direction or a data line extending along a second direction intersecting the first direction.

6. The method of claim 1, wherein the forming of the connection wiring that overlaps the connection area by utilizing the sacrificial layer comprises:
forming the sacrificial layer, in which a first opening overlapping the connection area is defined; and
forming connection wiring in an area overlapping the first opening.

7. The method of claim 6, further comprising, between the forming of the light-emitting diode and the forming of the connection wiring:
inverting the display panel so that an upper surface and a lower surface of the display panel are reversely arranged; and
removing the lower layer, and
wherein the sacrificial layer is formed on a lower surface of the pixel circuit layer.

8. The method of claim 7, further comprising, between the forming of the light-emitting diode and the inverting of the display panel, forming an upper elastomer layer to cover the light-emitting diode,
wherein the connection wiring is on a lower surface of the upper elastomer layer.

9. The method of claim 7, further comprising, after the removing of the sacrificial layer, forming a lower elastomer layer on a lower surface of the pixel circuit layer to cover the connection wiring.

10. The method of claim 6, wherein the forming of the connection wiring that overlaps the connection area by utilizing the sacrificial layer and the removing of the sacrificial layer are performed between the forming of the pixel circuit layer and the forming of the light-emitting diode, And
wherein the sacrificial layer is formed on an upper surface of the pixel circuit layer.

11. The method of claim 10, wherein
the forming of the lower layer comprises forming a base layer on the substrate, and
the connection wiring is defined in the base layer and is provided within a second opening that overlaps the first opening.

12. The method of claim 11, wherein the second opening exposes an upper surface of the substrate.

13. The method of claim 11, further comprising:
detaching the substrate; and
forming a lower elastomer layer on a lower surface of the base layer and a lower surface of the connection wiring.

14. The method of claim 11, wherein
the forming of the lower layer further comprises forming a lower elastomer layer between the substrate and the base layer, and
the second opening exposes an upper surface of the lower elastomer layer.

15. The method of claim 10, further comprising forming an upper elastomer layer to cover the light-emitting diode and the connection wiring.

16. The method of claim 6, wherein the forming of the connection wiring that overlaps the connection area by utilizing the sacrificial layer and the removing of the sacrificial layer are performed between the forming of the lower layer and the forming of the pixel circuit layer.

17. The method of claim 16, wherein
the forming of the lower layer comprises forming a lower elastomer layer on the substrate, and
the sacrificial layer and the connection wiring are formed on the lower elastomer layer.

18. The method of claim 1, wherein the forming of the connection wiring that overlaps the connection area by utilizing the sacrificial layer comprises:
forming a sacrificial layer on the lower layer;
forming, on the sacrificial layer, a sub-elastomer layer patterned to overlap the connection area; and
forming the connection wiring on an upper surface of the sub-elastomer layer.

19. The method of claim 18, further comprising, after the removing of the sacrificial layer, forming a lower elastomer layer on a lower surface of the pixel circuit layer and a lower surface of the sub-elastomer layer.

20. An electronic apparatus comprising:
a display panel comprising a pixel area and a connection area surrounding the pixel area; and
a lower cover forming an outer appearance and having an opening exposing a portion of the display panel in a front surface of the lower cover,
wherein the display panel comprises:
a lower elastomer layer;
a pixel circuit layer on the lower elastomer layer, and comprising an inorganic insulating layer and a pixel circuit to overlap the pixel area;
a light-emitting diode on the pixel circuit layer; and
connection wiring on the lower elastomer layer and overlapping the connection area,
the pixel circuit layer comprises a signal line electrically connected to the pixel circuit, and
the signal line in the pixel area extends to the connection area and is in direct contact with the connection wiring.
